(19) United States
(12) Patent Application Publication
(10) Pub. No.: US 2017/0115571 A1
(43) Pub. Date: Apr. 27, 2017

(54) PATTERN FORMING METHOD AND METHOD FOR MANUFACTURING ELECTRONIC DEVICE USING SAME

(71) Applicant: FUJIFILM Corporation, Tokyo (JP)

(72) Inventors: Keita KATO, Haibara-gun (JP); Keiyu OU, Haibara-gun (JP); Michihiro SHIRAKAWA, Haibara-gun (JP); Akiyoshi GOTO, Haibara-gun (JP)

(73) Assignee: FUJIFILM Corporation, Tokyo (JP)

(21) Appl. No.: 15/401,385

(22) Filed: Jan. 9, 2017

Related U.S. Application Data
(63) Continuation of application No. PCT/JP2015/068829, filed on Jun. 30, 2015.

(30) Foreign Application Priority Data
Aug. 1, 2014 (JP) 2014-158046

(51) Int. Cl. G03F 7/09; G03F 7/039; G03F 7/40; G03F 7/32; G03F 7/095; G03F 7/16; G03F 7/30; G03F 7/038; G03F 7/20

(52) U.S. Cl. CPC G03F 7/094; G03F 7/038; G03F 7/039; G03F 7/40; G03F 7/2041; G03F 7/095; G03F 7/162; G03F 7/168; G03F 7/2006; G03F 7/3085; G03F 7/322

(57) ABSTRACT

A pattern forming method includes (A) a step of forming a first resist film on a substrate by using a first resist composition, (B) a step of exposing the first resist film, (C) a step of forming a first pattern by developing the exposed first resist film, (D) a step of forming a planarization layer on the substrate provided with the first pattern by using composition for forming a planarization layer (a), (E) a step of forming a second resist film on the planarization layer by using a second resist composition, (F) a step of exposing the second resist film, and (G) a step of forming a second pattern by developing the exposed second resist film in this order, in which the first pattern is insoluble in the composition for forming the planarization layer (a), and a method for manufacturing an electronic device using the pattern forming method.

### CROSS-REFERENCE TO RELATED APPLICATIONS

This application is a Continuation of PCT International Application No. PCT/JP2015/68829, filed on Jun. 30, 2015, which claims priority under 35 U.S.C. §119(a) to Japanese Patent Application No. 2014-158046, filed on Aug. 1, 2014. Each of the above application(s) is hereby expressly incorporated by reference, in its entirety, into the present application.

### BACKGROUND OF THE INVENTION

1. Field of the Invention

The present invention relates to a pattern forming method and a method for manufacturing an electronic device using the pattern forming method. More specifically, the present invention relates to a pattern forming method, which is suitable for a process of manufacturing a semiconductor such as IC, manufacturing of a circuit board of liquid crystals, thermal heads, and the like, and other photofabrication lithography processes, and to a method for manufacturing an electronic device using the pattern forming method. Particularly, the present invention relates to a pattern forming method, which is suitable for exposure using an ArF exposure device and an ArF liquid immersion-type projection exposure device that uses far-ultraviolet rays having a wavelength of equal to or less than 300 nm as a light source, and to a method for manufacturing an electronic device using the pattern forming method.

2. Description of the Related Art

Although ArF liquid immersion lithography is being currently used for forming a leading edge pattern, in recent years, a further improvement of resolution has been required. As one of the lithography techniques that have been newly suggested, there is a double patterning process of forming a resist pattern by performing patterning two or more times (for example, see JP2008-197526A and JP2010-511915A).

According to the double patterning process, for example, a first resist pattern is formed by performing patterning on a support by using a first resist composition, and then patterning is performed on the support, on which the first resist pattern is formed, by using a second resist composition. It is considered that, in this way, it is possible to form a resist pattern having resolution higher than that of a resist pattern formed by patterning performed once.

In the double patterning process described above, at the time of performing patterning by using the second resist composition, the first resist pattern is easily affected. Therefore, for example, there is a problem in that the resist pattern shape is ruined due to a decrease in a line width of the first resist pattern (pattern thinning) or film thinning, and hence a fine resist pattern having excellent shape cannot be formed.

As a method for preventing the defectiveness of a resist pattern shape, there is a technique that uses, for example, a freezing material after the formation of a first resist pattern, but in view of the improvement of throughput, this technique is not preferable.

### SUMMARY OF THE INVENTION

The present invention has been made in consideration of the above problem, and an object thereof is to provide a pattern forming method, which makes it possible to easily form an ultrafine pattern (for example, a line-and-space pattern in which both of a line width and a space width are equal to or less than 40 nm), and a method for manufacturing an electronic device.

The present invention has the following constitution, and the aforementioned object of the present invention was achieved by the constitution.

[1] A pattern forming method comprising:

(A) a step of forming a first resist film on a substrate by using a first resist composition;

(B) a step of exposing the first resist film;

(C) a step of forming a first pattern by developing the exposed first resist film;

(D) a step of forming a planarization layer on the substrate provided with the first pattern by using a composition for forming a planarization layer (a);

(E) a step of forming a second resist film on the planarization layer by using a second resist composition;

(F) a step of exposing the second resist film; and

(G) a step of forming a second pattern by developing the exposed second resist film in this order,

in which the first pattern is insoluble in the composition for forming the planarization layer (a).

[2] The pattern forming method described in [1], in which the step (C) is a step of forming the first pattern by developing the exposed first resist film by using a developer containing an organic solvent.

[3] The pattern forming method described in [1] or [2], further comprising (C′) a step of heating the first pattern between the step (C) and the step (D).

[4] The pattern forming method described in [3], in which a heating temperature in the step (C′) is equal to or higher than 130° C.

[5] The pattern forming method described in any one of [1] to [4], in which the step (G) is a step of forming a negative pattern as the second pattern by using the developer containing an organic solvent.

[6] The pattern forming method described in any one of [1] to [4], in which the step (G) is a step of forming a positive pattern as the second pattern by using an alkali developer.

[7] The pattern forming method described in any one of [1] to [6], in which at least one of the first pattern or the second pattern contains a silicon atom.

[8] The pattern forming method described in any one of [1] to [7], further comprising (H) a step of converting the first pattern into a microfabricated pattern by performing an etching treatment on the planarization layer and the first pattern by using the second pattern as a mask after the step (G).

[9] The pattern forming method described in [8], further comprising (I) a step of removing the planarization layer and the second pattern after the step (H).

[10] The pattern forming method described in [9], in which the step (I) includes a step of performing an etching treatment on the planarization layer under a condition in which an etching rate of the planarization layer becomes higher than an etching rate of the microfabricated pattern.

[11] The pattern forming method described in any one of [1] to [10], in which the planarization layer is a layer containing a resin having an Onishi parameter of equal to or greater than 4.0.

[12] A method for manufacturing an electronic device, comprising the pattern forming method described in any one of [1] to [11].

[13] An electronic device manufactured by the method for manufacturing an electronic device described in [12].

The present invention preferably further has the following constitution.

[14] The pattern forming method described in any one of [1] to [11], in which the first pattern and the second pattern are formed such that the shape of the first pattern seen in a direction perpendicular to the substrate and the shape of the second pattern seen in a direction perpendicular to the substrate do not completely overlap each other.

[15] The pattern forming method described in [14], in which both of the first pattern and the second pattern are a line-and-space pattern in which a line width is greater than a space width.

[16] The pattern forming method described in [15], in which a line direction of the first pattern and a line direction of the second pattern are parallel to each other.

According to the present invention, it is possible to provide a pattern forming method, which makes it possible to easily form an ultrafine pattern (for example, a line-and-space pattern in which both of a line width and a space width are equal to or less than 40 nm), a method for manufacturing an electronic device, and an electronic device.

### BRIEF DESCRIPTION OF THE DRAWINGS

FIG. 1 is a schematic sectional view for describing embodiments of the present invention.

### DESCRIPTION OF THE PREFERRED EMBODIMENTS

Hereinafter, embodiments of the present invention will be specifically described.

In the present specification, regarding a description of a group (atomic group), in a case where there is no description regarding whether the group is substituted or unsubstituted, the group includes both of a group (atomic group) not having a substituent and a group (atomic group) having a substituent. For example, an “alkyl group” includes not only an alkyl group not having a substituent (unsubstituted alkyl group) but also an alkyl group having a substituent (substituted alkyl group).

In the present specification, “actinic rays” or “radiation” means, for example, a bright-line spectrum of a mercury lamp, far ultraviolet rays represented by an excimer laser, extreme ultraviolet rays (EUV light), X-rays, or electron beams (EB). Furthermore, in the present invention, light means actinic rays or radiation.

In the present specification, “exposure” is not particularly limited, and includes not only exposure by a mercury lamp, far ultraviolet rays represented by an excimer laser, extreme ultraviolet rays (EUV light), X-rays, and the like, but also writing by particle rays such as electron beams and ion beams.

The patterning forming method of the present invention is a pattern forming method including (A) a step of forming a first resist film on a substrate by using a first resist composition, (B) a step of exposing the first resist film, (C) a step of forming a first pattern by developing the exposed first resist film, (D) a step of forming a planarization layer on the substrate provided with the first pattern by using a composition for forming a planarization layer (a), (E) a step of forming a second resist film on the planarization layer by using a second resist composition, (F) a step of exposing the second resist film, and (G) a step of forming a second pattern by developing the exposed second resist film in this order, in which the first pattern is insoluble in the composition for forming the planarization layer (a).

Herein, the fact that the first pattern is insoluble in the composition for forming a planarization layer (a) typically means that when the first pattern is dipped into the composition for forming a planarization layer (a) for 1,000 seconds at room temperature (25° C.), an average dissolution rate thereof (a film thickness reduction rate of the first pattern) measured using a quartz crystal microbalance (QCM) sensor or the like is equal to or less than 3 nm/s, more preferably equal to or less than 1 nm/s, and even more preferably equal to or less than 0.1 nm/s.

Therefore, the step (C) is typically a step of forming a first pattern by developing the exposed first resist film by using a developer containing an organic solvent.

The reason why the aforementioned pattern forming method makes it possible to easily form an ultrafine pattern (for example, a line-and-space pattern in which both of a line width and a space width are equal to or less than 40 nm) is unclear, but is assumed to be as below.

First, in the pattern forming method of the present invention, the first pattern is formed through the steps (A) to (C) as described above. Typically, the first resist film contains an organic compound such as a resin as a main component. Therefore, because the solubility of an unexposed portion in the developer containing an organic solvent (hereinafter, referred to as an organic developer as well) is high while the solubility of an exposed portion, in which the main component is altered due to exposure, in the organic developer is low, the pattern formed through the steps (A) to (C) is typically a negative pattern.

For example, in a case where it is desired to form an ultrafine space pattern (for example, a space width of equal to or less than 40 nm) by forming a positive pattern, a region in which a space portion is to be formed becomes an exposed portion, and accordingly, it is optically extremely difficult to expose and resolve an ultrafine region. In contrast, in a case where it is desired to form an ultrafine space pattern by forming a negative pattern by using an organic developer, a wide region other than a space portion can be used as an exposed portion. Accordingly, optically difficulties are reduced, and the aforementioned space pattern can be reliably formed.

Furthermore, as described above, the first pattern is insoluble in the composition for forming a planarization layer (a), and a film portion of the first pattern is typically a region that exhibits low solubility with respect to the organic developer as described above. Therefore, the first pattern is not easily affected by the solvent in the composition for forming a planarization layer (a) used in the step (D) (that is, the first pattern has sufficient solvent resistance). Consequently, for example, a step of treating a pattern with a freezing material that is frequently used in a positive pattern forming method can be skipped.

As described above, according to the pattern forming method of the present invention, first, it is considered that an ultrafine resist pattern (particularly, an ultrafine space pattern) can be easily formed as the first pattern.

Next, in the pattern forming method of the present invention, a planarization layer is formed by the step (D) as described above. Typically, the planarization layer is for simply functioning as a basis for forming the second resist film.

Then, in the pattern forming method of the present invention, the second pattern is formed through the steps (E) to (G) as described above.

According to the pattern forming method of the present invention described above, particularly by a simple operation, in which the first pattern and the second pattern are formed such that the shape of the first pattern seen in a direction perpendicular to the substrate and the shape of the second pattern seen in a direction perpendicular to the substrate do not completely overlap each other, an etching treatment is performed on the planarization layer and the first pattern by using the second pattern as a mask, and then the planarization layer and the second pattern are removed, it is possible to form a microfabricated pattern, which has a shape formed by the transfer of the shape of the first pattern and the shape of the second pattern, on the substrate.

Herein, for example, by forming both of the first pattern and the second pattern as a line-and-space pattern in which a line width is greater than a space width and making the line direction of the first pattern and the line direction of the second pattern parallel to each other (more specifically, for example, by making a center line of a space portion of the second pattern and a center line of a line portion of the first pattern coincide with each other in a case where the patterns are seen in a direction perpendicular to the substrate), it is possible to easily form a line-and-space pattern in which both of a line width and a space width are equal to or less than 40 nm.

As described above, in the pattern forming method of the present invention, an ultrafine resist pattern can be easily formed as the first pattern. In addition, by the formation of the planarization layer, exposure and development can be performed in each of the step of forming the first pattern and the step of forming the second pattern. As a result, in the step of forming each pattern, optically achievable exposure can be adopted, and ultimately, a microfabricated pattern to which the shape of the first pattern and the shape of the second pattern are transferred can be easily formed. It is considered that, for this reason, an ultrafine pattern (for example, a line-and-space pattern in which both of a line width and a space width are equal to or less than 40 nm) can be easily formed.

<Pattern Forming Method>

Hereinafter, the pattern forming method of the present invention will be specifically described.

The pattern forming method of the present invention is a pattern forming method including (A) a step of forming a first resist film on a substrate by using a first resist composition, (B) a step of exposing the first resist film, (C) a step of forming a first pattern by developing the exposed first resist film, (D) a step of forming a planarization layer on the substrate provided with the first pattern by using a composition for forming a planarization layer (a), (E) a step of forming a second resist film on the planarization layer by using a second resist composition, (F) a step of exposing the second resist film, and (G) a step of forming a second pattern by developing the exposed second resist film in this order, in which the first pattern is insoluble in the composition for forming the planarization layer (a).

In the pattern forming method of the present invention, each of the steps (A) to (G) can be performed by a generally known method.

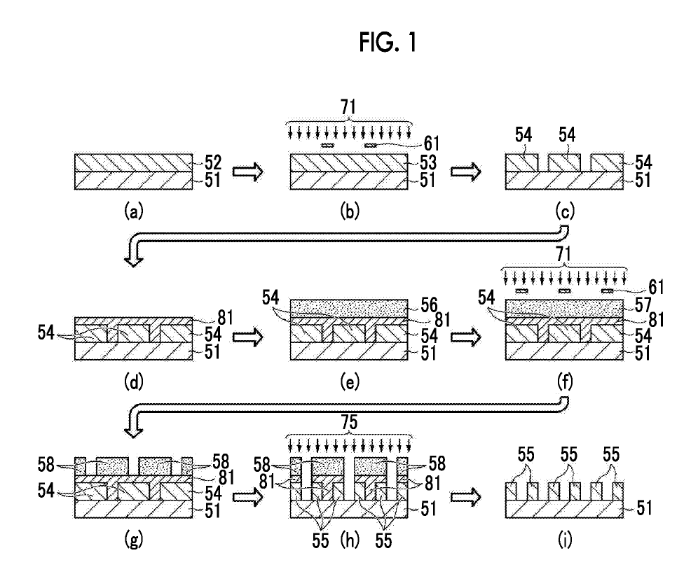

In an embodiment of the present invention, as shown in (a) of FIG. 1 which is a schematic sectional view, first, a first resist film 52 is formed on a substrate 51 by using a first resist composition (step (A)).

It is preferable that the first resist composition contains a resin of which the solubility in a developer containing an organic solvent (organic developer) decreases due to an increase in polarity caused by the action of an acid, for the following reason. In a case where the first resist composition contains particularly the aforementioned resin, the first pattern obtained through the steps (B) and (C), which will be described later, contains the resin of which the solubility in an organic developer has decreased due to exposure. Therefore, as described above, the first pattern can be made insoluble in the composition for forming a planarization layer (a) and is not easily affected by the solvent in the composition for forming a planarization layer (a) used in the step (D), and hence a desired pattern can be easily formed.

The details of the first resist composition, the resin which is preferably contained in the first resist composition and of which the solubility in a developer containing an organic solvent decreases due to an increase in polarity caused by the action of an acid, and the like will be described later.

In the step (A), the method for forming the first resist film on the substrate by using the first resist composition can be performed typically by coating the substrate with the first resist composition. As the coating method, it is possible to use a spin coating method, a spray method, a roller coating method, a dipping method, and the like known in the related art. It is preferable that the substrate is coated with the first resist composition by a spin coating method.

A film thickness of the first resist film is preferably 20 to 160 nm, more preferably 25 to 140 nm, and even more preferably 30 to 120 nm.

The substrate 51 for forming the first resist film is not particularly limited, and it is possible to use substrates such as an inorganic substrate of silicon, SiO₂, SiN, or the like and an inorganic substrate for coating of SOG or the like that are generally used in a process of manufacturing a semiconductor such as IC, a process of manufacturing a circuit board of liquid crystals, a thermal head, and the like, and other photofabrication lithography processes. If necessary, an underlayer film such as an antireflection film may be formed between the first resist film and the substrate. As the underlayer film, an organic antireflection film, an inorganic antireflection film, and others can be appropriately selected. Materials of the underlayer film are available from Brewer Science, Inc., NISSAN CHEMICAL INDUSTRIES, LTD., and the like. Examples of the underlayer film suitable for a process of performing development by using a developer containing an organic solvent include the underlayer film described in WO2012/039337A.

It is preferable that the pattern forming method of the present invention also includes a Prebake (PB) step between the step (A) and the step (B).

It is also preferable that the pattern forming method of the present invention includes a Post Exposure Bake (PEB) step before the step (B) and the step (C).

In both of PB and PEB, heating is performed preferably at a temperature of 70° C. to 130° C. and more preferably at a temperature of 80° C. to 120° C.

The heating time is preferably 30 to 300 seconds, more preferably 30 to 180 seconds, and even more preferably 30 to 90 seconds.

The heating can be performed by means equipped with a general exposure and developing machine or may be performed using a hot plate.

Due to the baking, the reaction of an exposed portion is accelerated, and hence the sensitivity or the pattern profile is improved.

At least one of the PB step or the PEB step may include a heating step performed plural times.

Then, as shown in (b) of FIG. 1 which is a schematic sectional view, the first resist film 52 is irradiated with (that is, exposed to) actinic rays or radiation 71 through a mask 61, thereby obtaining a first resist film 53 having undergone exposure (step (B)).

A mask pattern in the mask 61 is not particularly limited, and examples thereof include a mask which has a line-and-space pattern having a line portion as a light shielding portion and a space portion as a light transmission portion and in which a ratio of a width of the line portion to a width of the space portion is 1:3.

In the step (B), a wavelength of a light source used in an exposure device is not particularly limited, and examples of the light source include infrared light, visible light, ultraviolet light, far ultraviolet light, extreme ultraviolet light, X-rays, electron beams, and the like. Among these, far ultraviolet light preferably having a wavelength of equal to or less than 250 nm, more preferably having a wavelength of equal to or less than 220 nm, and particularly preferably having a wavelength of 1 to 200 nm is preferable. Specific examples thereof include a KrF excimer laser (248 nm), an ArF excimer laser (193 nm), an F₂ excimer laser (157 nm), X-rays, EUV (13 nm), electron beams, and the like. Among these, a KrF excimer laser, an ArF excimer laser, EUV, or electron beams are preferable, and an ArF excimer laser is more preferable.

The step (B) may include an exposure step performed plural times.

In the step (B), a liquid immersion exposure method can be applied.

The liquid immersion exposure method is a technique for improving resolving power. In this technique, exposure is performed in a state where a space between a projection lens and a sample is filled with a liquid (hereinafter, referred to as an “immersion liquid” as well) having a high refractive index.

As described above, regarding the “effect of liquid immersion”, provided that a wavelength of exposure light in the air is λ₀, a refractive index of an immersion liquid with respect to the air is n, and a convergence half angle θ of light rays is expressed by NA₀=sin θ, in a case where liquid immersion is performed, a resolving power and a focal depth can be represented by the following equations. Herein, k₁ and k₂ are coefficients involved in the process.

(Resolving power)=k₁·(λ₀/n)/NA₀

(Focal depth)=±k₂·(λ₀/n)/NA₀²

That is, the effect of liquid immersion is equivalent to an effect obtained when an exposure wavelength of 1/n is used. In other words, in a case of a projection optical system having the same NA, by liquid immersion, a focal depth can be increased by a factor of n. The liquid immersion is effective for various pattern shapes, and can be combined with super-resolution techniques that are currently under investigation, such as a phase shifting method and a modified illumination method.

In a case where liquid immersion exposure is performed, at either or both of (1) a point in time before the step of exposure is performed after the first resist film is formed on a substrate and (2) a point in time before the step of heating the first resist film is performed after the step of exposing the first resist film through the immersion liquid, a step of rinsing the surface of the first resist film with an aqueous chemical solution may be performed.

The immersion liquid is preferably a liquid which transmits the exposure wavelength and of which a temperature coefficient of a refractive index is as small as possible such that the distortion of an optical image projected onto the first resist film is minimized. Particularly, in a case where the exposure light source is an ArF excimer laser (wavelength; 193 nm), from the viewpoint described above and in view of ease of availability and ease of handleability, it is preferable to use water.

In a case where water is used, an additive (liquid), which reduces the surface tension of water and enhancing surface activity, may be added in a small proportion. As the additive, a liquid is preferable which does not dissolve a resist layer on a wafer and negligibly affects an optical coat of a lower surface of a lens element.

As the additive, an aliphatic alcohol is preferable which has a refractive index that is substantially the same as the refractive index of water, and specific examples thereof include methyl alcohol, ethyl alcohol, isopropyl alcohol, and the like. The addition of an alcohol having a refractive index that is substantially the same as the refractive index of water results in an advantage that, even if the alcohol component in water evaporates and hence the concentration thereof contained changes, an overall change of a refractive index of the liquid can be minimized.

In contrast, in a case where a substance which does not transmit light of 193 nm or impurities which have a refractive index greatly different from the refractive index of water are intermixed, an optical image projected onto a lens is distorted. Therefore, as water to be used, distilled water is preferable. Furthermore, pure water filtered through an ion exchange filter may also be used.

An electric resistance of water used as an immersion liquid is desirably equal to or greater than 18.3 MΩcm, and a total organic carbon (TOC) thereof is desirably equal to or less than 20 ppb. Furthermore, it is desirable that the water has undergone a deaeration treatment.

If a refractive index of an immersion liquid is increased, lithography performance can be improved. From this viewpoint, an additive that will increase the refractive index may be added to water, or heavy water (D₂O) may be used instead of water.

In a case where the first resist film formed using the first resist composition of the present invention is exposed through a liquid immersion medium, if necessary, a hydrophobic resin (D) which will be described later can be added. The addition of the hydrophobic resin (D) improves a receding contact angle of a surface. A receding contact angle of the first resist film is preferably 60° to 90°, and more preferably equal to or greater than 70°.

In the liquid immersion exposure step, the immersion liquid needs to move along with the movement of an exposure head that forms an exposure pattern by performing scanning on a wafer at a high speed. Therefore, a contact angle of the immersion liquid with respect to the first resist film in a dynamic state is important, and the resist is required to have performance of following the high-speed scanning performed by the exposure head without leaving liquid droplets.

In order to prevent the film from directly contacting the immersion liquid, a film poorly soluble in the immersion liquid (hereinafter, referred to as a “top coat” as well) may be provided between the first resist film, which is formed using the first resist composition of the present invention, and the immersion liquid. Examples of functions required for the top coat include a property of being suitable for coating an upper layer portion of resist, transparency with respect to radiation particularly having a wavelength of 193 nm, and a property of being poorly soluble in the immersion liquid. It is preferable that the top coat is not mixed with the resist and can evenly coat an upper layer of the resist.

From the viewpoint of transparency at 193 nm, the top coat is preferably a polymer not containing an aromatic group.

Specifically, examples thereof include a hydrocarbon polymer, an acrylic acid ester polymer, polymethacrylic acid, polyacrylic acid, polyvinyl ether, a silicon-containing polymer, a fluorine-containing polymer, and the like. The hydrophobic resin (D) which will be described later is also suitable as a top coat. In a case where impurities are eluted onto the immersion liquid from the top coat, the optical lens is contaminated. Therefore, it is preferable that the amount of a residual monomer component of the polymer contained in the top coat is small.

At the time of peeling the top coat, a developer may be used, or a release agent may be separately used. As a release agent, a solvent that hardly permeates the first resist film is preferable. It is preferable that a difference in a refractive index between the top coat and the immersion liquid is zero or small. In this case, the resolving power can be improved. In a case where an ArF excimer laser (wavelength: 193 nm) is an exposure light source, it is preferable to use water as an immersion liquid, and accordingly, a refractive index of the top coat for ArF liquid immersion exposure is preferably close to the refractive index (1.44) of water. From the viewpoint of the transparency and refractive index, the top coat is preferably a thin film.

It is preferable that the top coat is not mixed with the first resist film and the immersion liquid. From this viewpoint, in a case where water is an immersion liquid, it is preferable that a solvent used in the top coat is poorly soluble in a solvent used in the composition of the present invention and is a water-insoluble medium. In a case where an organic solvent is an immersion liquid, the top coat may be water-soluble or water-insoluble.

Then, as shown in (c) of FIG. 1 which is a schematic sectional view, by developing the first resist film 53 having undergone exposure, a first pattern 54 is formed (step (C)).

Typically, the step (C) is a step of forming the first pattern by developing the exposed first resist film by using a developer containing an organic solvent. The first pattern 54 is typically a negative pattern.

In the step (C), as the developer (hereinafter, referred to as an organic developer as well) in the step of forming the first pattern by developing the first resist film by using a developer containing an organic solvent, it is possible to use a polar solvent, such as a ketone-based solvent, an ester-based solvent, an alcohol-based solvent, an amide-based solvent, or an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and the like.

Examples of the ester-based solvent include methyl acetate, butyl acetate, ethyl acetate, isopropyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, and the like.

Examples of the ether-based solvent include the aforementioned glycol ether-based solvent, dioxane, tetrahydrofuran, phenetole, dibutyl ether, and the like.

Examples of the amide-based solvent include N-methyl-2-pyrrolidone, N,N-dimethylacetamide, N,N-dimethylformamide, hexamethylphosphoric triamide, 1,3-dimethyl-2-imidazolidinone, and the like.

Examples of the hydrocarbon-based solvent include an aromatic hydrocarbon-based solvent such as toluene or xylene and an aliphatic hydrocarbon-based solvent such as pentane, hexane, octane, or decane.

The above solvent may be used as a mixture of plural solvents or used by being mixed with solvents other than the above or water. Here, in order to fully bring about the effects of the present invention, a total moisture content of the developer is preferably less than 10% by mass and more preferably practically 0% by mass.

That is, an amount of the organic solvent used in the organic developer is, with respect to a total amount of the developer, preferably equal to or greater than 90% by mass and equal to or less than 100% by mass, and more preferably equal to or greater than 95% by mass and equal to or less than 100% by mass.

Particularly, the organic developer is preferably a developer containing at least one kind of organic solvent selected from the group consisting of a ketone-based solvent, an ester-based solvent, an alcohol-based solvent, an amide-based solvent, and an ether-based solvent.

At 20° C., a vapor pressure of the organic developer is preferably equal to or less than 5 kPa, more preferably equal to or less than 3 kPa, and particularly preferably equal to or less than 2 kPa. In a case where the vapor pressure of the organic developer is equal to or less than 5 kPa, the developer is inhibited from evaporating on the substrate or in a developing cup, and temperature uniformity within the wafer surface is improved. As a result, dimensional uniformity within the wafer surface is improved.

Specific examples of the solvent having a vapor pressure of equal to or less than 5 kPa include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methyl cyclohexanone, phenylacetone, or methyl isobutyl ketone, an ester-based solvent such as butyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, or propyl formate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, an glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, an ether-based solvent such as tetrahydrofuran, phenetole, or dibutyl ether, an amide-based solvent such as N-methyl-2-pyrrolidone, N,N-dimethylacetamide, or N,N-dimethylformamide, an aromatic hydrocarbon-based solvent such as toluene or xylene, and an aliphatic hydrocarbon-based solvent such as octane or decane.

Specific examples of the solvent having a vapor pressure of equal to or less than 2 kPa which is a particularly preferred range include a ketone-based solvent such as 1-octanone, 2-octanone, 1-nonanone, 2-nonanone, 4-heptanone, 2-hexanone, diisobutyl ketone, cyclohexanone, methyl cyclohexanone, or phenylacetone, an ester-based solvent such as butyl acetate, amyl acetate, cyclohexyl acetate, isobutyl isobutyrate, propylene glycol monomethyl ether acetate, ethylene glycol monoethyl acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, or propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol, or n-decanol, a glycol-based solvent such as ethylene glycol, diethylene glycol, or triethylene glycol, a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, or methoxymethyl butanol, an ether-based solvent such as phenetole or dibutyl ether, an amide-based solvent such as N-methyl-2-pyrrolidone, N,N-dimethylacetamide, or N,N-dimethylformamide, an aromatic hydrocarbon-based solvent such as xylene, and an aliphatic hydrocarbon-based solvent such as octane or decane.

If necessary, an appropriate amount of surfactant can be added to the organic developer.

The surfactant is not particularly limited, and for example, ionic or nonionic fluorine-based surfactant and/or silicon-based surfactant can be used. Examples of the fluorine-based surfactant and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A. Among these, a nonionic surfactant is preferable. The nonionic surfactant is not particularly limited, and it is more preferable to use a fluorine-based surfactant or a silicon-based surfactant.

An amount of the surfactant used is, with respect to a total amount of the developer, generally 0.001% to 5% by mass, preferably 0.005% to 2% by mass, and even more preferably 0.01% to 0.5% by mass.

If necessary, the organic developer may contain a basic compound. Examples of the basic compound include nitrogen-containing basic compounds such as the nitrogen-containing compounds described in paragraphs “0021” to “0063” of JP2013-11833A. In a case where the organic developer contains a basic compound, the improvement of contrast at the time of development, the inhibition of film thinning, and the like can be expected.

The resin of which the solubility in a developer containing an organic solvent decreases due to an increase in polarity thereof caused by the action of an acid can be a resin of which the solubility in an alkali developer increases due to an increase in polarity caused by the action of an acid. Therefore, the pattern forming method of the present invention may further include a step of performing development by using an alkali developer between the step (B) and the step (C) or between the step (C) and the step (D) (in a case where a step (C′) which will be described later is performed, between the step (C) and the step (C′)). In a case where the development using the organic developer and the development using the alkali developer are combined, as described in FIGS. 1 to 11 and the like of U.S. Pat. No. 8,227,183B, a pattern having a line width that is ½ of a line width of a mask pattern could be resolved.

In a case where the pattern forming method of the present invention further includes the step of performing development by using an alkali developer, as the alkali developer, for example, it is possible to use an alkali aqueous solution of inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine.

Furthermore, an appropriate amount of alcohols or surfactants may be used by being added to the aforementioned alkali aqueous solution. Examples of the surfactants include the surfactants described above.

An alkali concentration of the alkali developer is generally 0.1% to 20% by mass.

A pH of the alkali developer is generally 10.0 to 15.0.

Particularly, a 2.38% by mass aqueous solution of tetramethylammonium hydroxide is desirable.

As a development method, for example, it is possible to use a method of dipping a substrate into a tank filled with a developer for a certain period of time (dipping method), a method of performing development by heaping up a developer on the surface of a substrate by exploiting surface tension and allowing the developer standstill for a certain period of time (paddle method), a method of spraying a developer onto the surface of a substrate (spray method), a method of continuously jetting a developer onto a substrate, which is spinning at a certain rate, while scanning a developer-jetting nozzle at a certain rate (dynamic dispense method), and the like.

In a case where the aforementioned various development methods include a step of jetting a developer from a developing nozzle of a developing device to a resist film, a jetting pressure of the developer jetted (a flow rate of the jetted developer per unit area) is preferably equal to or less than 2 mL/sec/mm², more preferably equal to or less than 1.5 mL/sec/mm², and even more preferably equal to or less than 1 mL/sec/mm². A lower limit of the flow rate is not particularly limited. Considering throughput, the lower limit is preferably equal to or greater than 0.2 mL/sec/mm².

In a case where the jetting pressure of the jetted developer is within the above range, it is possible to markedly reduce the pattern defect resulting from resist residues remaining after development.

The details of the mechanism thereof are unclear. Presumably, in a case where the jetting pressure is within the above range, a pressure that the developer applies to the resist film may be reduced, the resist film and the resist pattern may be inhibited from being unnecessarily scraped or collapsed, and hence the aforementioned effect may be obtained.

The jetting pressure (mL/sec/mm²) of the developer is a value at an exit of a developing nozzle in a developing device.

Examples of a method of adjusting the jetting pressure of the developer include a method of adjusting the jetting pressure by using a pump or the like, a method of changing the jetting pressure by adjusting the pressure by means of supplying the developer from a pressurized tank, and the like.

After the step of performing development by using a developer containing an organic solvent, a step of stopping development while substituting the developer with other solvents may be performed.

The pattern forming method of the present invention may include a step of performing rinsing by using a rinsing liquid containing an organic solvent (rinsing step) between the step (C) and the step (D) (in a case where the step (C′) which will be described later is performed, between the step (C) and the step (C′)), that is, before the step of performing development by using a developer containing an organic solvent.

The rinsing liquid, which is used in the rinsing step following the step of performing development by using a developer containing an organic solvent, is not particularly limited as long as the rinsing liquid does not dissolve the resist pattern, and a solution containing a general organic solvent can be used. As the rinsing liquid, it is preferable to use a rinsing liquid containing at least one kind of organic solvent selected from the group consisting of a hydrocarbon-based solvent, a ketone-based solvent, an ester-based solvent, an alcohol-based solvent, an amide-based solvent, and an ether-based solvent.

Specific examples of the hydrocarbon-based solvent, the ketone-based solvent, the ester-based solvent, the alcohol-based solvent, the amide-based solvent, and the ether-based solvent include the same solvents as described above for the developer containing an organic solvent.

The pattern forming method of the present invention more preferably includes a step of performing rinsing by using a rinsing liquid containing at least one kind of organic solvent selected from the group consisting of a ketone-based solvent, an ester-based solvent, an alcohol-based solvent, and an amide-based solvent, even more preferably includes a step of performing rinsing by using a rinsing liquid containing an alcohol-based solvent or an ester-based solvent, particularly preferably includes a step of performing rinsing by using a rinsing liquid containing a monohydric alcohol, and most preferably includes a step of performing rinsing by using a rinsing liquid containing a monohydric alcohol having 5 or more carbon atoms, after the step of performing development by using a developer containing an organic solvent.

Examples of the monohydric alcohol used in the rinsing step include a linear, branched, or cyclic monohydric alcohol. Specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and the like. As a particularly preferred monohydric alcohol having 5 or more carbon atoms, it is possible to use 1-hexanol, 2-hexanol, 4-methyl-2-pentanol, 1-pentanol, 3-methyl-1-butanol, and the like.

A plurality of each of the components described above may be mixed together, or each of the components may be used by being mixed with an organic solvent other than those described above.

A moisture content in the rinsing liquid is preferably equal to or less than 10% by mass, more preferably equal to or less than 5% by mass, and particularly preferably equal to or less than 3% by mass. In a case where the moisture content is equal to or less than 10% by mass, excellent developing characteristics can be obtained.

At 20° C., a vapor pressure of the rinsing liquid used after the step of performing development by using a developer containing an organic solvent is preferably equal to or greater than 0.05 kPa and equal to or less than 5 kPa, more preferably equal to or greater than 0.1 kPa and equal to or less than 5 kPa, and most preferably equal to or greater than 0.12 kPa and equal to or less than 3 kPa. In a case where the vapor pressure of the rinsing liquid is equal to or greater than 0.05 kPa and equal to or less than 5 kPa, temperature uniformity within the wafer surface is improved, swelling resulting from the permeation of the rinsing liquid is inhibited, and hence dimensional uniformity within the wafer surface is improved.

In a case where the pattern forming method of the present invention further includes the step of performing development by using an alkali developer, the pattern forming method may also include the step of performing rinsing by using a rinsing liquid (rinsing step). In this case, pure water is used as the rinsing liquid, and a surfactant may also be used by being added thereto in an appropriate amount.

A method of rinsing treatment in the aforementioned rinsing step is not particularly limited. For example, it is possible to use a method of continuously jetting the rinsing liquid onto a substrate that is spinning at a certain rate (spin coating method), a method of dipping a substrate into a tank filled with the rinsing liquid for a certain period of time (dipping method), a method of spraying the rinsing liquid onto the surface of a substrate (spray method), and the like. Particularly, it is preferable to perform the rinsing treatment by using the spin coating method among the above methods and to remove the rinsing liquid from the surface of the substrate by spinning the substrate after rinsing at a rotation frequency of 2,000 rpm to 4,000 rpm. It is also preferable that the pattern forming method of the present invention includes a heating step (Post Bake) after the rinsing step. Through baking, the developer and the rinsing liquid remaining between the patterns and inside the patterns is removed. The heating step after the rinsing step is performed generally at 40° C. to 160° C. and preferably at 70° C. to 95° C., generally for 10 seconds to 3 minutes and preferably for 30 seconds to 90 seconds.

After the developing treatment or the rinsing treatment, it is possible to perform a treatment for removing the developer or the rinsing liquid that has adhered onto the pattern by using a supercritical fluid.

Between the step (C) and the step (D) which will be specifically described later, a heating step (C′) may be additionally performed. In a case where the step (C′) is performed, solvent resistance of the first pattern formed by the step (C) can be further improved as described above, and it is possible to prevent the first pattern from being easily damaged even if the first pattern is coated with a liquid composed of the composition for forming a planarization layer (a) in the following step (D). A temperature during the heating step is preferably equal to or higher than 130° C., more preferably equal to or higher than 150° C., and even more preferably equal to or higher than 170° C. The temperature is generally equal to or less than 240° C. A heating time during the heating step is about 30 to 120 seconds.

It is also preferable that the heating step (C′) is performed under reduced pressure, because then the volatilization of decomposition residues of organic substances is accelerated, and hence the heating temperature can be reduced and the heating time can be shortened.

As described above, the first pattern 54 has sufficient solvent resistance, and accordingly, a freezing material does not need to be used. However, in the present invention, a known freezing material may be used for the first pattern 54.

Then, as shown in (d) of FIG. 1 which is a schematic sectional view, on the substrate 51 on which the first pattern 54 is formed, a planarization layer 81 is formed using the composition for forming a planarization layer (a) (step (D)).

The details of the composition for forming a planarization layer (a) will be described later.

in the step (D), a method for forming a planarization layer by using the composition for forming a planarization layer (a) is the same as the method for forming the first resist film by using the first resist composition in the step (A).

A film thickness of the planarization layer based on the surface of the first pattern as a reference surface is preferably 0 to 50 nm, more preferably 2 to 40 nm, and even more preferably 5 to 30 nm. In a case where the planarization layer is formed such that void portions of the first pattern are filled with the planarization layer, and a flat surface is formed by the surface of the first pattern and the surface of the planarization layer, a film thickness of the planarization layer based on the surface of the first pattern as a reference surface may be 0 nm.

Then, as shown in (e) of FIG. 1 which is a schematic sectional view, on the substrate 51 on which the first pattern 54 is formed, a second resist film 56 is formed using a second resist composition (step (E)).

It is preferable that the second resist composition contains a resin of which the solubility in an organic developer decreases due to an increase in polarity caused by the action of an acid, for the following reason. In a case where the second resist composition particularly contains the aforementioned resin, the second pattern obtained through steps (F) and (G), which will be described later, can be made into a negative pattern formed using an organic developer, and accordingly, as described above, an ultrafine space pattern (for example, having a space width of equal to or less than 40 nm) can be reliably formed unlike in a case where a positive pattern is formed.

The details of the second resist composition, the resin which is preferably contained in the second resist composition and of which the solubility in an organic developer decreases due to an increase in polarity caused by the action of an acid, and the like will be described later.

In the step (E), a method for forming the second resist film by using the second resist composition is the same as the method for forming the first resist film by using the first resist composition in the step (A).

A preferred range of a film thickness of the second resist film is also the same as the aforementioned preferred range of the film thickness of the first resist film.

It is also preferable that the pattern forming method of the present invention includes a Prebake step (PB) between the step (E) and the step (F).

Furthermore, it is preferable that the pattern forming method of the present invention includes a Post Exposure Bake (PEB) step between the step (F) and the step (G).

In both of PB and PEB, a heating temperature is preferably 70° C. to 130° C., and more preferably 80° C. to 120° C.

A heating time is preferably 30 to 300 seconds, more preferably 30 to 180 seconds, and even more preferably 30 to 90 seconds.

The heating may be performed by means equipped with a general exposure and developing machine or may be performed using a hot plate or the like.

Due to the baking, a reaction of an exposed portion is accelerated, and the sensitivity or the pattern profile is improved.

At least one of the prebake step and the post exposure bake step may include a heating step performed plural times.

Then, as shown in (f) of FIG. 1 which is a schematic sectional view, the second resist film 56 is irradiated with (that is, exposed to) actinic rays or radiation 71 through a mask 61, thereby obtaining a second resist film 57 having undergone exposure (step (F)).

The mask pattern in the mask 61 is not particularly limited, and examples thereof include the same mask as the mask used in the step (B) (for example, a mask which has a line-and-space pattern having a line portion as a light shielding portion and a space portion as a light transmission portion and in which a ratio of a width of the line portion to a width of the space portion is 1:3).

It is preferable that the light shielding portion of the mask 61 is disposed in a position that deviates from the position of the light shielding portion in the step (B) by half pitch (that is, the light shielding portion of the mask 61 is preferably positioned such that the line direction of the first pattern and the line direction of the second pattern ultimately become parallel to each other; more specifically, the light shielding portion of the mask 61 is preferably positioned such that, in a case where the patterns are seen in a direction perpendicular to the substrate, the center line of the space portion of the second pattern and the center line of the line portion of the first pattern coincide with each other). In a case where the light shielding portion of the mask 61 is disposed in such a position, by performing steps (G), (H), and (I) which will be described later, an ultrafine 1:1 line-and-space pattern can be formed.

As an exposure method in the step (F), it is possible to adopt the same method as the method described for the exposure in the step (B).

Then, as shown in (g) of FIG. 1 which is a schematic sectional view, by developing the second resist film 57 having undergone exposure, a second pattern 58 is formed (step (G)).

In the step (G), a developer which can be used in the step of forming the second pattern by developing the second resist film may be an organic developer or an alkali developer. As each of the organic developer and the alkali developer, it is possible to use the same organic developer as described above for the organic developer in the step (C) and, for example, the same alkali developer as described above for the alkali developer in the aforementioned “step of performing development by using an alkali developer” that may be performed between the step (C) and the step (D).

Examples of the step (G) suitably include a step of forming a negative pattern as the second pattern by using a developer containing an organic solvent and a step of forming a positive pattern as the second pattern by using an alkali developer.

As described above, the second pattern 58 may be a negative pattern or a positive pattern. However, it is preferable that the second pattern 58 is a negative pattern, because then an ultrafine space pattern (for example, having a space width of equal to or less than 40 nm) can be reliably formed as described above. It is more preferable that the step (G) is a step of forming a negative pattern as the second pattern by using a developer containing an organic solvent.

The step (G) may include either a step of performing development by using an organic developer or a step of performing development by using an alkali developer. The step (G) may include both of the step of performing development by using an organic developer and the step of performing development by using an alkali developer, and in this case, the order of the development steps is not particularly limited.

As the development method in the step (G), it is possible to use the same development method as described above for the step (C) and, for example, the same development method as described above for the aforementioned “step of performing development by using an alkali developer” that may be performed between the step (C) and the step (D).

The pattern forming method of the present invention may include a step of performing rinsing by using a rinsing liquid (rinsing step) after the step (G). As the rinsing liquid in the rinsing step following the step of performing development by using an organic developer, it is possible to use the same rinsing liquid as described above in the step of performing rinsing by using a rinsing liquid containing an organic solvent (rinsing step) that can be performed after the step (C). As the rinsing liquid in the rinsing step following the step of performing development by using an alkali developer, for example, it is possible to use the same rinsing liquid as described above in the rinsing step which can be performed after the aforementioned “step of performing development by using an alkali developer” that may be performed between the step (C) and the step (D).

Examples of the rinsing treatment method in these rinsing steps include the same rinsing treatment methods as described above.

Then, as shown in (h) of FIG. 1 which is a schematic sectional view, by using the second pattern 58 as a mask, an etching treatment using etching gas 75 or the like is performed on the planarization layer 81 and the first pattern 54, thereby converting the first pattern 54 into a microfabricated pattern 55 (step (H)).

The etching treatment method is not particularly limited, and any of known methods can be used. Various conditions and the like are appropriately determined according to the type of the layer subjected to the etching treatment and the like. For example, etching can be performed based on Proceedings of SPIE (Proc. of SPIE) Vol. 6924, 692420 (2008), JP2009-267112A, and the like.

Herein, an aspect in which at least either the first pattern or the second pattern contains a silicon atom can be suitably exemplified.

This aspect is preferably an aspect in which at least one of the first resist composition or the second resist composition contains a silicon atom (for example, a silicon atom-containing resin), and hence at least one of the first pattern or the second pattern contains a silicon atom (for example, a silicon atom-containing resin).

According to this aspect, by adopting etching conditions under which an etching reaction easily occurs in a film containing a silicon atom or adopting etching conditions under which an etching reaction easily occurs in a film not containing a silicon atom, etching conditions are easily set under which an etching rate of the first pattern becomes sufficiently greater than an etching rate of the second pattern. As a result, the microfabricated pattern 55 formed by the transfer of the shape of the second pattern 58 to the first pattern 54 can be easily formed.

Then, as shown in (i) of FIG. 1 which is a schematic sectional view, the planarization layer 81 and the second pattern 58 are removed (step (I)).

The step (I) is not particularly limited as long as the planarization layer and the second pattern can be removed. The step (I) can be suitably performed by performing one or more kinds of treatment selected from an “etching treatment”, “exposure using a solvent”, and “exposure using an aqueous solution (for example, an acidic aqueous solution or a basic aqueous solution)” on at least one of the planarization layer or the second pattern. That is, the planarization layer and the second pattern may be subjected to the same treatment or different treatments.

In the step (I), it is preferable to remove the planarization layer 81 and the second pattern 58 without damaging the microfabricated pattern 55, that is, to selectively remove the planarization layer 81 and the second pattern 58. Therefore, among the treatments exemplified above, a treatment that makes it possible to selectively remove the planarization layer 81 and the second pattern 58 is preferably adopted.

Considering the above aspect, in a case where the planarization layer 81 is removed by the etching treatment, it is preferable that the step (I) includes a step of performing the etching treatment on the planarization layer 81 under the conditions in which an etching rate of the planarization layer 81 becomes greater than an etching rate of the microfabricated pattern 55.

In a case where the planarization layer 81 is removed by the etching treatment, it is preferable that the step (I) includes a step of performing the etching treatment on the planarization layer 81 under the conditions in which an etching rate of the planarization layer 81 becomes greater than an etching rate of the second pattern 58.

The aforementioned conditions can be established by appropriately adjusting the makeup of each of the first resist composition, the second resist composition, and the composition for forming a planarization layer, the type of etching gas, and the like. As will be described later, it is preferable that the planarization layer 81 is a layer containing a resin having a Onishi parameter of equal to or greater than 4.0, because then the aforementioned conditions are easily established.

Hitherto, the pattern forming method of an embodiment of the present invention has been described. As described in the above embodiment, in the present invention, typically, the first pattern and the second pattern are formed such that the shape of the first pattern seen in a direction perpendicular to the substrate and the shape of the second pattern seen in a direction perpendicular to the substrate do not completely overlap each other.

As described in the above embodiment, it is preferable that both of the first pattern and the second pattern are a line-and-space pattern in which a line width is greater than a space width. Particularly, in this case, it is preferable that the line direction of the first pattern and the line direction of the second pattern are parallel to each other.

The aforementioned embodiment is suitable as an embodiment that makes it possible to easily form an ultrafine pattern (for example, a line-and-space pattern in which both of a line width and a space width are equal to or less than 40 nm).

In the pattern forming method according to the embodiment of the present invention, both of the first pattern and the second pattern are a line-and-space pattern, but the present invention is not limited to this aspect. For example, it is possible to adopt an aspect in which one of the first pattern or the second pattern is a line-and-space pattern and the other is a hole pattern or an aspect in which both of the first pattern and the second pattern are a hole pattern.

In this way, the type, size, and the like of the shape of each of the first pattern and the second pattern can be appropriately selected according to the shape of the microfabricated pattern that is desired to be ultimately formed, and are not specifically limited.

In the aforementioned embodiment of the present invention, after the step (G), another planarization layer may be additionally formed on the planarization layer provided with the second pattern by using the composition for forming a planarization layer, a third resist film may be then formed using a third resist composition on another planarization layer described above, and then a third pattern may be formed by exposing and developing the third resist film. According to this aspect, by performing an etching treatment on the second pattern by using the third pattern as a mask, the second pattern to which the shape of the third pattern is transferred can be formed, and then by performing an etching treatment on the first pattern by using the second pattern, to which the shape of the third pattern is transferred, as a mask, a microfabricated pattern in which the shape of the second pattern and the shape of the third pattern are transferred to the first pattern can be formed.

In this way, in the pattern forming method of the present invention, after the step (G), a series of steps consisting of “forming another planarization layer, forming another resist film, and forming another pattern by exposing and developing the resist film” may be performed once or more.

<First Resist Composition>

Hereinafter, the first resist composition used in the pattern forming method of the present invention will be described.

Typically, the first resist composition is a negative resist composition (more specifically, a negative resist composition for organic solvent development), and a known composition can be used as it. Furthermore, the first resist composition is a typically a chemical amplification-type resist composition.

[1] (A) Resin of which the solubility in developer decreases due to increase in polarity caused by the action of acid

As described above, it is preferable that the first resist composition contains a resin (A) of which the solubility in a developer decreases due to an increase in polarity caused by the action of an acid.

Examples of the resin (A) include a resin having a group, which generates a polar group by being decomposed by the action of an acid (hereinafter, referred to as an “acid-decomposable group” as well), on either or both of a main chain and a side chain of the resin (hereinafter, the resin will be referred to as an “acid-decomposable resin” or a “resin (A)” as well).

It is preferable that the acid-decomposable group has a structure protected with a group that decomposes and eliminates a polar group by the action of an acid.

The polar group is not particularly limited as long as it is a group which is poorly soluble or insoluble in a developer containing an organic solvent, and examples thereof include an acidic group (a group dissociated in an 2.38% by mass aqueous tetramethylammonium hydroxide solution which is used as a resist developer in the related art) such as a phenolic hydroxyl group, a carboxyl group, a fluorinated alcohol group (preferably a hexafluoroisopropanol group), a sulfonic acid group, a sulfonamide group, a sulfonyl imide group, an (alkylsulfonyl) (alkylcarbonyl) methylene group, an (alkylsulfonyl) (alkylcarbonyl) imide group, a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, or a tris(alkylsulfonyl) methylene group, an alcoholic hydroxyl group, and the like.

The alcoholic hydroxyl group refers to a hydroxyl group which is bonded to a hydrocarbon group and other than a hydroxyl group directly bonded to an aromatic ring (phenolic hydroxyl group). The alcoholic hydroxyl group does not include, as a hydroxyl group, an aliphatic alcohol group (for example, a fluorinated alcohol group (such as hexafluoroisopropanol group)) in which the a position is substituted with an electron-withdrawing group such as a fluorine atom. The alcoholic hydroxyl group is preferably a hydroxyl group having a pKa of equal to or greater than 12 and equal to or less than 20.

Examples of the preferred polar group include a carboxyl group, a fluorinated alcohol group (preferably a hexafluoroisopropanol group), and a sulfonic acid group.

As the acid-decomposable group, the groups obtained by substituting a hydrogen atom of the aforementioned groups with a group eliminated by an acid are preferable.

Examples of the group eliminated by an acid include —C(R₃₆)(R₃₇)(R₃₈), —C(R₃₆)(R₃₇)(OR₃₉), —C(R₀₁)(R₀₂)(OR₃₉), and the like.

In the formulae, R₃₆ to R₃₉ each independently represent an alkyl group, a cycloalkyl group, an aryl group, an aralkyl group, or an alkenyl group. R₃₆ and R₃₇ may form a ring by being bonded to each other.

R₀₁ and R₀₂ each independently represent a hydrogen atom, an alkyl group, a cycloalkyl group, an aryl group, an aralkyl group, or an alkenyl group.

The alkyl group as R₃₆ to R₃₉, R₀₁, and R₀₂ is preferably an alkyl group having 1 to 8 carbon atoms, and examples thereof include a methyl group, an ethyl group, a propyl group, a n-butyl group, a sec-butyl group, a hexyl group, an octyl group, and the like.

The cycloalkyl group as R₃₆ to R₃₉, R₀₁, and R₀₂ may be monocyclic or polycyclic. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, a cyclooctyl group, and the like. As the polycyclic cycloalkyl group, a cycloalkyl group having 6 to 20 carbon atoms is preferable, and examples thereof include an adamantly group, a norbornyl group, an isobornyl group, a camphanyl group, a dicyclopentyl group, an α-pinel group, a tricyclodecanyl group, a tetracyclododecyl group, an androstanyl group, and the like. At least one carbon atom in the cycloalkyl group may be substituted with a heteroatom such as an oxygen atom.

The aryl group as R₃₆ to R₃₉, R₀₁, and R₀₂ is preferably an aryl group having 6 to 10 carbon atoms, and examples thereof include a phenyl group, a naphthyl group, an anthryl group, and the like.

The aralkyl group as R₃₆ to R₃₉, R₀₁, and R₀₂ is preferably an aralkyl group having 7 to 12 carbon atoms, and examples thereof include a benzyl group, a phenethyl group, a naphthyl methyl group, and the like.

The alkenyl group as R₃₆ to R₃₉, R₀₁, and R₀₂ is preferably an alkenyl group having 2 to 8 carbon atoms, and examples thereof include a vinyl group, an allyl group, a butenyl group, a cyclohexenyl group, and the like.

The ring formed by the bonding between R₃₆ and R₃₇ is preferably a (monocyclic or polycyclic) cycloalkyl group. The cycloalkyl group is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantly group, more preferably a monocyclic cycloalkyl group having 5 or 6 carbon atoms, and particularly preferably a monocyclic cycloalkyl group having 5 carbon atoms.

The acid-decomposable group is preferably a cumyl ester group, an enol ester group, an acetal ester group, a tertiary alkyl ester group, or the like, and more preferably a tertiary alkyl ester group.

It is preferable that the resin (A) has a repeating unit having an acid-decomposable group.

Furthermore, it is preferable that the resin (A) has, as the repeating unit having an acid-decomposable group, a repeating unit represented by the following Formula (AI). The repeating unit represented by Formula (AI) generates a carboxyl group as a polar group by the action of an acid. A plurality of carboxyl groups highly interact with each other due to hydrogen bonding. Therefore, the formed negative pattern can more reliably become insoluble or poorly soluble in the solvent in the composition for forming a planarization layer (a).

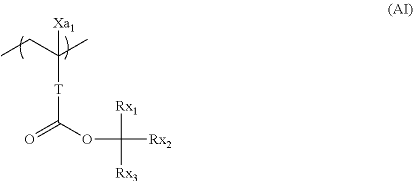

In Formula (AI), Xa₁ represents a hydrogen atom, an alkyl group, a cyano group, or a halogen atom.

T represents a single bond or a divalent linking group.

Rx₁ to Rx₃ each independently represent an alkyl group or a cycloalkyl group.

Two out of Rx₁ to Rx₃ may form a ring structure by being bonded to each other.

Examples of the divalent linking group as T include an alkylene group, a —COO-Rt- group, a —O-Rt- group, a phenylene group, and the like. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group. T is more preferably a single bond.

The alkyl group as Xa₁ may have a substituent, and examples of the substituent include a hydroxyl group and a halogen atom (preferably a fluorine atom).

The alkyl group as Xa₁ preferably has 1 to 4 carbon atoms, and examples thereof include a methyl group, an ethyl group, a propyl group, a hydroxymethyl group, a trifluoromethyl group, and the like. The alkyl group is preferably a methyl group.

Xa₁ is preferably a hydrogen atom or a methyl group.

The alkyl group as Rx₁, Rx₂, and Rx₃ may be branched or cyclic, and preferred examples thereof include a methyl group, an ethyl group, a n-propyl group, an isopropyl group, a n-butyl group, an isobutyl group, a t-butyl group, and the like. The number of carbon atoms of the alkyl group is preferably 1 to 10, and more preferably 1 to 5.

The cycloalkyl group as Rx₁, Rx₂, and Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The ring structure formed by bonding between two out of Rx₁, Rx₂, and Rx₃ is preferably a monocyclic cycloalkane ring such as a cyclopentyl ring or a cyclohexyl ring, or a polycyclic cycloalkane group such as a norbornane ring, a tetracyclodecane ring, a tetracyclododecane ring, or an adamantane ring, and particularly preferably a monocyclic cycloalkane ring having 5 or 6 carbon atoms.

Rx₁, Rx₂, and Rx₃ each independently preferably represent an alkyl group, and more preferably represent a linear or branched alkyl group having 1 to 4 carbon atoms.

Each of the above groups may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, an alkoxycarbonyl group (having 2 to 6 carbon atoms), and the like, and the number of carbon atoms thereof is preferably equal to or less than 8. Among these, from the viewpoint of further improving dissolution contrast in the developer containing an organic solvent before and after acid decomposition, the substituent is more preferably a substituent not having a heteroatom such as an oxygen atom, a nitrogen atom, or a sulfur atom (for example, the substituent is more preferably not an alkyl group substituted with a hydroxyl group), even more preferably a group composed only of a hydrogen atom and a carbon atom, and particularly preferably a linear or branched alkyl group or cycloalkyl group.

It is preferable that, in Formula (AI), Rx₁ to Rx₃ each independently represent an alkyl group, and two out of Rx₁ to Rx₃ do not form a ringstructure by being bonded to each other. In a case where the repeating unit has such a structure, an increase in volume of the group represented by —C(Rx₁)(Rx₂)(Rx₃) that is a group decomposed and eliminated by the action of an acid tends to be able to be inhibited, and in the exposure step and the post exposure bake step which may be performed after the exposure step, the volumetric shrinkage of an exposed portion tends to be able to be inhibited.

Specific examples of the repeating unit represented by Formula (AI) will be shown below, but the present invention is not limited to the specific examples.

In the specific examples, Rx represents a hydrogen atom, CH₃, CF₃, or CH₂OH. Rxa and R×b each independently represent an alkyl group (preferably an alkyl group having 1 to 10 carbon atoms and more preferably an alkyl group having 1 to 5 carbon atoms). Xa₁ represents a hydrogen atom, CH₃, CF₃, or CH₂OH. Z represents a substituent. In a case where there is a plurality of Z's, the plurality of Z's may be the same as or different from each other. p represents 0 or a positive integer. Specific examples and preferred examples of Z are the same as the specific examples and preferred examples of the substituent that each group as Rx₁ to Rx₃ and the like can have.

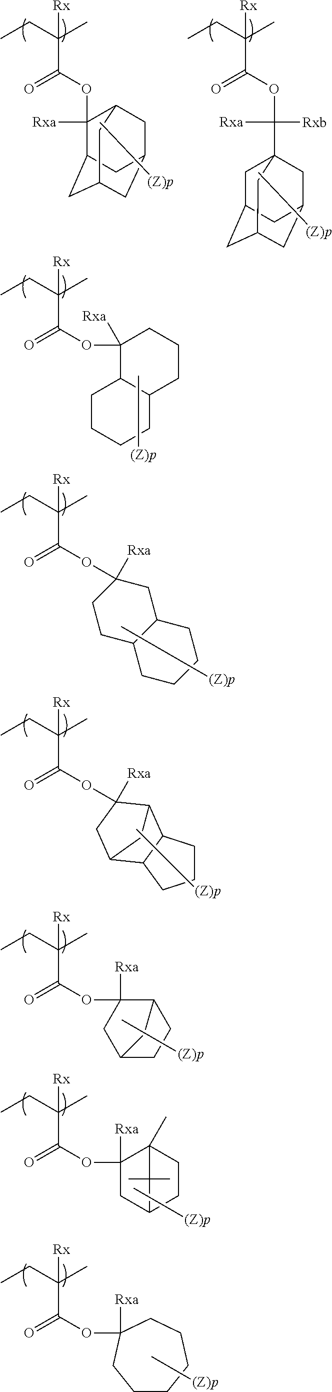

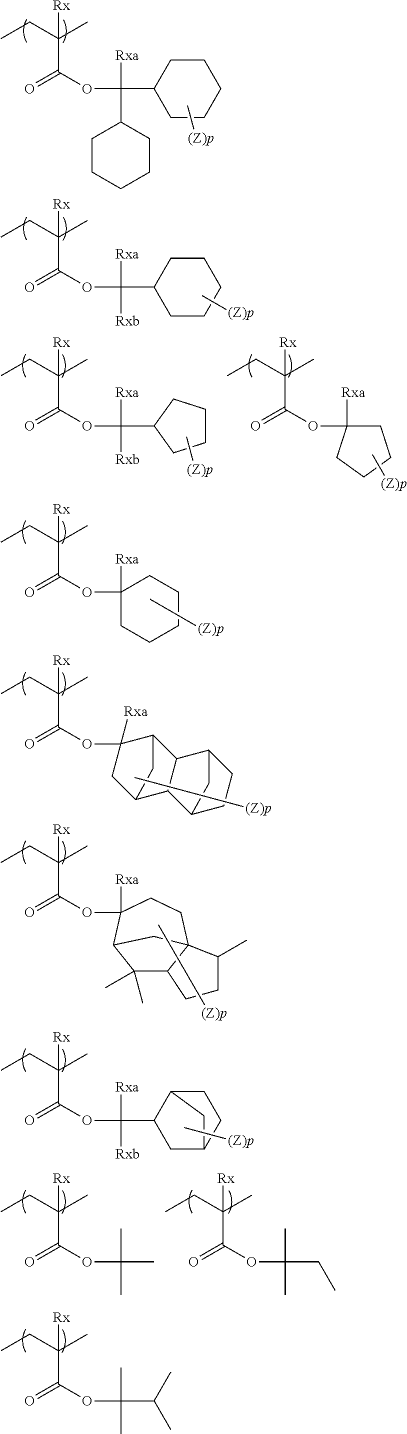

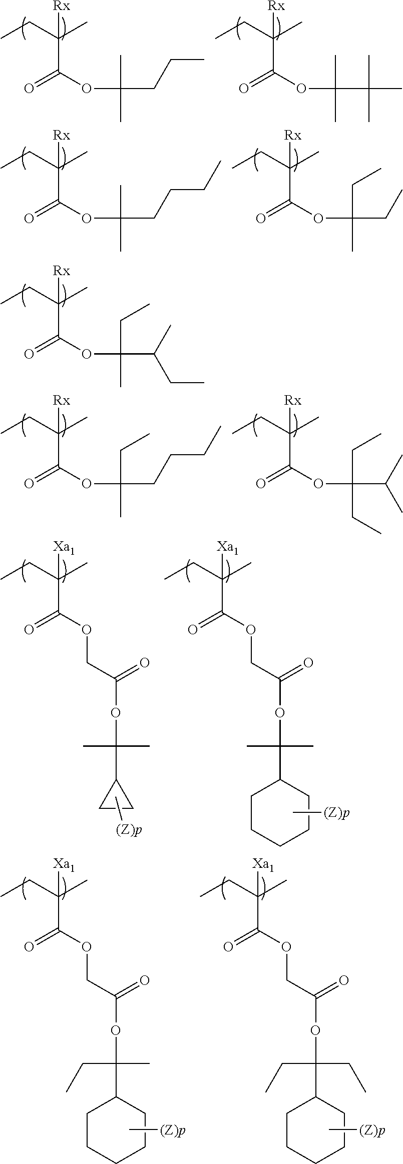

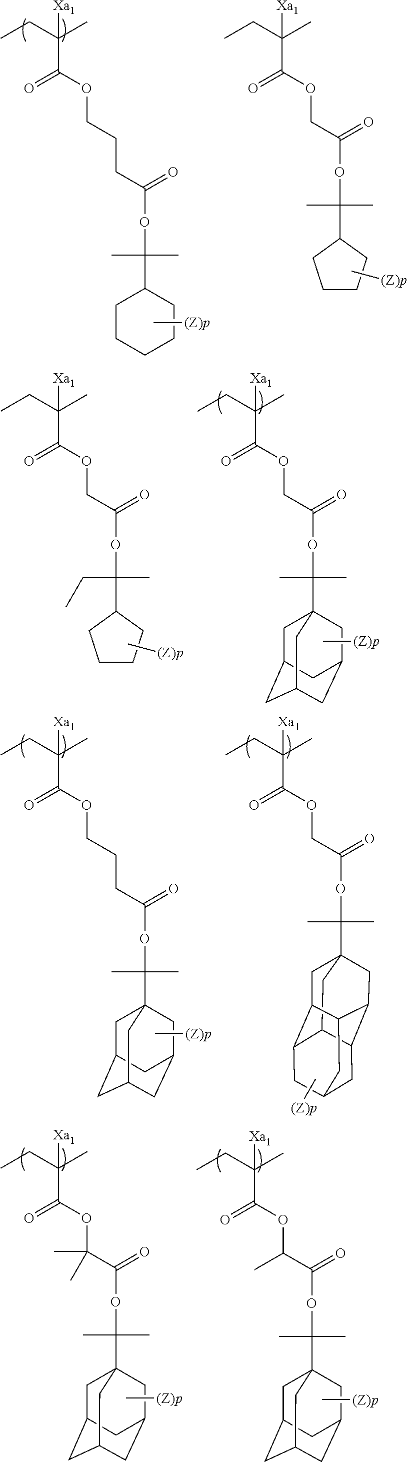

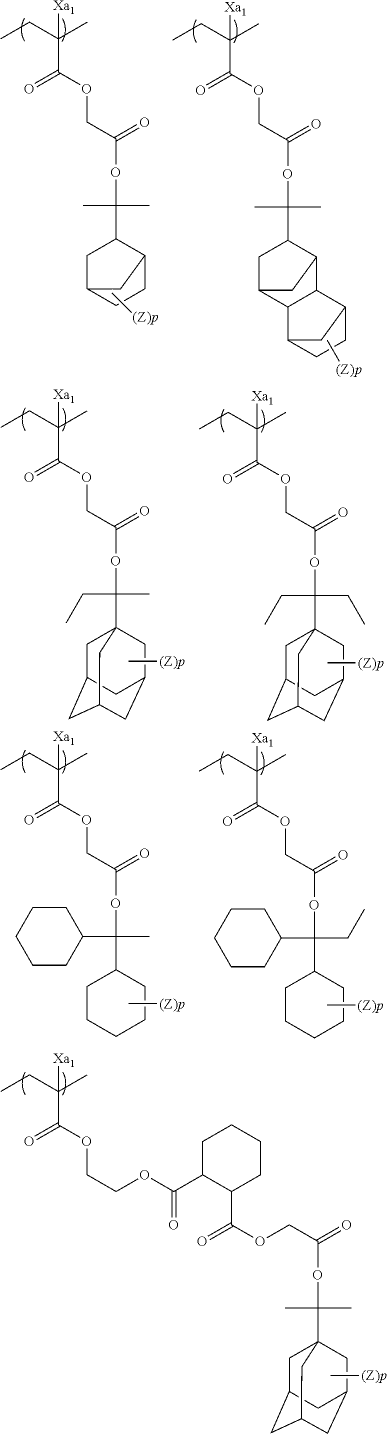

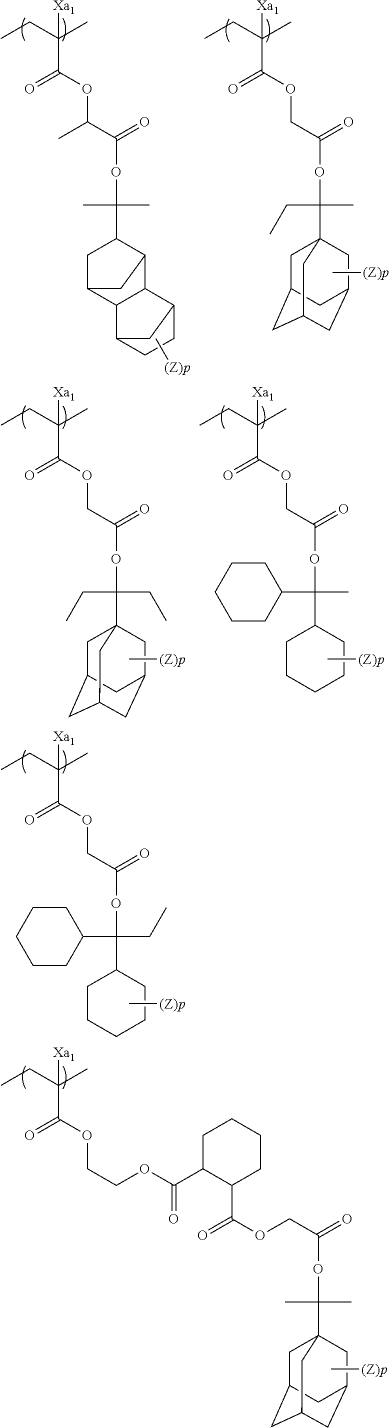

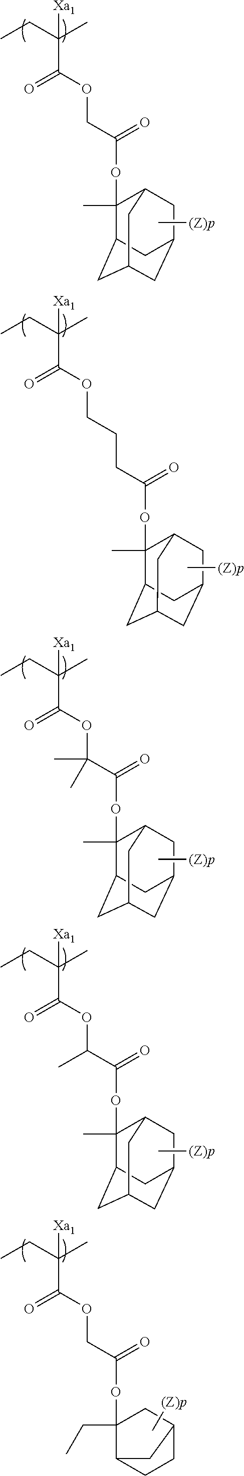

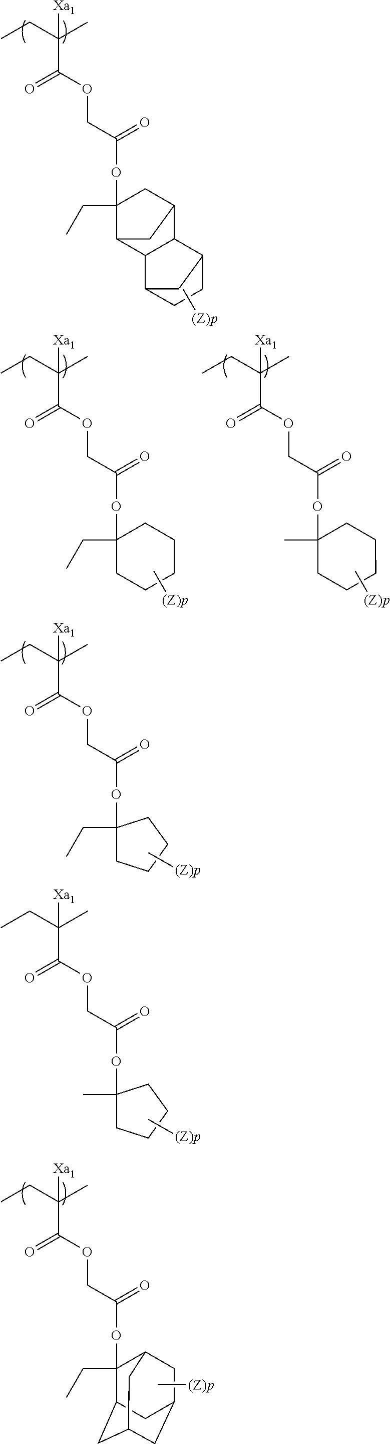

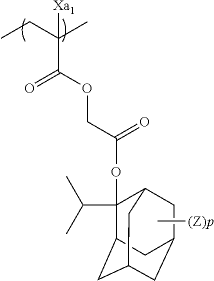

It is also preferable that the resin (A) has, as a repeating unit having an acid-decomposable group, a repeating unit represented by the following Formula (IV).

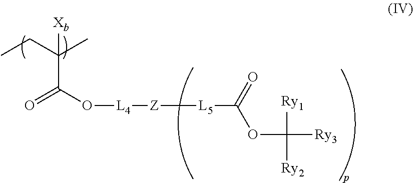

In Formula (IV), X_{b} represents a hydrogen atom, an alkyl group, a cyano group, or a halogen atom.

Ry₁ to Ry₃ each independently represent an alkyl group or a cycloalkyl group. Two out of Ry₁ to Ry₃ may form a ring by being bonded to each other.

Z represents a (p+1)-valent linking group having a polycyclic hydrocarbon structure that may have a heteroatom as a ring member. It is preferable that Z does not contain an ester bond as a atomic group constituting a polycyclic ring (in other words, it is preferable that Z does not contain a lactone ring as a ring constituting a polycyclic ring).

L₄ and L₅ each independently represent represents a single bond or a divalent linking group.

p represents an integer of 1 to 3.

When p is 2 or 3, a plurality of L₅'s, a plurality of Ry₁'s, a plurality of Ry₂'s, and a plurality of Ry₃'s may be the same as or different from each other respectively.

The alkyl group as X_{b} may have a substituent, and examples of the substituent include a hydroxyl group and a halogen atom (preferably a fluorine atom).

The alkyl group as X_{b} preferably has 1 to 4 carbon atoms, and examples thereof include a methyl group, an ethyl group, a propyl group, a hydroxymethyl group, a trifluoromethyl group, and the like. The alkyl group is preferably a methyl group.

X_{b} is preferably a hydrogen atom or a methyl group.

Specific examples and preferred examples of the alkyl group and the cycloalkyl group as Ry₁ to Ry₃ are the same as the specific examples and preferred examples of the alkyl group and the cycloalkyl group as Rx₁ to Rx₃ in Formula (AI).

Specific examples and preferred examples of the ring structure formed by the bonding between two out of Ry₁ to Ry₃ are the same as the specific examples and preferred examples of the ring structure formed by the bonding between two out of Rx₁ to Rx₃ in Formula (AI).

Ry₁ to Ry₃ each independently preferably represent an alkyl group, and more preferably represent a linear or branched alkyl group having 1 to 4 carbon atoms. The total number of carbon atoms of the linear or branched alkyl group as Ry₁ to Ry₃ is preferably equal to or less than 5.

Ry₁ to Ry₃ may further have a substituent, and examples of the substituent are the same as the examples of substituents that Rx₁ to Rx₃ in Formula (AI) may further have.

The linking group as Z having a polycyclic hydrocarbon structure includes a ring-aggregated hydrocarbon ring group and a cross-linked cyclic hydrocarbon ring group, and examples of each of them include a group obtained by removing any (p+1) hydrogen atoms from a ring-aggregated hydrocarbon ring and a group obtained by removing any (p+1) hydrogen atoms from a cross-linked cyclic hydrocarbon ring.

Examples of the ring-aggregated hydrocarbon ring group include a bicyclohexane ring group, a perhydronaphthalene ring group, and the like. Examples of the cross-linked cyclic hydrocarbon ring group include a bicyclic hydrocarbon ring group such as a pinane ring group, a bornane ring group, a norpinane ring group, a norbornane ring group, a bicyclooctane ring group (a bicyclo[2.2.2]octane ring group, a bicyclo[3.2.1]octane ring group, or the like), a tricyclic hydrocarbon ring group such as a homobredane ring group, an adamantane ring group, a tricyclo[5.2.1.0^{2,6}]decane ring group, or a tricyclo[4.3.1.1^{2,5}]undecane ring group, a tetracyclic hydrocarbon ring group such as tetracyclo[4.4.0.1^{2,5}.1^{7,10}]dodecane ring group or a perhydro-1,4-methano-5,8-methanonaphthalene ring group, and the like. The cross-linked cyclic hydrocarbon ring group also includes a condensed cyclic hydrocarbon group, for example, a condensed ring group in which a plurality of 5- to 8-membered cycloalkane ring groups is condensed, such as a perhydronaphthalene (decalin) ring group, a perhydroanthracene ring group, a perhydrophenanthrene ring group, a perhydroacenaphthene ring group, a perhydrofluorene ring group, a perhydroindene ring group, or a perhydrophenalene ring group.

Examples of a preferred cross-linked cyclic hydrocarbon ring group include a norbornane ring group, an adamantane ring group, a bicyclooctane ring group, a tricyclo[5.2.1.0^{2,6}]decane ring group, and the like. Examples of a more preferred cross-linked cyclic hydrocarbon ring group include a norbornane ring group and an adamantane ring group.

The linking group represented by Z having a polycyclic hydrocarbon structure may have a substituent. Examples of the substituent that Z may have include substituents such as an alkyl group, a hydroxyl group, a cyano group, a keto group (an alkylcarbonyl group or the like), an acyloxy group, —COOR, —CON(R)₂, —SO₂R, —SO₃R, and —SO₂N(R)₂. Herein, R represents a hydrogen atom, an alkyl group, a cycloalkyl group, or an aryl group.

The alkyl group, the alkylcarbonyl group, the acyloxy group, —COOR, —CON(R)₂, —SO₂R, —SO₃R, and —SO₂N(R)₂ as the substituents that Z may have may further have a substituent, and examples of the substituent include a halogen atom (preferably a fluorine atom).

In the linking group represented by Z having a polycyclic hydrocarbon structure, the carbon constituting the polycyclic ring (carbon that contributes to the formation of a ring) may be carbonyl carbon. Furthermore, as described above, the polycyclic ring may have, as a ring member, a heteroatom such as an oxygen atom or a sulfur atom. Here, as described above, Z does not contain an ester bond as an atomic group constituting the polycyclic ring.

Examples of the linking group represented by L₄ and L₅ include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), a linking group in which a plurality of the above groups is combined, and the like. Among these, a linking group having 12 or less carbon atoms in total is preferable.

L₄ is preferably a single bond, an alkylene group, —COO—, —OCO—, —CONH—, —NHCO—, -alkylene group-COO—, -alkylene group-OCO—, -alkylene group-CONH—, -alkylene group-NHCO—, —CO—, —O—, —SO₂—, or -alkylene group-O—, and more preferably a single bond, an alkylene group, -alkylene group-COO—, or -alkylene group-O—.

L₅ is preferably a single bond, an alkylene group, —COO—, —OCO—, —CONH—, —NHCO—, —COO— alkylene group-, —OCO-alkylene group-, —CONH— alkylene group-, —NHCO— alkylene group-, —CO—, —O—, —SO₂—, —O-alkylene group-, or —O-cycloalkylene group-, and more preferably a single bond, an alkylene group, —COO— alkylene group-, —O-alkylene group-, or —O-cycloalkylene group-.

In the above description, the bond “—” at the left end means that the group is connected to an ester bond on a main chain side in L₄ and to Z in L₅. The bond “—” at the right end means that the group is bonded to Z in L₄ and to an ester bond connected to a group represented by (Ry₁)(Ry₂)(Ry₃)C— in L₅.

L₄ and L₅ may be bonded to the same atom constituting the polycyclic ring in Z.

p is preferably 1 or 2, and more preferably 1.

Specific examples of the repeating unit represented by Formula (IV) will be shown below, but the present invention is not limited thereto. In the following specific examples, Xa represents a hydrogen atom, an alkyl group, a cyano group, or a halogen atom.

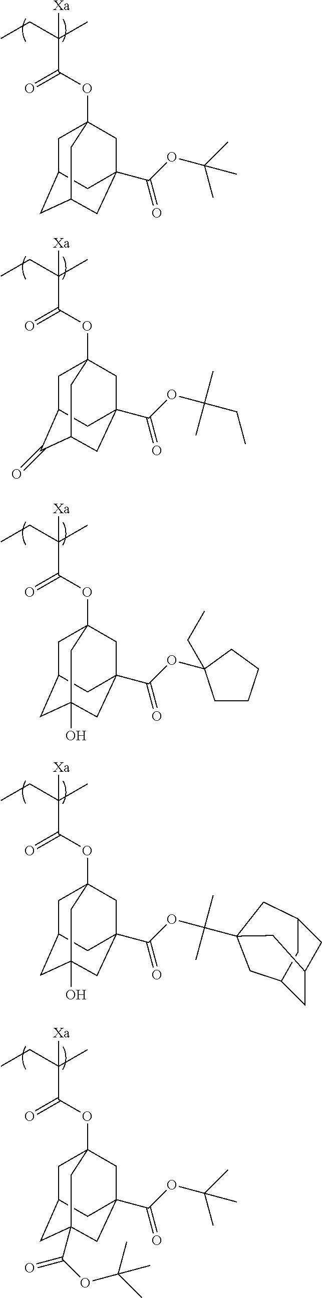

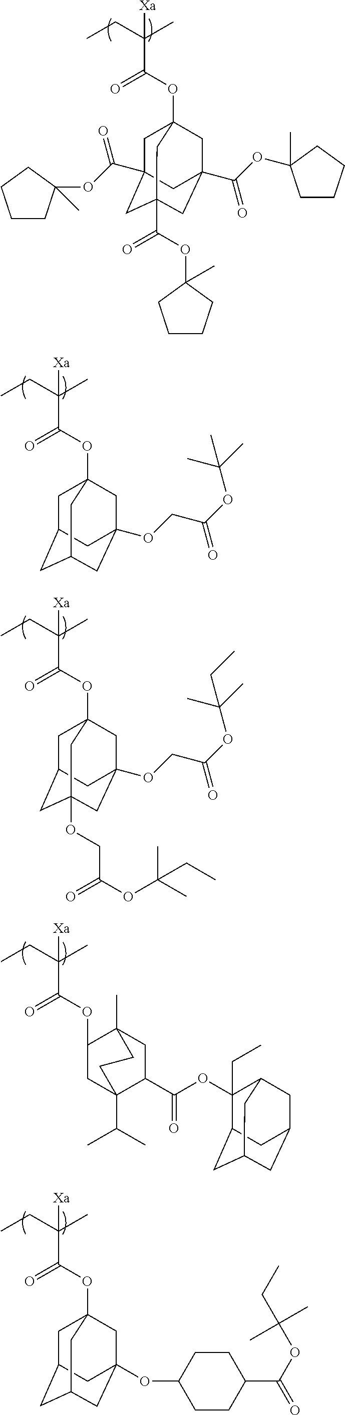

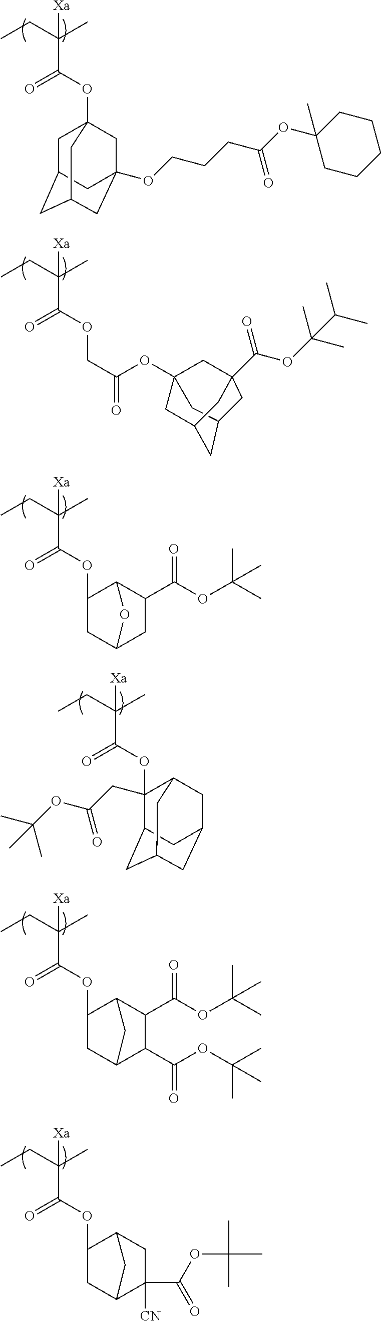

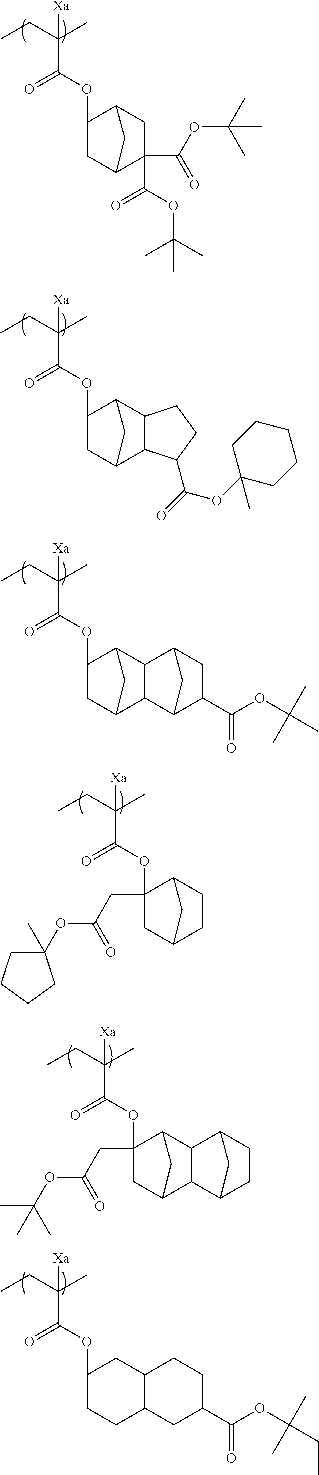

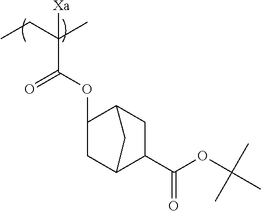

The resin (A) may also have, as a repeating unit having an acid-decomposable group, a repeating unit which is represented by the following formula and generates an alcoholic hydroxyl group by being decomposed by the action of an acid.

In the following specific examples, Xa₁ represents a hydrogen atom, CH₃, CF₃, or CH₂OH.

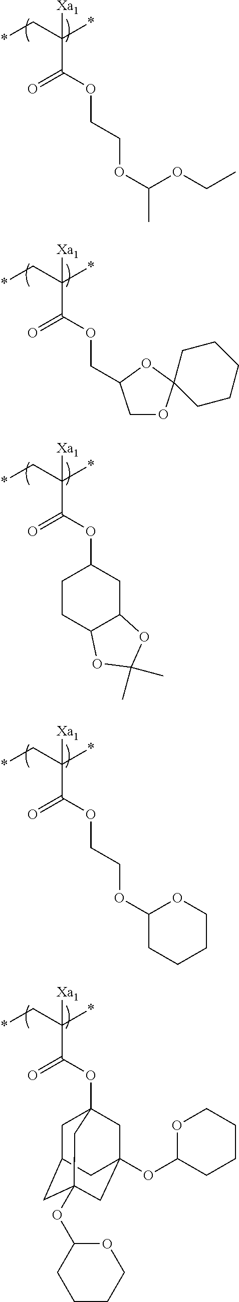

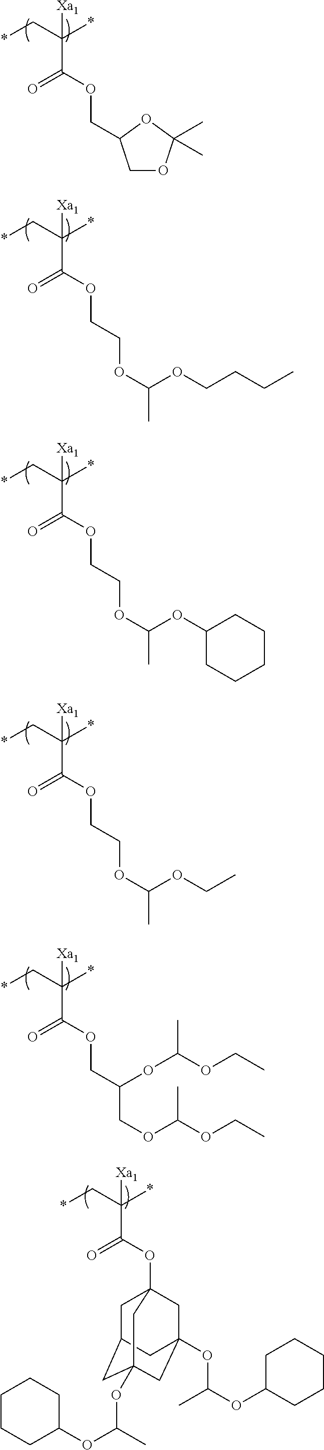

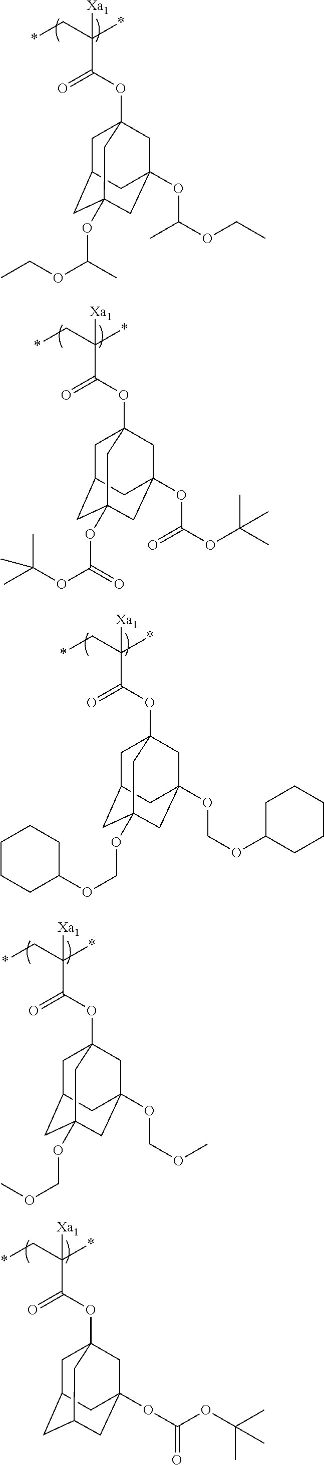

One kind of repeating unit having an acid-decomposable group may be used singly, or two or more kinds thereof may be used in combination.

A content of the repeating unit having an acid-decomposable group that is contained in the resin (A) (in a case where there is a plurality of repeating units having an acid-decomposable group, a total content thereof) is, with respect to all of the repeating units of the resin (A), preferably equal to or greater than 15 mol %, more preferably equal to or greater than 20 mol %, even more preferably equal to or greater than 25 mol %, and particularly preferably equal to or greater than 40 mol %. Particularly, it is preferable that the resin (A) has the repeating unit represented by Formula (AI), and a content of the repeating unit represented by Formula (AI) with respect to all of the repeating units of the resin (A) is equal to or greater than 40 mol %.

In a case where the content of the repeating unit having an acid-decomposable group with respect to all of the repeating units of the resin (A) is equal to or greater than 40 mol %, the resin present in the formed negative pattern has a large amount of polar groups. Consequently, interaction (hydrogen bonding or the like) between the polar groups sufficiently occurs, and hence it is possible to more reliably make the negative pattern insoluble or poorly soluble in the solvent in the composition for forming a planarization layer (a).

The content of the repeating unit having an acid-decomposable group is, with respect to all of the repeating units of the resin (A), preferably equal to or less than 80 mol %, more preferably equal to or less than 70 mol %, and even more preferably equal to or less than 65 mol %.

The resin (A) may also contain a repeating unit having a lactone structure or a sultone structure.

Any of lactone structures or sultone structures can be used as long as they have a lactone structure or a sultone structure. The lactone structure or the sultone structure is preferably a 5- to 7-membered lactone ring structure or a 5- to 7-membered sultone ring structure, and more preferably a structure in which other ring structures are condensed with a 5- to 7-membered lactone ring structure by forming a bicyclo structure or a spiro structure or a structure in which other ring structures are condensed with a 5- to 7-membered sultone ring structure by forming a bicyclo structure or a spiro structure. It is even more preferable that the resin (A) has a repeating unit having a lactone structure represented by any of the following Formulae (LC1-1) to (LC1-21) or a sultone structure represented by any of the following Formulae (SL1-1) to (SL1-3). The lactone structure or the sultone structure may be directly bonded to a main chain. Those represented by (LC1-1), (LC1-4), (LC1-5), (LC1-6), (LC1-13), (LC1-14), and (LC1-17) are preferable as the lactone structure, and a lactone structure represented by (LC1-4) is particularly preferable. In a case where the repeating unit has these specific lactone structures, LER and development defects are improved.

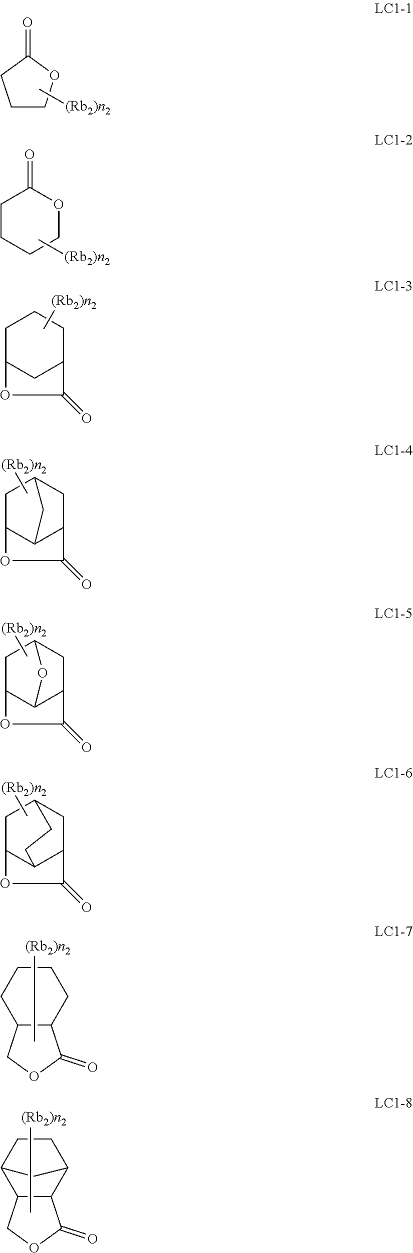

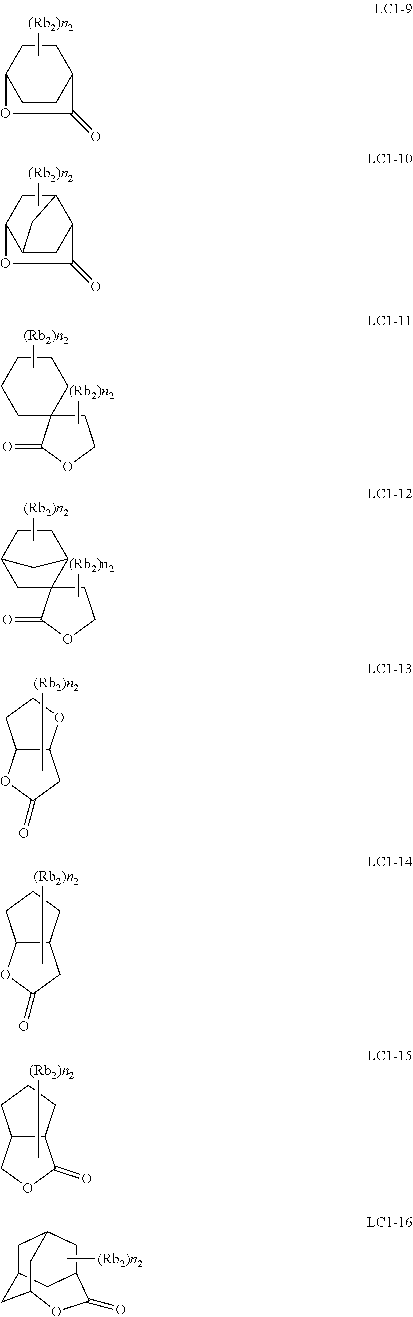

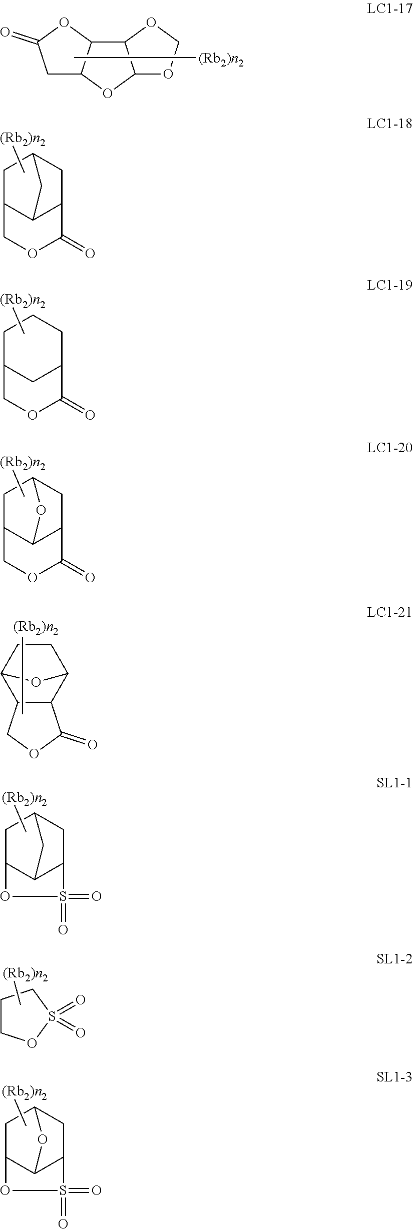

The lactone structure portion or the sultone structure portion may or may not have a substituent (Rb₂). Examples of the preferred substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, and the like. The substituent (Rb₂) is more preferably an alkyl group having 1 to 4 carbon atoms, a cyano group, or an acid-decomposable group. n₂ represents an integer of 0 to 4. When n₂ is equal to or greater than 2, a plurality of substituents (Rb₂) may be the same as or different from each other. Furthermore, a plurality of substituents (Rb₂) may form a ring by being bonded to each other.

Generally, the repeating unit having a lactone structure or a sultone structure has an optical isomer, and any of optical isomers may be used. One kind of optical isomer may be used singly, or a plurality of optical isomers may be used by being mixed together. In a case where 1 kind of optical isomer is mainly used, an optical purity (ee) thereof is preferably equal to or higher than 90% and more preferably equal to or higher than 95%.

The repeating unit having a lactone structure or a sultone structure is preferably a repeating unit represented by the following Formula (III).

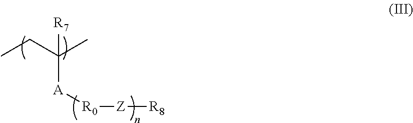

In Formula (III), A represents an ester bond (a group represented by —COO—) or an amide bond (a group represented by —CONH—).

In a case where there is a plurality of R₀'s, R₀ each independently represents an alkylene group, a cycloalkylene group, or a combination of these.

In a case where there is a plurality of Z's, Z each independently represents a single bond, an ether bond, an ester bond, an amide bond, a urethane bond,

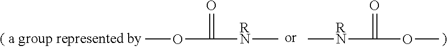

or a urea bond.

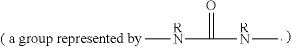

Herein, R each independently represents a hydrogen atom, an alkyl group, a cycloalkyl group, or an aryl group.

R₈ represents a monovalent organic group having a lactone structure or a sultone structure.

n is a repetition number of a structure represented by —R₀—Z— and represents an integer of 0 to 5. n is preferably 0 or 1, and more preferably 0. In a case where n is 0, —R₀—Z— is not present, and a single bond is formed.

R₇ represents a hydrogen atom, a halogen atom, or an alkyl group.

The alkylene group or the cycloalkylene group as R₀ may have a substituent.

Z is preferably an ether bond or an ester bond, and particularly preferably an ester bond.

The alkyl group as R₇ is preferably an alkyl group having 1 to 4 carbon atoms, more preferably a methyl group or an ethyl group, and particularly preferably a methyl group.

The alkylene group or the cycloalkylene group as R₀ and the alkyl group as R₇ may each have a substituent, and examples of the substituent include a halogen atom such as a fluorine atom, a chlorine atom, or a bromine atom, a mercapto group, a hydroxyl group, an alkoxy group such as a methoxy group, an ethoxy group, an isopropoxy group, a t-butoxy group, or a benzyloxy group, and an acyloxy group such as an acetyloxy group or a propionyloxy group.

R₇ is preferably a hydrogen atom, a methyl group, a trifluoromethyl group, or a hydroxymethyl group.

R₀ is preferably a linear alkylene group having 1 to 10 carbon atoms and more preferably a linear alkylene group having 1 to 5 carbon atoms, and examples thereof include a methylene group, an ethylene group, a propylene group, and the like. The cycloalkylene group as R₀ is preferably a cycloalkylene group having 3 to 20 carbon atoms, and examples thereof include a cyclohexylene group, a cyclopentylene group, a norbornylene group, an adamantylene group, and the like. In order to bring about the effects of the present invention, a linear alkylene group is more preferable, and a methylene group is particularly preferable.

The monovalent organic group represented by R₈ having a lactone structure or a sultone structure is not limited as long as it has a lactone structure or a sultone structure, and specific examples thereof include a lactone structure or a sultone structure represented by any of Formulae (LC1-1) to (LC1-21) and (SL1-1) to (SL1-3). Among these, a structure represented by (LC1-4) is particularly preferable. n₂ in (LC1-1) to (LC1-21) is more preferably equal to or less than 2.

R₈ is preferably a monovalent organic group having an unsubstituted lactone structure or sultone structure or a monovalent organic group having a lactone structure or a sultone structure having a methyl group, a cyano group, or an alkoxycarbonyl group as a substituent, and more preferably a monovalent organic group having a lactone structure (cyanolactone) having a cyano group as a substituent.

Specific examples of the repeating unit having a lactone structure or a sultone structure will be shown below, but the present invention is not limited thereto.

(In the formulae, Rx represents H, CH₃, CH₂OH, or CF₃.)

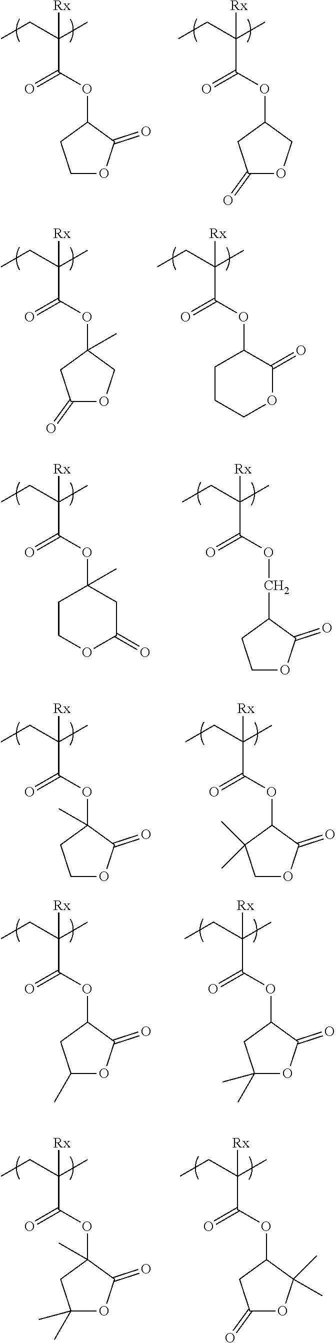

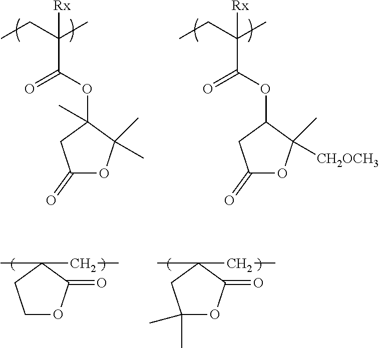

(In the formulae, Rx represents H, CH₃, CH₂OH, or CF₃.)

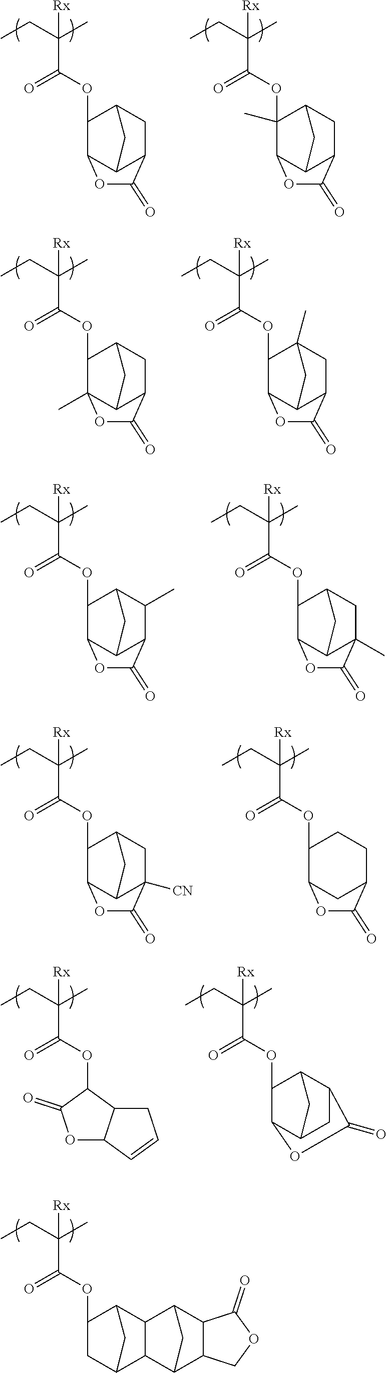

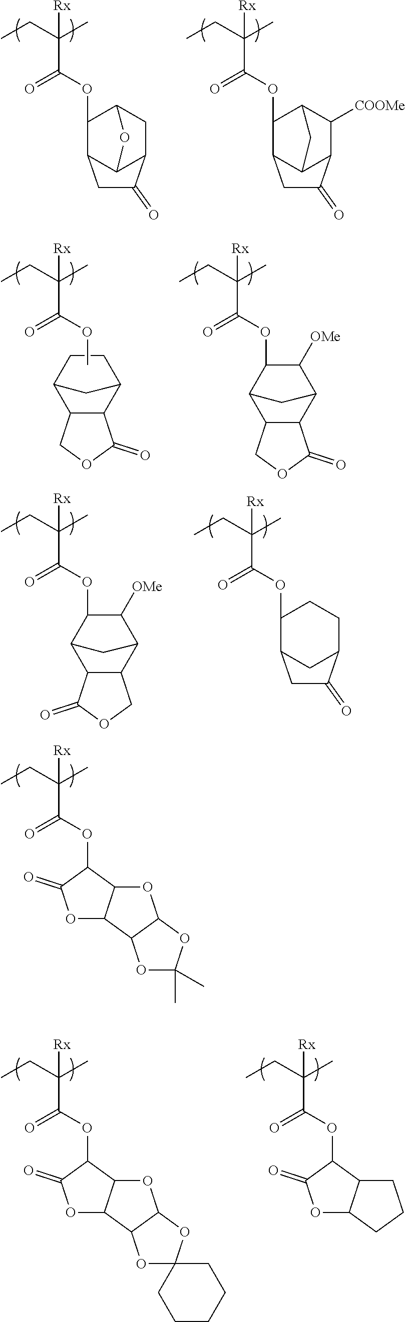

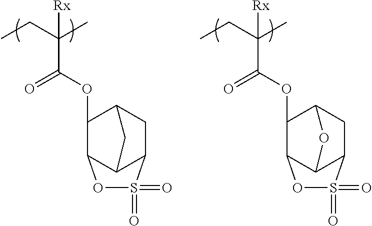

(In the formulae, Rx represents H, CH₃, CH₂OH, or CF₃.)

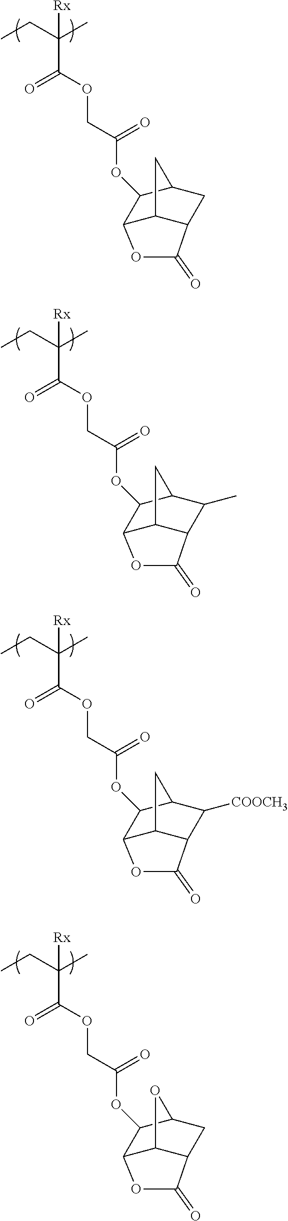

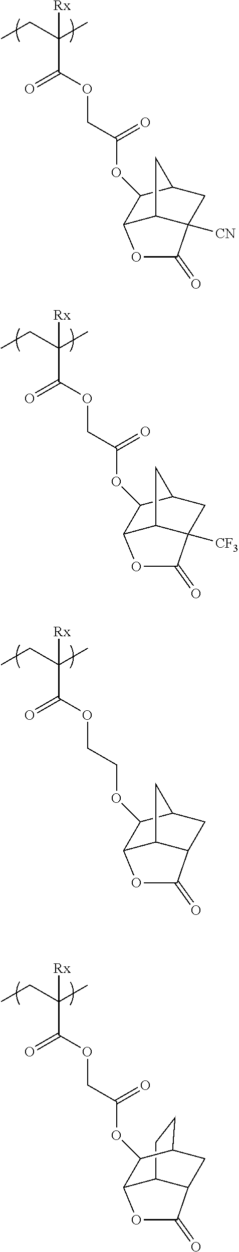

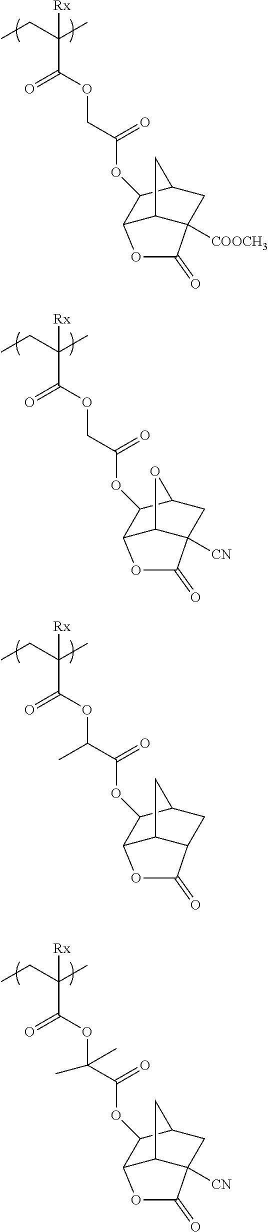

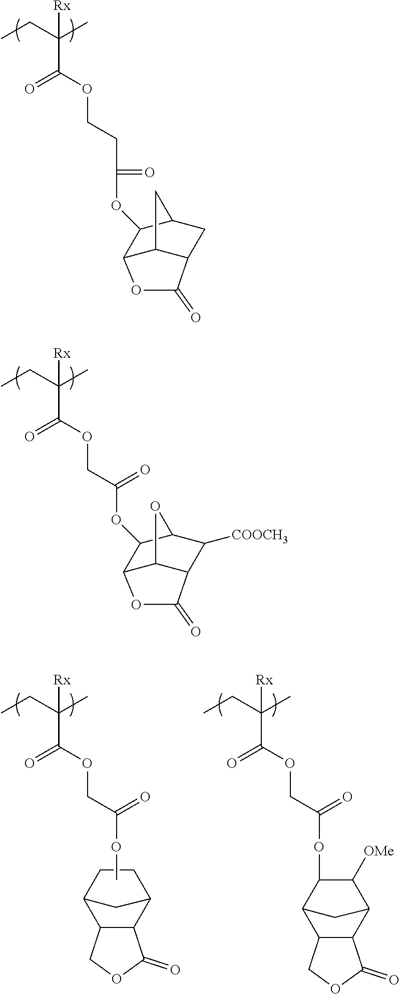

In order to enhance the effects of the present invention, it is possible to use two or more kinds of repeating unit having a lactone structure or a sultone structure in combination.

In a case where the resin (A) has the repeating unit having a lactone structure or a sultone structure, a content of the repeating unit having a lactone structure or a sultone structure is, with respect to all of the repeating units in the resin (A), preferably 5 to 60 mol %, more preferably 5 to 55 mol %, and even more preferably 10 to 50 mol %.

The resin (A) may also have a repeating unit having a cyclic carbonic acid ester structure.

The repeating unit having a cyclic carbonic acid ester structure is preferably a repeating unit represented by the following Formula (A-1).

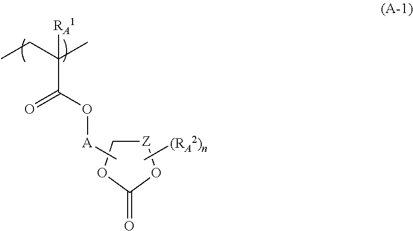

In Formula (A-1), R_{A}¹ represents a hydrogen atom or an alkyl group.

In a case where n is equal to or greater than 2, R_{A}² each independently represents a substituent.

A represents a single bond or a divalent linking group.

Z represents an atomic group which forms a monocyclic or polycyclic structure together with a group represented by —O—C(═O)—O— in the formula.

n represents an integer of equal to or greater than 0.

Formula (A-1) will be specifically described.

The alkyl group represented by R_{A}¹ may have a substituent such as a fluorine atom. R_{A}¹ preferably represents a hydrogen atom, a methyl group, or a trifluoromethyl group, and more preferably represents a methyl group.

The substituent represented by R_{A}² is, for example, an alkyl group, a cycloalkyl group, a hydroxyl group, an alkoxy group, an amino group, or an alkoxycarbonylamino group. R_{A}² is preferably an alkyl group having 1 to 5 carbon atoms, and examples thereof include a linear alkyl group having 1 to 5 carbon atoms such as a methyl group, an ethyl group, a propyl group, or a butyl group; a branched alkyl group having 3 to 5 carbon atoms such as an isopropyl group, an isobutyl group, or a t-butyl group; and the like. The alkyl group may have a substituent such as a hydroxyl group.

n is an integer of equal to or greater than 0 that represents the number of substituents. n is, fore example, preferably 0 to 4, and more preferably 0.

Examples of the divalent linking group represented by A include an alkylene group, a cycloalkylene group, an ester bond, an amide bond, an ether bond, a urethane bond, a urea bond, and a combination of these. The alkylene group is preferably an alkylene group having 1 to 10 carbon atoms, and more preferably an alkylene group having 1 to 5 carbon atoms. Examples thereof include a methylene group, an ethylene group, a propylene group, and the like.

In an aspect of the present invention, A is preferably a single bond or an alkylene group.

Examples of the monocyclic ring containing —O—C(═O)—O— that is represented by Z include a 5- to 7-membered ring in which n_{A}=2 to 4 in a cyclic carbonic acid ester represented by the following Formula (a). The monocyclic ring is preferably a 5-membered or 6-membered ring (n_{A}=2 or 3), and more preferably a 5-membered ring (n_{A}=2).

Examples of the polycyclic ring containing —O—C(═O)—O— that is represented by Z include a structure in which a cyclic carbonic acid ester represented by the following Formula (a) forms a condensed ring or a spiro ring together with one or two or more other rings. The “other rings” that can form a condensed ring or a spiro ring may be an aliphatic hydrocarbon group, an aromatic hydrocarbon group, or a heterocyclic ring.

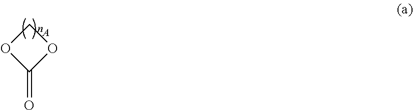

Monomers corresponding to the repeating unit represented by Formula (A-1) are described in, for examples, Tetrahedron Letters, Vol. 27, No. 32 p. 3741 (1986) and Organic Letters, Vol. 4, No. 15 p. 2561 (2002), and can be synthesized by the methods known in the related art.

The resin (A) may contain only one kind among the repeating units represented by Formula (A-1) or contain two or more kinds thereof.

In the resin (A), a content rate of the repeating unit having a cyclic carbonic acid ester structure (preferably the repeating unit represented by Formula (A-1)) is, with respect to all of the repeating units constituting the resin (A), preferably 3 to 80 mol %, more preferably 3 to 60 mol %, particularly preferably 3 to 30 mol %, and most preferably 10 to 15 mol %. In a case where the content rate is within the above range, it is possible to improve the developability, low defectiveness, low LWR, low PEB temperature dependency, profile, and the like of the composition as a resist.

Specific examples of the repeating unit represented by Formula (A-1) (repeating units (A-1a) to (A-1w)) will be shown below, but the present invention is not limited thereto.

In the following specific examples, R_{A}¹ has the same definition as R_{A}¹ in Formula (A-1).

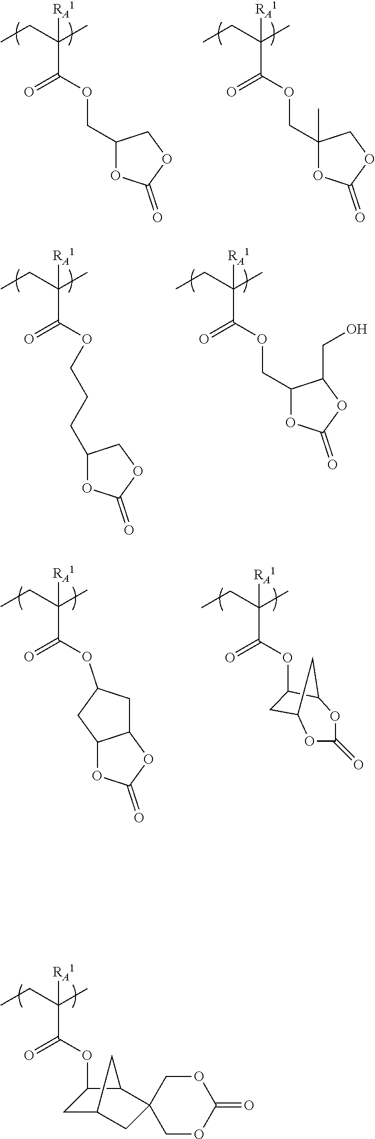

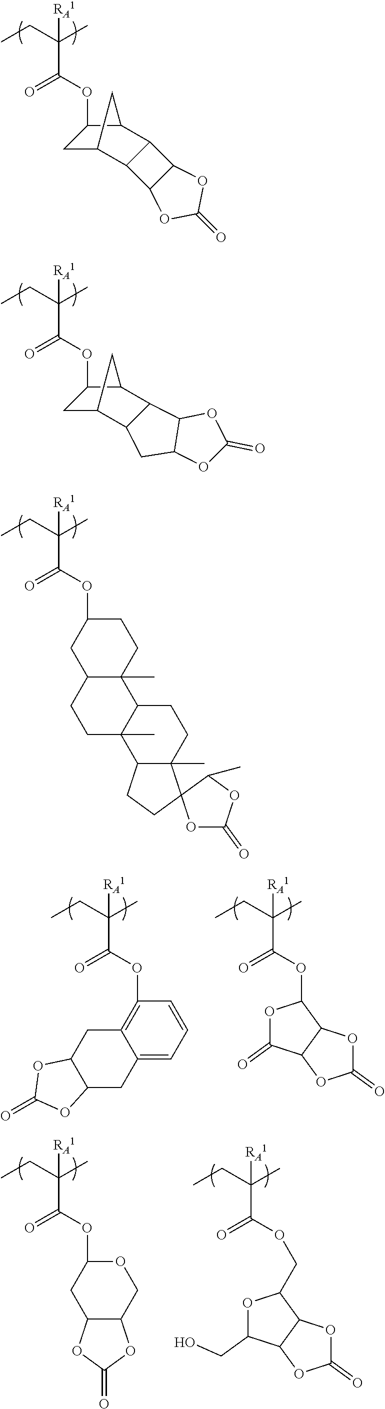

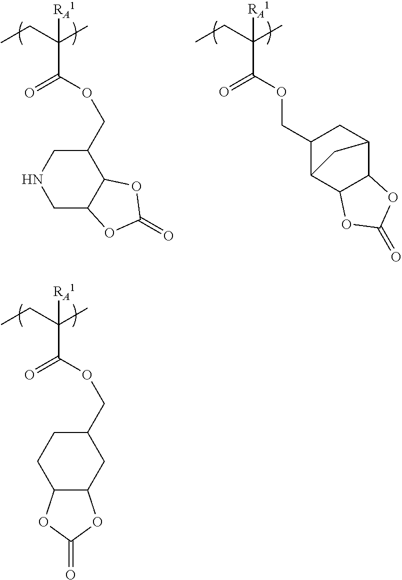

The resin (A) may also have a repeating unit having a hydroxyl group or a cyano group. If the resin (A) has such a repeating unit, the adhesiveness to a substrate and the affinity with a developer are improved. The repeating unit having a hydroxyl group or a cyano group is preferably a repeating unit which has an alicyclic hydrocarbon structure substituted with a hydroxyl group or a cyano group and does not have an acid-decomposable group.

The repeating unit having an alicyclic hydrocarbon structure substituted with a hydroxyl group or a cyano group is preferably different from the repeating unit having an acid-decomposable group (that is, preferably a repeating unit stable against an acid).

In the alicyclic hydrocarbon structure substituted with a hydroxyl group or a cyano group, the alicyclic hydrocarbon structure is preferably an adamantyl group, a diamantyl group, or a norbornane group.

Examples of a more preferred repeating unit include a repeating unit represented by any of the following Formulae (AIIa) to (AIId).

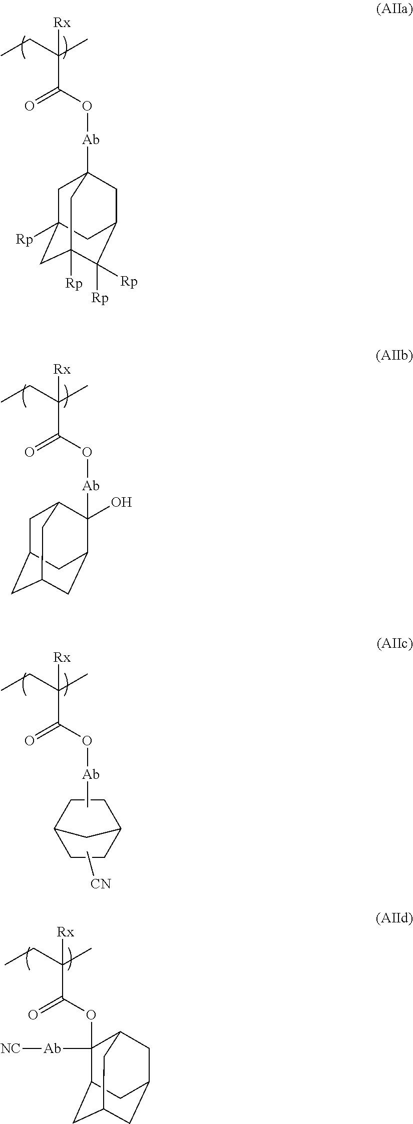

In the formulae, Rx represents a hydrogen atom, a methyl group, a hydroxymethyl group, or a trifluoromethyl group.

Ab represents a single bond or a divalent linking group.

Examples of the divalent linking group represented by Ab include an alkylene group, a cycloalkylene group, an ester bond, an amide bond, an ether bond, a urethane bond, a urea bond, a combination of these, and the like. The alkylene group is preferably an alkylene group having 1 to 10 carbon atoms, and more preferably an alkylene group having 1 to 5 carbon atoms. Examples thereof include a methylene group, an ethylene group, a propylene group, and the like.

In an aspect of the present invention, Ab is preferably a single bond or an alkylene group.

Rp represents a hydrogen atom, a hydroxyl group, or a hydroxyalkyl group.

Although a plurality of Rp's may be the same as or different from each other, at least one of the plurality of Rp's represents a hydroxyl group or a hydroxyalkyl group.

The resin (A) may or may not contain the repeating unit having a hydroxyl group or a cyano group. In a case where the resin (A) contains the repeating unit having a hydroxyl group or a cyano group, a content of the repeating unit having a hydroxyl group or a cyano group is, with respect to all of the repeating units in the resin (A), preferably 1% to 40 mol %, more preferably 3% to 30 mol %, and even more preferably 5% to 25 mol %.

Specific examples of the repeating unit having a hydroxyl group or a cyano group will be shown below, but the present invention is not limited thereto.

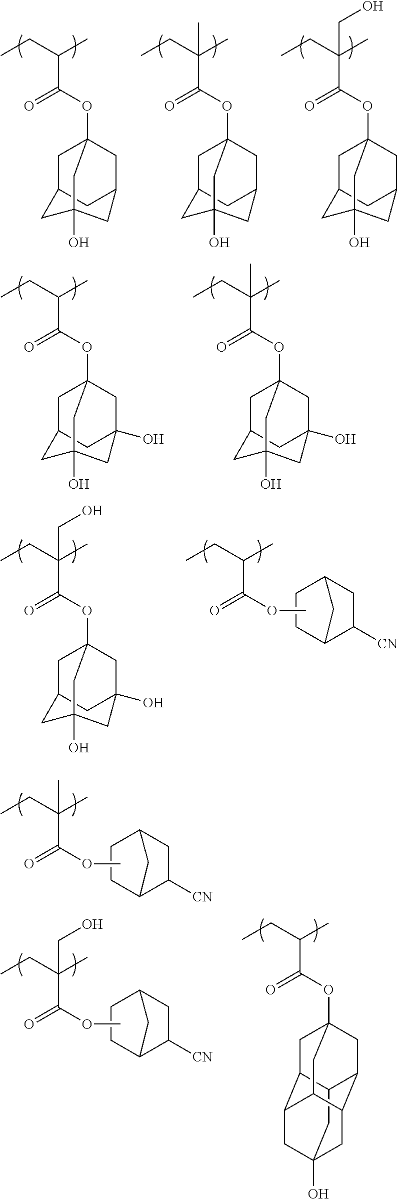

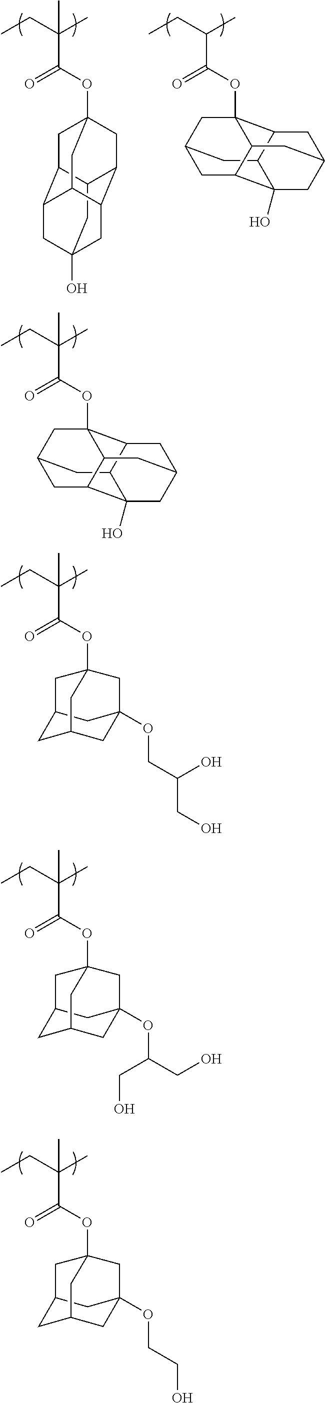

In addition, it is possible to appropriately use the monomers described in WO2011/122336A from paragraph “0011”, repeating units corresponding thereto, and the like.

The resin (A) may also have a repeating unit having an acid group. Examples of the acid group include a carboxyl group, a sulfonamide group, a sulfonylimide group, a bissulfonylimide group, a naphthol structure, and an aliphatic alcohol group (for example, hexafluoroisopropanol group) in which the a position is substituted with an electron-withdrawing group. The resin (A) more preferably has a repeating unit having a carboxyl group. In a case where the resin (A) contains the repeating unit having an acid group, resolution thereof used for contact holes is improved. As the repeating unit having an acid group, all of a repeating unit in which an acid group is directly bonded to a main chain of a resin, such as a repeating unit composed of an acrylic acid or a methacrylic acid, a repeating unit in which an acid group is bonded to a main chain of a resin through a linking group, and a repeating unit introduced into a terminal of a polymer by using a polymerization initiator or a chain transfer agent having an acid group at the time of polymerization are preferable. The linking group may have a monocyclic or polycyclic hydrocarbon structure. Among the above, a repeating unit composed of an acrylic acid or a methacrylic acid is particularly preferable.

The resin (A) may or may not contain the repeating unit having an acid group. In a case where the resin (A) contain the repeating unit having an acid group, a content of the repeating unit is, with respect to all of the repeating units in the resin (A), preferably equal to or less than 25 mol %, and more preferably equal to or less than 20 mol %. In a case where the resin (A) contains the repeating unit having an acid group, the content of the repeating unit having an acid group in the resin (A) is generally equal to or greater than 1 mol %.

Specific examples of the repeating unit having an acid group will be shown below, but the present invention is not limited thereto.

In the specific examples, Rx represents H, CH₃, CH₂OH, or CF₃.

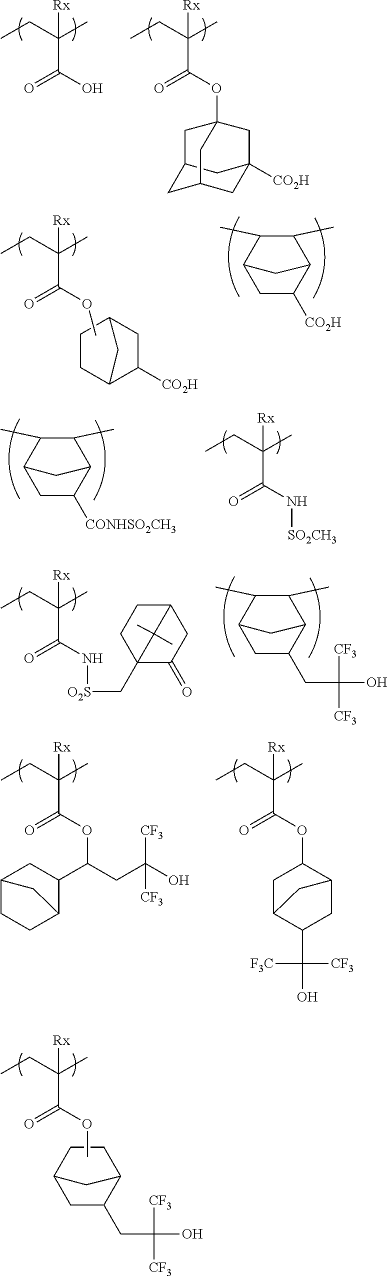

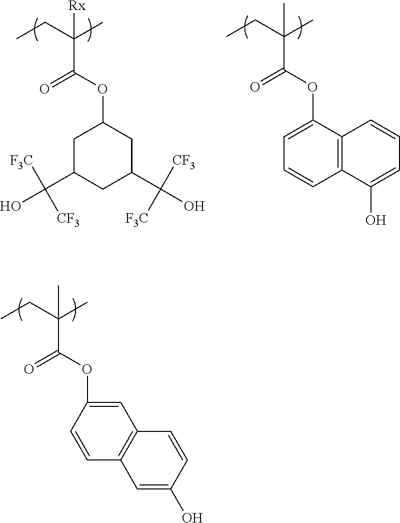

In the present invention, the resin (A) can further have a repeating unit which has an alicyclic hydrocarbon structure not having a polar group (for example, the aforementioned acid group, a hydroxyl group, or a cyano group) and is not decomposed by an acid. In a case where the resin (A) has such a repeating unit, it is possible to reduce the elution of low-molecular weight components to an immersion liquid from the resist film at the time of liquid immersion exposure and to appropriately adjust the solubility of the resin at the time of development using a developer containing an organic solvent. Furthermore, it is possible to improve dry etching resistance. Examples of such a repeating unit include a repeating unit represented by Formula (IV).

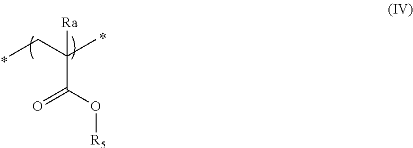

In Formula (IV), R₅ represents a hydrocarbon group which has at least one cyclic structure and does not have a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

The cyclic structure that R₅ has include a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group, or a cyclooctyl group, and a cycloalkenyl group having 3 to 12 carbon atoms such as a cyclohexenyl group. The monocyclic hydrocarbon group is preferably a monocyclic hydrocarbon group having 3 to 7 carbon atoms, and more preferably, for example, a cyclopentyl group or a cyclohexyl group.

The polycyclic hydrocarbon group include a ring-aggregated hydrocarbon group and a cross-linked cyclic hydrocarbon group. Examples of the ring-aggregated hydrocarbon group include a bicyclohexyl group, perhydronaphthalenyl group, and the like. Examples of the cross-linked cyclic hydrocarbon group include a bicyclic hydrocarbon ring such as pinane, bornane, norpinane, norbornane, a bicyclooctane ring (a bicyclo[2.2.2]octane ring, a bicyclo[3.2.1]octane ring, or the like), a tricyclic hydrocarbon ring such as homobredane, adamantane, tricyclo[5.2.1.0^{2,6}]decane, or a tricyclo[4.3.1.1^{2,5}]undecane ring, a tetracyclic hydrocarbon ring such as tetracyclo[4.4.0.1^{2,5}.1^{7,10}]dodecane or perhydro-1,4-methano-5,8-methanonaphthalene ring, and the like. The cross-linked cyclic hydrocarbon group also includes a condensed cyclic hydrocarbon ring, for example, a condensed ring in which a plurality of 5- to 8-membered cycloalkane rings is condensed, such as perhydronaphthalene (decalin), perhydroanthracene, perhydrophenanthrene, perhydroacenaphthene, perhydrofluorene, perhydroindene, or a perhydrophenalene ring.

Examples of a preferred cross-linked cyclic hydrocarbon group include a norbornyl group, an adamantyl group, a bicyclooctanyl group, a tricyclo[5.2.1.0^{2,6}]decanyl group, and the like. Examples of a more preferred cross-linked cyclic hydrocarbon group include a norbornyl group and an adamantyl group.

These cross-linked cyclic hydrocarbon groups may have a substituent, and examples of a preferred substituent include a halogen atom, an alkyl group, a hydroxyl group in which a hydrogen atom is substituted, an amino group in which a hydrogen atom is substituted, and the like. Examples of a preferred halogen atom include bromine, chlorine, and fluorine atoms, and examples of a preferred alkyl group include a methyl group, an ethyl group, a n-butyl group, and a t-butyl group. The above alkyl group may further have a substituent, and examples of the substituent that the alkyl group may further have include a halogen atom, an alkyl group, a hydroxyl group in which a hydrogen atom is substituted, and an amino group in which a hydrogen atom is substituted.

Examples of the aforementioned substituent of a hydrogen atom include an alkyl group, a cycloalkyl group, an aralkyl group, a substituted methyl group, a substituted ethyl group, an alkoxycarbonyl group, and an aralkyloxycarbonyl group. Examples of the preferred alkyl group include an alkyl group having 1 to 4 carbon atoms. Examples of the preferred substituted methyl group include a methoxymethyl, methoxythiomethyl, benzyloxymethyl, t-butoxymethyl, or 2-methoxyethoxymethyl group. Examples of the preferred substituted ethyl group include 1-ethoxyethyl and 1-methyl-1-methoxyethyl. Examples of the preferred acyl group include an aliphatic acyl group having 1 to 6 carbon atoms such as a formyl, acetyl, propionyl, butyryl, isobutyryl, valeryl, or pivalolyl group. Examples of the alkoxycarbonyl group include an alkoxycarbonyl group having 1 to 4 carbon atoms and the like.

The resin (A) may or may not contain the repeating unit which has an alicyclic hydrocarbon structure not having a polar group and is not decomposed by an acid. In a case where the resin (A) contains such a repeating unit, a content of the repeating unit is, with respect to all of the repeating units in the resin (A), preferably 1 to 50 mol %, and more preferably 5 to 50 mol %.

Specific examples of the repeating unit which has an alicyclic hydrocarbon structure not having a polar group and is not decomposed by an acid will be shown below, but the present invention is not limited thereto. In the formulae, Ra represents H, CH₃, CH₂OH, or CF₃.

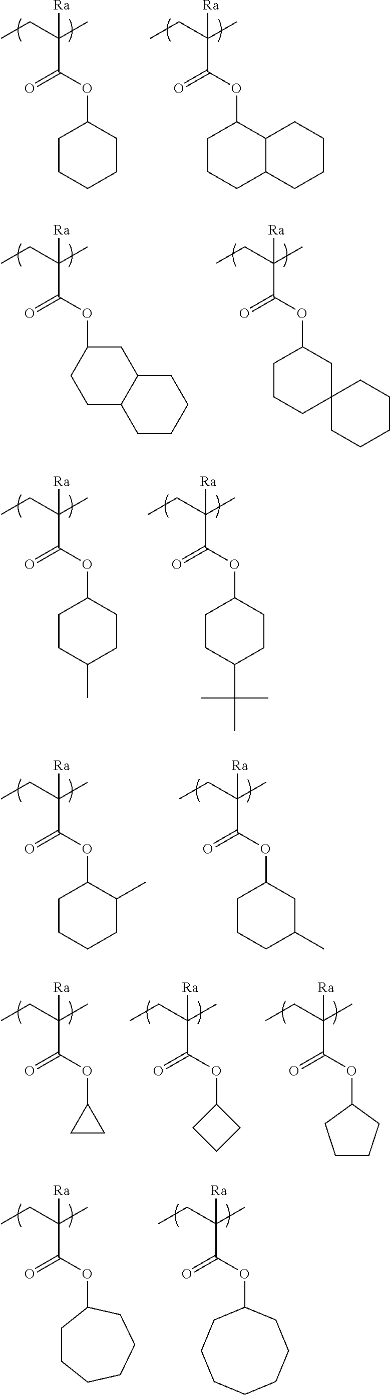

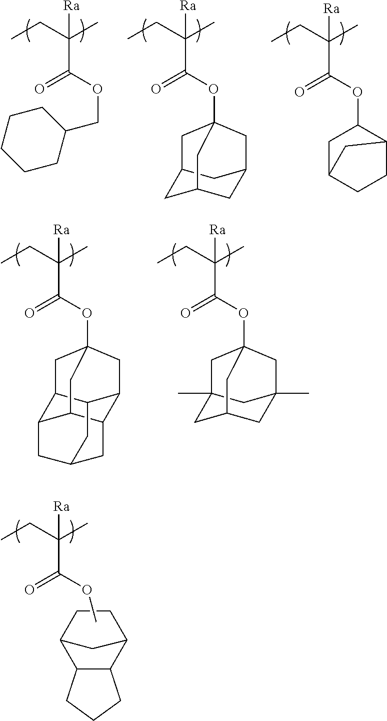

For the purpose of controlling the dry etching resistance, suitability for a standard developer, adhesiveness to a substrate, and resist profile as well as the resolving power, heat resistance, sensitivity, and the like which are characteristics generally required for the first resist composition, the resin (A) used in the composition of the present invention can have various repeating structural units in addition to the aforementioned repeating structural units.

Examples of such repeating structural units include, but are not limited to, repeating structural units corresponding to the following monomers.

In a case where the resin (A) contains the following monomers, the performances required for the resin used in the composition according to the present invention, particularly, (1) solubility in a coating solvent, (2) film formability (glass transition point), (3) alkali developability, (4) film thinning (hydrophilicity, hydrophobicity, and selection of an alkali-soluble group), (5) adhesiveness of an unexposed portion to a substrate, (6) dry etching resistance, and the like can be finly adjusted.

Examples of such monomers include a compound having one addition-polymerizable unsaturated bond selected from acrylic acid esters, methacrylic acid esters, acrylamides, methacrylamides, an allyl compound, vinyl ethers, and vinyl esters, and the like.

In addition, other addition-polymerizable unsaturated compounds can be copolymerized with the monomers corresponding to the aforementioned various repeating structural units as long as the compounds can be copolymerized with the monomers.

In the resin (A) used in the composition of the present invention, a molar ratio of each repeating structural unit contained is appropriately set so as to control the dry etching resistance, suitability for a standard developer, adhesiveness to a substrate, and resist profile of the first resist composition as well as the resolving power, heat resistance, sensitivity, and the like which are characteristics generally required for the first resist composition.

When the composition of the present invention is for ArF exposure, in view of transparency with respect to ArF light, it is preferable that the resin (A) used in the composition of the present invention substantially does not have an aromatic ring (specifically, a proportion of a repeating unit having an aromatic group in the resin is preferably equal to or less than 5 mol %, more preferably equal to or less than 3 mol %, and ideally 0 mol %; that is, it is preferable that the resin does not have an aromatic group), and has a monocyclic or polycyclic hydrocarbon structure.

The resin (A) in the present invention may have any of a random shape, a block shape, a comb shape, and a star shape. The resin (A) can be synthesized by, for example, the radical, cationic, or anionic polymerization of an unsaturated monomer corresponding to each structure. Furthermore, by polymerizing an unsaturated monomer corresponding to a precursor of each structure and then causing a polymer reaction, an intended resin can be obtained.

In a case where the composition of the present invention contains a resin (D) which will be described later, from the viewpoint of compatibility with the resin (D), it is preferable that the resin (A) does not contain a fluorine atom and a silicon atom.

As the resin (A) used in the composition of the present invention, a resin in which all of the repeating units are constituted with a (meth)acrylate-based repeating unit is preferable. In this case, it is possoble to use all of a resin in which all of the repeating units are methacrylate-based repeating units, a resin in which all of the repeating units are acrylate-based repeating units, and a resin in which all of the repeating units are methacrylate-based repeating units and acrylate-based repeating units. It is preferable that a proportion of the acrylate-based repeating units is preferably equal to or less than 50 mol % with respect to all of the repeating units.

In a case where the composition of the present invention is irradiated with KrF excimer laser light, electron beams, X-rays, or high-energy beams (EUV or the like) having a wavelength of equal to or less than 50 nm, it is preferable that the resin (A) further has a hydroxystyrene-based repeating unit. It is more preferable that the resin (A) has a hydroxystyrene-based repeating unit and an acid-decomposable repeating unit such as a hydroxystyrene-based repeating unit protected with an acid-decomposable group or a (meth)acrylic acid tertiary alkyl ester.

Examples a preferred hydroxystyrene-based repeating unit having an acid-decomposable group include a repeating unit composed of t-butoxycarbonyloxystyrene, 1-alkoxyethoxystyrene, or a (meth)acrylic acid tertiary alkyl ester, and the like. As the above repeating unit, repeating units composed of 2-alkyl-2-adamantyl (meth)acrylate and dialkyl(1-adamantyl) methyl (meth)acrylate are more preferable.

The resin (A) in the present invention can be synthesized according to a common method (for example, radical polymerization). Examples of the general synthesis method include a batch polymerization method in which polymerization is performed by dissolving a monomer species and an initiator in a solvent and heating the solution, a dropping polymerization method in which a solution containing a monomer species and an initiator is added dropwise to a heated solvent for 1 to 10 hours, and the like. Among these, a dropping polymerization method is preferable. Examples of the reaction solvent include ethers such as tetrahydrofuran, 1,4-dioxane, and diisopropyl ether, ketones such as methyl ethyl ketone and methyl isobutyl ketone, an ester solvent such as ethyl acetate, an amide solvent such as dimethyl formamide or a dimethyl acetamide, and a solvent dissolving the composition of the present invention such as propylene glycol monomethyl ether acetate, propylene glycol monomethyl ether, or cyclohexanone which will be descried later. It is more preferable to perform polymerization by using the same solvent as the solvent used in the composition of the present invention. In a case where such a solvent is used, the occurrence of particles at the time of storage can be inhibited.

It is preferable to perform the polymerization reaction in an atmosphere of inert gas such as nitrogen or argon. The polymerization is initiated using a commercially available radical initiator (an azo-based initiator, a peroxide, or the like) as a polymerization initiator. As the radical initiator, an azo-based initiator is preferable, and as the azo-based initiator, an azo-based initiator having an ester group, a cyano group, or a carboxyl group is preferable. Examples of a preferred initiator include azobisisobutyronitrile, azobisdimethylvaleronitrile, dimethyl 2,2′-azobis(2-methylpropionate), and the like. The initiator is added as desired or added in divided portions, the resultant is added to a solvent after the reaction ends, and a desired polymer is collected by a method such as collecting powder or a solid. A concentration of the reaction is 5% to 50% by mass and preferably 10% to 30% by mass. A reaction temperature is generally 10° C. to 150° C., preferably 30° C. to 120° C., and even more preferably 60° C. to 100° C.

After the reaction ends, the reaction solution is left to cool to room temperature, followed by purification. For the purification, it is possible to use a general method such as a liquid-liquid extraction method in which a residual monomer or an oligomer component is removed rinsing or by using appropriate solvents in combination, a purification method performed in a solution state such as ultrafiltration in which only a component having a molecular weight equal to or less than a certain molecular weight is extracted and removed, a re-precipitation method in which a residual monomer or the like is removed by coagulating the resin in a poor solvent by adding the resin solution dropwise to the poor solvent, or a purification method performed in a solid state in which the resin slurry separated by filtration is washed with a poor solvent.

For example, by bringing the reaction solution into contact with a solvent (poor solvent), in which the resin is poorly soluble or insoluble, in a volumetric amount of no greater than 10 times the amount of the reaction solution and preferably in a volumetric amount of 5 to 10 times the amount of the reaction solution, the resin is precipitated as a solid.

The solvent (a precipitation or re-precipitation solvent) used at the time of the operation of precipitating or re-precipitating the polymer from the polymer solution should be a poor solvent of the polymer, and can be used by being appropriately selected from hydrocarbon, halogenated hydrocarbon, a nitro compound, an ether, a ketone, an ester, a carbonate, an alcohol, a carboxylic acid, water, a mixed solvent containing these solvents, and the like according to the type of the polymer. Among these, as the precipitation or re-precipitation solvent, a solvent that contains at least an alcohol (particularly, methanol or the like) or water is preferable.

An amount of the precipitation or re-precipitation solvent used can be appropriately selected in consideration of efficiency, yield, or the like. Generally, the amount is, with respect to 100 parts by mass of the polymer solution, 100 to 10,000 parts by mass, preferably 200 to 2,000 parts by mass, and even more preferably 300 to 1,000 parts by mass.

A temperature at the time of causing precipitation or re-precipitation can be appropriately selected in consideration of efficiency, operation properties, and the like. Generally, the temperature is about 0° C. to 50° C., and preferably close to a room temperature (for example, about 20° C. to 35° C.). The precipitation or re-precipitation operation can be performed by a known method such as a batch method or continuous method by using a generally used mixing container such as a stirred tank.

Usually, the precipitated or re-precipitated polymer is used after being subjected to a general solid-liquid separation process such as filtration or centrifugation and drying. The filtration is performed using a solvent-resistant filter medium preferably under pressure. The drying is performed under normal pressure or reduced pressure (preferably under reduced pressure) at a temperature of about 30° C. to 100° C. and preferably of about 30° C. to 50° C.

After being precipitated and separated once, the resin may be dissolved again in a solvent and brought into contact with a solvent in which the resin is poorly soluble or insoluble. That is, a method may be used which includes a step of precipitating a resin by bringing the polymer solution into contact with a solvent, in which the polymer is poorly soluble or insoluble, after the aforementioned radical polymerization reaction ends (step a), a step of separating the resin from the solution (step b), a step of preparing a resin solution A by dissolving again the resin in a solvent (step c), a step of then precipitating a resin solid by bringing the resin solution A into contact with a solvent, in which the resin is poorly soluble or insoluble, in a volumetric amount of less than 10 times the amount of the resin solution A (preferably in a volumetric amount of no greater than 5 times the amount of the resin solution A) (step d), and a step of separating the precipitated resin (step e).

In order to inhibit the resin from being aggregated after the composition is prepared, for example, as descried in JP2009-037108A, a step may be added in which the synthesized resin is dissolved in a solvent so as to obtain a solution, and the solution is heated for about 30 minutes to 4 hours at a temperature of about 30° C. to 90° C.

A weight-average molecular weight of the resin (A) in the present invention that is measured by GPC and expressed in terms of polystyrene is equal to or greater than 7,000 as described above, preferably 7,000 to 200,000, more preferably 7,000 to 50,000, even more preferably 7,000 to 40,000, and particularly preferably 7,000 to 30,000. In a case where the weight-average molecular weight is less than 7,000, the solubility of the resin in an organic developer becomes too high, and hence a precise pattern may not be able to be formed.

A dispersity (molecular weight distribution) is generally 1.0 to 3.0, and a resin is used which has a dispersity preferably within a range of 1.0 to 2.6, more preferably within a range of 1.0 to 2.0, and particularly preferably within a range of 1.4 to 2.0. The smaller the molecular weight distribution, the better the resolution and the pattern shape. Furthermore, a side wall of the resist pattern becomes smooth, and roughness properties become excellent.

In the present specification, a weight-average molecular weight and a dispersity can be determined by using, for example, HLC-8120 (manufactured by Tosoh Corporation), TSK gel Multipore HXL-M (manufactured by Tosoh Corporation, 7.8 mmID×30.0 cm) as a column, and tetrahydrofuran (THF) as an eluant.

In the first resist composition of the present invention, a formulation ratio of the resin (A) in the entirety of the composition is preferably 30% to 99% by mass and more preferably 60% to 95% by mass in the total solid content.

In the present invention, one kind of the resin (A) may be used, or plural kinds thereof may be used in combination.

[2] (B) Compound Generating Acid by being Irradiated with Actinic Rays or Radiation

Generally, the first resist composition in the present invention further contains a compound (B) (hereinafter, referred to as an “acid generator”) generating an acid by being irradiated with actinic rays or radiation. The compound (B) generating an acid by being irradiated with actinic rays or radiation is preferably a compound generating an organic acid by being irradiated with actinic rays or radiation.

The compound (B) generating an acid by being irradiated with actinic rays or radiation may be in the form of a low-molecular weight compound or in the form of a compound incorporated into a portion of a polymer. Furthermore, a low-molecular weight compound and a compound incorporated into a portion of a polymer may be used in combination.

In a case where the compound (B) generating an acid by being irradiated with actinic rays or radiation is in the form of a low-molecular weight compound, a molecular weight thereof is preferable equal to or less than 3,000, more preferably equal to or less than 2,000, and even more preferably equal to or less than 1,000.

In a case where the compound (B) generating an acid by being irradiated with actinic rays or radiation is in the form of a compound incorporated into a portion of a polymer, the compound (B) may be incorporated into a portion of the aforementioned acid-decomposable resin or may be incorporated into a resin different from the acid-decomposable resin.

In the present invention, the compound (B) generating an acid by being irradiated with actinic rays or radiation is preferably in the form of a low-molecular weight compound.

As the acid generator, it is possible to appropriately select and use known compounds, which generate an acid by being irradiated with actinic rays or radiation, or a mixture thereof used in a photoinitiator for photo-cationic polymerization, a photoinitiator for photo-radical polymerization, a colorant-type photodecolorizer, a photo-discoloring agent, a micro resist, and the like.

Examples of the acid generator include a diazonium salt, a phosphonium salt, a sulfonium salt, an iodonium salt, imide sulfonate, oxime sulfonate, diazo disulfone, disulfone, and o-nitrobenzyl sulfonate.

Examples of compounds preferable as the acid generator include compounds represented by the following Formulae (ZI), (ZII), and (ZIII)

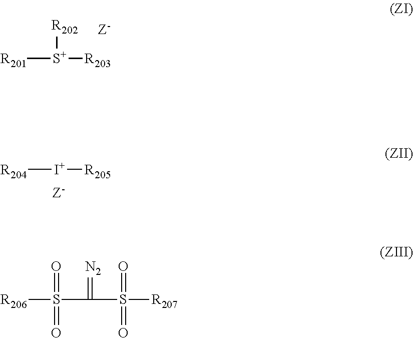

In Formula (ZI), R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Two out of R₂₀₁ to R₂₀₃ may form a ring structure by being bonded to each other, and the ring may contain an oxygen atom, a sulfur atom, an ester bond, an amide bond, or a carbonyl bond in the ring. Examples of the group formed by the bonding between two out of R₂₀₁ to R₂₀₃ include an alkylene group (for example, a butylene group or a pentylene group).

Z⁻ represents a non-nucleophilic anion.

Examples the non-nucleophilic anion as Z⁻ include a sulfonate anion, a carbonate anion, a sulfonylimide anion, a bis(alkylsulfonyl)imide anion, a tris(alkylsulfonyl)methide anion, and the like.

A non-nucleophilic anion is an anion which has a markedly poor ability to cause a nucleophilic reaction and can inhibit the decomposition that progresses with the passage of time due to an intermolecular nucleophilic reaction. Due to the non-nucleophilic anion, temporal stability of the resist composition is improved.

Examples of the sulfonate anion include an aliphatic sulfonate anion, an aromatic sulfonate anion, a camphorsulfonate anion, and the like.

Examples of the carbonate anion include an aliphatic carbonate anion, an aromatic carbonate anion, an aralkyl carbonate anion, and the like.

In the aliphatic sulfonate anion and the aliphatic carbonate anion, the aliphatic moiety may be an alkyl group or a cycloalkyl group, and preferably an alkyl group having 1 to 30 carbon atoms and a cycloalkyl group having 3 to 30 carbon atoms. Examples thereof include a methyl group, an ethyl group, a propyl group, an isopropyl group, a n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

An aromatic group in the aromatic sulfonate anion and the aromatic carbonate anion is preferably an aryl group having 6 to 14 carbon atoms, and examples thereof include a phenyl group, a tolyl group, a naphthyl group, and the like.

The alkyl group, the cycloalkyl group, and the aryl group in the aliphatic sulfonate anion and the aromatic sulfonate anion may have a substituent. Examples of the substituent of the alkyl group, the cycloalkyl group, and the aryl group in the aliphatic sulfonate anion and the aromatic sulfonate anion include a nitro group, a halogen atom (a fluorine atom, a chlorine atom, a bromine atom, or an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkyl aryloxysulfonyl group (preferably having 7 to 20 carbon atoms), a cycloalkyl aryloxysulfonyl group (preferably having 10 to 20 carbon atoms), alkyloxyalkyloxy group (preferably having 5 to 20 carbon atoms), a cycloalkyl alkyloxyalkyloxy group (preferably having 8 to 20 carbon atoms), and the like. Regarding the aryl group and the ring structure that each group has, examples of the substituent include an alkyl group (preferably having 1 to 15 carbon atoms) and a cycloalkyl group (preferably having 3 to 15 carbon atoms).

An aralkyl group in the aralkyl carbonate anion is preferably an aralkyl group having 7 to 12 carbon atoms, and examples thereof include a benzyl group, a phenethyl group, a naphthyl methyl group, a naphthyl ethyl group, a naphthyl butyl group, and the like.

The alkyl group, the cycloalkyl group, the aryl group, and the aralkyl group in the aliphatic carbonate anion, the aromatic carbonate anion, and the aralkyl carbonate anion may have a substituent. Examples of the substituent include the same halogen atom, alkyl group, cycloalkyl group, alkoxy group, alkylthio group, and the like as in the aromatic sulfonate anion.

Examples of the sulfonylimide anion include a saccharin anion.

The alkyl group in the bis(alkylsulfonyl)amide anion and the tris(alkylsulfonyl)methide anion is preferably an alkyl group having 1 to 5 carbon atoms, and examples thereof include a methyl group, an ethyl group, a propyl group, an isopropyl group, a n-butyl group, an isobutyl group, a sec-butyl group, a pentyl group, a neopentyl group, and the like.

Two alkyl groups in the bis(alkylsulfonyl)imide anion may form an alkylene group (preferably having 2 to 4 carbon atoms) by being linked to each other and form a ring together with an imide group and two sulfonyl groups. Examples of a substituent that these alkyl groups and the alkylene group formed by the linkage of two alkyl groups in the bis(alkylsulfonyl)imide anion can have include a halogen atom, an alkyl group substituted with a halogen atom, an alkoxy group, an alkylthio group, an alkyloxysulfonyl group, an aryloxysulfonyl group, a cycloalkyl aryloxysulfonyl group, and the like. Among these, an alkyl group substituted with a fluorine atom is preferable.

Examples of other non-nucleophilic anions include fluorinated phosphorus (for example, PF₆⁻), fluorinated boron (for example, BF₄⁻), fluorinated antimony (for example, SbF₆⁻), and the like.

The non-nucleophilic anion as Z⁻ is preferably an aliphatic sulfonate anion in which at least the a position of a sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom. The non-nucleophilic anion is more preferably a perfluoro aliphatic sulfonate anion having 4 to 8 carbon atoms or a benzene sulfonate anion having a fluorine atom, and even more preferably a nonafluorobutane sulfonate anion, a perfluorooctane sulfonate anion, a pentafluorobenzene sulfonate anion, or a 3,5-bis(trifluoromethyl)benzene sulfonate anion.

The acid generator is preferably a compound generating an acid represented by the following Formula (V) or (VI) by being irradiated with actinic rays or radiation. In a case where the acid generator is a compound generating an acid represented by the following Formula (V) or (VI), the acid generator has a cyclic organic group, and accordingly, resolution and roughness performance can be further improved.

As the non-nucleophilic anion, an anion generating an organic acid represented by the following Formula (V) or (VI) can be used.

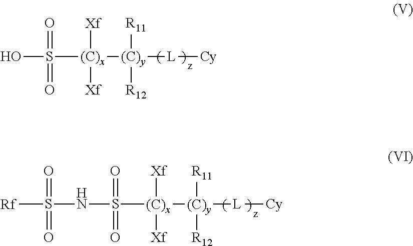

In the above formulae, Xf each independently represents a fluorine atom or an alkyl group substituted with at least one fluorine atom.

R₁₁ and R₁₂ each independently represent a hydrogen atom, a fluorine atom, or an alkyl group.

L each independently represents a divalent linking group.

Cy represents a cyclic organic group.

Rf represents a group containing a fluorine atom.

x represents an integer of 1 to 20.

y represents an integer of 0 to 10.

z represents s an integer of 0 to 10.

Xf represents a fluorine atom or an alkyl group substituted with at least one fluorine atom. The number of carbon atoms of the alkyl group is preferably 1 to 10, and more preferably 1 to 4. The alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉, and more preferably a fluorine atom or CF₃. It is particularly preferable that both of Xf's represent a fluorine atom.

R₁₁ and R₁₂ each independently represent a hydrogen atom, a fluorine atom, or an alkyl group. The alkyl group may have a substituent (preferably a fluorine atom) and preferably has 1 to 4 carbon atoms. The alkyl group is more preferably a perfluoroalkyl group having 1 to 4 carbon atoms. Specific examples of the alkyl group as R₁₁ and R₁₂ that has a substituent include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, CF₃ is preferable.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), cycloalkylene group (preferably having 3 to 10 carbon atoms), an alkenylene group (preferably having 2 to 6 carbon atoms), a divalent linking group obtained by combining a plurality of these groups, and the like. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

Cy represents a cyclic organic group. Examples of the cyclic organic group include an alicyclic group, an aryl group, and a heterocyclic group.

The alicyclic group may be monocyclic or polycyclic. Examples of the monocyclic alicycilc group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, from the viewpoint of inhibiting diffusivity in a film during the post exposure bake (PEB) step and improving a Mask Error Enhancement Factor (MEEF), alicyclic groups having a bulky structure having 7 or more carbon atoms, such as a norbornyl group, a tricyclodecanyl group, a tetracyclodecanyl group, a tetracyclododecanyl group, and an adamantyl group, are preferable.

The aryl group may be monocyclic or polycyclic. Examples of the aryl group include a phenyl group, a naphthyl group, a phenanthryl group, and an anthryl group. Among these, a naphthyl group having a relatively low absorbance at 193 nm is preferable.

Although the heterocyclic group may be monocyclic or polycyclic, the polycyclic heterocyclic group can more reliably inhibit the diffusion of an acid. The heterocyclic group may or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heteroyclic ring not having aromaticity include a tetrahydrofuran ring, a lactone or sultone ring, and a decahydroisoquinoline ring. As a heterocyclic ring in the heterocyclic group, a furan ring, a thiophene ring, a pyridine ring, or a decahydroisoquinoline ring is particularly preferable. Examples of the lactone or sultone ring include the lactone structure or sultone exemplified for the resin (A) descried above.

The aforementioned cyclic organic group may have a substituent. Examples of the substituent include an alkyl group (may be any of linear and branched alkyl groups, preferably having 1 to 12 carbon atoms), a cycloalkyl group (may be any of monocyclic, polycyclic, and spiro rings, preferably having 3 to 20 carbon atoms), an aryl group (preferably having 6 to 14 carbon atoms), a hydroxyl group, an alkoxy group, an ester group, an amide group, a urethane group, a ureide group, a thioether group, a sulfonamide group, and a sulfonic acid ester group. The carbon constituting the cyclic organic group (carbon that contributes to the formation of a ring) may be carbonyl carbon.

x is preferably 1 to 8, more preferably 1 to 4, and particularly preferably 1. y is preferably 0 to 4, and more preferably 0. z is preferably 0 to 8, and more preferably 0 to 4.

Examples of the group having a fluorine atom represented by Rf include an alkyl group having at least one fluorine atom, a cycloalkyl group having at least one fluorine atom, and an aryl group having at least one fluorine atom.

These alkyl group, cycloalkyl group, and aryl group may be substituted with either a fluorine atom or other fluorine atom-containing substituents. In a case where Rf is a cycloalkyl group having at least one fluorine atom or an aryl group having at least one fluorine atom, examples of other fluorine atom-containing substituents include an alkyl group substituted with at least one fluorine atom.

Furthermore, these alkyl group, cycloalkyl group, and aryl group may be further substituted with a substituent not containing a fluorine atom. Examples of the substituent include the substituents which were described above for Cy and do not contain a fluorine atom.

Examples of the alkyl group having at least one fluorine atom that is represented by Rf include the same alkyl group as the alkyl group described above that is represented by Xf and substituted with at least one fluorine atom. Examples of the cycloalkyl group having at least one fluorine atom that is represented by Rf include a perfluorocyclopentyl group and a perfluorocyclohexyl group. Examples of the aryl group having at least one fluorine atom that is represented by Rf include a perfluorophenyl group.

It is also preferable that the aforementioned non-nucleophilic anion is an anion represented by any of the following Formulae (B-1) to (B-3).

First, the anion represented by the following Formula (B-1) will be described.

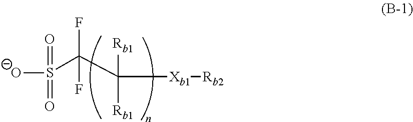

In Formula (B-1), R_{b1} each independently represents a hydrogen atom, a fluorine atom, or a trifluoromethyl group (CF₃).

n represents an integer of 1 to 4.

n is preferably an integer of 1 to 3, and is more preferably 1 or 2.

X_{b1} represents a single bond, an ether bond, an ester bond (—OCO— or —COO—), or a sulfonic acid ester bond (—OSO₂— or —SO₃—).

X_{b1} is preferably an ester bond (—OCO₂— or —COO—) or a sulfonic acid ester bond (—OSO₂— or —SO₃—).

R_{b2} represents a substituent having 6 or more carbon atoms.

The substituent having 6 or more carbon atoms represented by R_{b2} is preferably a bulky group, and examples thereof include an alkyl group, an alicyclic group, an aryl group, a heterocyclic group, and the like having 6 or more carbon atoms.

The alkyl group having 6 or more carbon atoms represented by R_{b2} may be linear or branched, and is preferably a linear or branched alkyl group having 6 to 20 carbon atoms. Examples thereof include a linear or branched hexyl group, a linear or branched heptyl group, a linear or branched octyl group, and the like. From the viewpoint of bulkiness, the alkyl group is preferably a branched alkyl group.

The alicyclic group having 6 or more carbon atoms represented by R_{b2} may be monocyclic or polycyclic. Examples of the monocyclic alicyclic group include a monocyclic cycloalkyl group such as a cyclohexyl group and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, from the viewpoint of inhibiting diffusivity in a film during the post exposure bake (PEB) step and improving a Mask Error Enhancement Factor (MEEF), alicyclic rings having a bulky structure having 7 or more carbon atoms, such as a norbornyl group, a tricyclodecanyl group, a tetracyclodecanyl group, a tetracyclododecanyl group, and an adamantyl group, are preferable.

The aryl group having 6 or more carbon atoms represented by R_{b2} may be monocyclic or polycyclic. Examples of the aryl group include a phenyl group, a naphthyl group, a phenanthryl group, and an anthryl group. Among these, a naphthyl group having a relatively low absorbance at 193 nm is preferable.

Although the heterocyclic group having 6 or more carbon atoms represented by R_{b2} may be monocyclic or polycyclic, the polycyclic heterocyclic group can more reliably inhibit the diffusion of an acid. The heterocyclic group may or may not have aromaticity. Examples of the heterocyclic ring having aromaticity include a benzofuran ring, a benzothiophene ring, a dibenzofuran ring, and a dibenzothiophene ring. Examples of the heteroyclic ring not having aromaticity include a tetrahydrofuran ring, a lactone ring, and a decahydroisoquinoline ring. As a heterocyclic ring in the heterocyclic group, a benzofuran ring or a decahydroisoquinoline ring is particularly preferable. Examples of the lactone ring include the lactone structure exemplified for the resin (A) descried above.

The substituent having 6 or more carbon atoms represented by R_{b2} may further have a substituent. Examples of the substituent that R_{b2} may further have include an alkyl group (may be any of linear and branched alkyl groups, preferably having 1 to 12 carbon atoms), a cycloalkyl group (may be any of monocyclic, polycyclic, and spiro rings, preferably having 3 to 20 carbon atoms), an aryl group (preferably having 6 to 14 carbon atoms), a hydroxy group, an alkoxy group, an ester group, an amide group, a urethane group, a ureide group, a thioether group, a sulfonamide group, and a sulfonic acid ester group. The carbon constituting the aforementioned alicyclic group, aryl group, or heterocyclic group (carbon that contributes to the formation of a ring) may be carbonyl carbon.

Specific examples of the anion represented by Formula (B-1) will be shown below, but the present invention is not limited thereto.

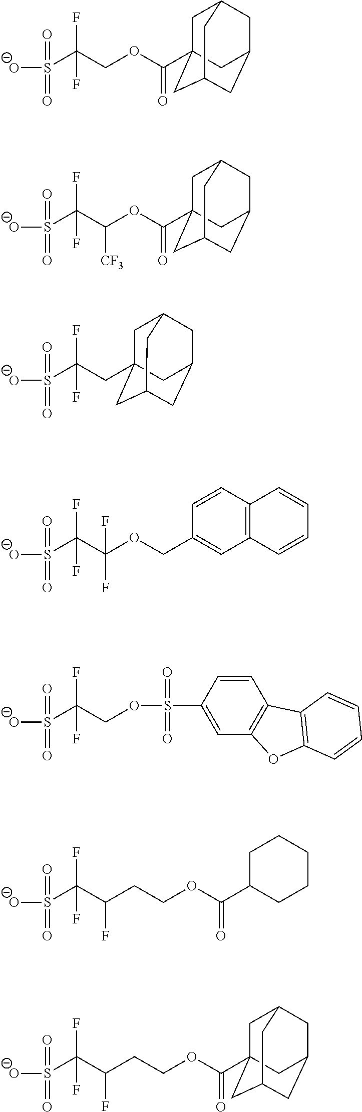

Next, the anion represented by the following Formula (B-2) will be described.

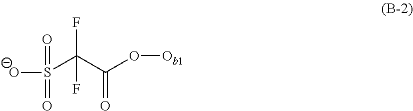

In Formula (B-2), Q_{b1} represents a group having a lactone structure, a group having a sultone structure, or a group having a cyclic carbonate structure.

Examples of the lactone structure and the sultone structure for Q_{b1} include the same lactone structure and sultone structure as the lactone structure and sultone structure in the repeating units having a lactone structure and a sultone structure described above for resin (A). Specific examples thereof include a lactone structure represented by any of Formulae (LC1-1) to (LC1-17) described above or a sultone structure represented by any of Formulae (SL1-1) to (SL1-3) described above.

The lactone structure or the sultone structure may be directly bonded to an oxygen atom of the ester group in Formula (B-2) or may be bonded to an oxygen atom of the ester group through an alkylene group (for example, a methylene group or an ethylene group). In this case, the group having the lactone structure or the sultone structure can be mentioned as an alkyl group having the lactone structure or the sultone structure as a substituent.

The cyclic carbonate structure for Q_{b1} is preferably a 5- to 7-membered cyclic carbonate structure, and examples thereof include 1,3-dioxolan-2-one, 1,3-dioxolan-2-one, and the like.

The cyclic carbonate structure may be directly bonded to an oxygen atom of the ester group in Formula (B-2) or may be bonded to an oxygen atom of the ester group through an alkylene group (for example, a methylene group or an ethylene group). In this case, the group having the cyclic carbonate structure can be mentioned as an alkyl group having the cyclic carbonate structure as a substituent.

Specific examples of the anion represented by Formula (B-2) will be shown below, but the present invention is not limited thereto.

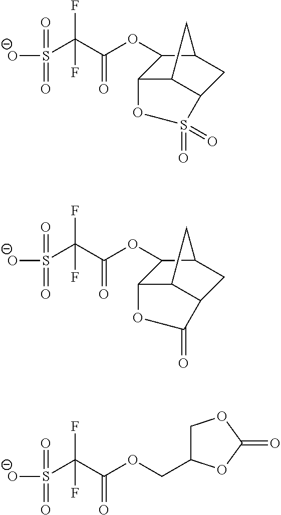 [SMILES: O=C(OC1C2CC3C1OS(=O)(=O)C3C2)C(F)(F)S(=O)(=O)[O-] ; O=C1OC2C3CC(CC13)C2OC(=O)C(F)(F)S(=O)(=O)[O-] ; O=C1OCC(COC(=O)C(F)(F)S(=O)(=O)[O-])O1]

Next, the anion represented by the following Formula (B-3) will be described.

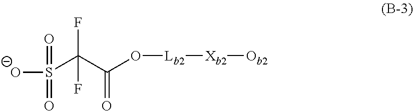

In Formula (B-3), L_{b2} represents an alkylene group having 1 to 6 carbon atoms, and examples thereof include a methylene group, an ethylene group, a propylene group, a butylene group, and the like. L_{b2} is preferably an alkylene group having 1 to 4 carbon atoms.

X_{b2} represents an ether bond or an ester bond (—OCO— or —COO—).

Q_{b2} represents an alicyclic group or a group containing an aromatic ring.

The alicyclic group as Q_{b2} may be monocyclic or polycyclic. Examples of the monocyclic alicyclic group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, alicyclic groups having a bulky structure having 7 or more carbon atoms, such as a norbornyl group, a tricyclodecanyl group, a tetracyclodecanyl group, a tetracyclododecanyl group, and an adamantyl group, are preferable.

The aromatic ring in the group containing an aromatic ring represented by Q_{b2} is preferably an aromatic ring having 6 to 20 carbon atoms, and examples thereof include a benzene ring, a naphthalene ring, a phenanthrene ring, an anthracene ring, and the like. Among these, a benzene ring or a naphthalene ring is more preferable. The aromatic ring may be substituted with at least one fluorine atom, and examples of the aromatic ring substituted with at least one fluorine atom include a perfluorophenyl group and the like.

The aromatic ring may be directly bonded to X_{b2} or may be bonded to X_{b2} through an alkylene group (for example, a methylene group or an ethylene group). In this case, the group containing an aromatic ring can be mentioned as an alkyl group having the aromatic ring as a substituent.

Specific examples of the anion structure represented by Formula (B-3) will be shown below, but the present invention is not limited thereto.

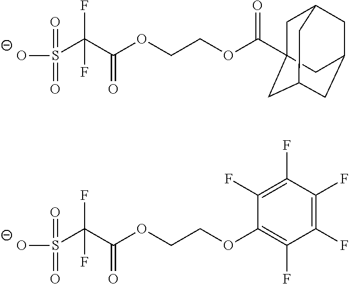 [SMILES: O=C(OCCOC(=O)C(F)(F)S(=O)(=O)[O-])C12CC3CC(CC(C3)C1)C2 ; O=C(OCCOc1c(F)c(F)c(F)c(F)c1F)C(F)(F)S(=O)(=O)[O-]]

Examples of the organic group represented by R₂₀₁, R₂₀₂, and R₂₀₃ include the corresponding groups in the compounds (ZI-1), (ZI-2), (ZI-3), and (ZI-4) which will be described later.

The acid generator may be a compound having a plurality of structures represented by Formula (ZI). For example, the acid generator may be a compound having a structure in which at least one of R₂₀₁ to R₂₀₃ of a compound represented by Formula (ZI) is bonded to at least one of R₂₀₁ to R₂₀₃ of the other compound represented by Formula (ZI) through a single bond or a linking group.

Examples of a more preferred (ZI) component include compounds (ZI-1), (ZI-2), (ZI-3), and (ZI-4) described below.

The compound (ZI-1) is an aryl sulfonium compound in which at least one of R₂₀₁ to R₂₀₃ of Formula (ZI) is an aryl group, that is, a compound using aryl sulfonium as a cation.

In the aryl sulfonium compound, all of R₂₀₁ to R₂₀₃ may be an aryl group. Alternatively, some of R₂₀₁ to R₂₀₃ may be an aryl group, and the rest may be an alkyl group or a cycloalkyl group.

Examples of the aryl sulfonium compound include a triaryl sulfonium compound, a diaryl alkyl sulfonium compound, an aryl dialkyl sulfonium compound, a diaryl cycloalkyl sulfonium compound, and an aryl dicycloalkyl sulfonium compound.

The aryl group of the aryl sulfonium compound is preferably a phenyl group or a naphthyl group, and more preferably a phenyl group. The aryl group may be an aryl group having a heterocyclic structure having an oxygen atom, a nitrogen atom, a sulfur atom, and the like. Examples of the heterocyclic structure include a pyrrole residue, a furan residue, a thiophene residue, an indole residue, a benzofuran residue, a benzothiophene residue, and the like. In a case where the aryl sulfonium compound has two or more aryl groups, the two or more aryl groups may be the same as or different from each other.

As the alkyl group or the cycloalkyl group that the aryl sulfonium compound has if necessary, a linear or branched alkyl group having 1 to 15 carbon atoms and a cycloalkyl group having 3 to 15 carbon atoms are preferable. Examples thereof include a methyl group, an ethyl group, a propyl group, a n-butyl group, a sec-butyl group, a t-butyl group, a cyclopropyl group, a cyclobutyl group, a cyclohexyl group, and the like.

The aryl group, the alkyl group, and the cycloalkyl group as R₂₀₁ to R₂₀₃ may have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group. The substituent is preferably a linear or branched alkyl group having 1 to 12 carbon atoms, a cycloalkyl group having 3 to 12 carbon atoms, or a linear, branched, or cyclic alkoxy group having 1 to 12 carbon atoms, and more preferably an alkyl group having 1 to 4 carbon atoms or an alkoxy group having 1 to 4 carbon atoms. The substituent may substitute any one of the three groups R₂₀₁ to R₂₀₃ or may substitute all of the three groups. In a case where R₂₀₁ to R₂₀₃ each represent an aryl group, the substituent may substitute the aryl group in the p-position thereof.

Next, the compound (ZI-2) will be described.

The compound (ZI-2) is a compound in which R₂₀₁ to R₂₀₃ in Formula (ZI) each independently represent an organic group not having an aromatic ring. The aromatic ring also includes a heteroatom-containing aromatic ring.

The organic group not containing an aromatic ring that is represented by R₂₀₁ to R₂₀₃ generally has 1 to 30 carbon atoms and preferably has 1 to 20 carbon atoms.

R₂₀₁ to R₂₀₃ each independently preferably represent an alkyl group, a cycloalkyl group, an allyl group, or a vinyl group, more preferably represent a linear or branched 2-oxoalkyl group, a 2-oxocycloalkyl group, or an alkoxycarbonyl methyl group, and particularly preferably represent a linear or branched 2-oxoalkyl group.

Preferred examples of the alkyl group and the cycloalkyl group represented by R₂₀₁ to R₂₀₃ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group). More preferred examples of the alkyl group include a 2-oxoalkyl group and an alkoxycarbonyl methyl group. More preferred examples of the cycloalkyl group include 2-oxocycloalkyl group.

The 2-oxoalkyl group may be linear or branched, and preferred examples thereof include a group having >C═O in the 2-position of the aforementioned alkyl group.

Preferred examples of the 2-oxocycloalkyl group include a group having >C═O in the 2-position of the aforementioned cycloalkyl group.

Preferred examples of the alkoxy group in the alkoxycarbonyl methyl group include an alkoxy group having 1 to 5 carbon atoms (a methoxy group, an ethoxy group, a propoxy group, a butoxy group, or a pentoxy group).

R₂₀₁ to R₂₀₃ may be further substituted with a halogen atom, an alkoxy group (for example, having 1 to 5 carbon atoms), a hydroxyl group, a cyano group, or a nitro group.

Next, the compound (ZI-3) will be described.

The compound (ZI-3) is a compound which is represented by the following Formula (ZI-3) and has a phenacyl sulfonium salt structure.

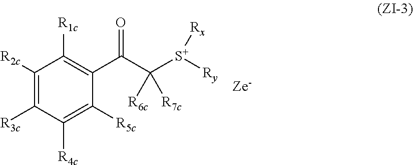

In Formula (ZI-3), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonyl alkyl group, an allyl group, or a vinyl group.

Any two or more groups out of R_{1c} to R_{5c}, R_{5c} and R_{6c}, R_{6c} and R_{1c}, R_{5c} and Rₓ, and Rₓ and R_{y} may form a ring structure by being bonded to each other respectively, and the ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocyclic ring, or a polycyclic condensed ring in which two or more of these rings are combined. Examples of the ring structure include a 3- to 10-membered ring. The ring structure is preferably a 4- to 8-membered ring, and more preferably a 5- or 6-membered ring.

Examples of the group formed by the bonding between any two or more groups out of R_{1c} to R_{5c}, the bonding between R_{6c} and R_{7c}, and the bonding between Rₓ and R_{y} include a butylene group, a pentylene group, and the like.

As the group formed by the bonding between R_{5c} and R_{6c} and the bonding between R_{5c} and Rₓ, a single bond or an alkylene group is preferable. Examples of the alkylene group include a methylene group and an ethylene group.

Zc⁻ represents a non-nucleophilic anion, and examples thereof include the same non-nucleophilic anion as Z⁻ in Formula (ZI).

The alkyl group as R_{1c} to R_{7c} may be linear or branched, and examples thereof include an alkyl group having 1 to 20 carbon atoms. Preferred examples of the alkyl group include a linear or branched alkyl group having 1 to 12 carbon atoms (for example, a methyl group, an ethyl group, a linear or branched propyl group, a linear or branched butyl group or a linear or branched pentyl group). Examples of the cycloalkyl group include a cycloalkyl group having 3 to 10 carbon atoms (for example, a cyclopentyl group or a cyclohexyl group).

The aryl group as R_{1c} to R_{5c} preferably has 5 to 15 carbon atoms, and examples thereof include a phenyl group and a naphthyl group.

The alkoxy group as R_{1c} to R_{5c} may be linear, branched, or cyclic, and examples thereof include an alkoxy group having 1 to 10 carbon atoms. Preferred examples of the alkoxy group include a linear or branched alkoxy group having 1 to 5 carbon atoms (for example, a methoxy group, an ethoxy group, a linear or branched propoxy group, a linear or branched butoxy group, or a linear or branched pentoxy group) and a cyclic alkoxy group having 3 to 10 carbon atoms (for example, a cyclopentyloxy group or a cyclohexyloxy group).

Specific examples of the alkoxy group in the alkoxycarbonyl group as R_{1c} to R_{5c} are the same as the specific examples of the alkoxy group as R_{1c} to R_{5c} described above.

Specific examples of the alkyl group in the alkylcarbonyloxy group and the alkylthio group as R_{1c} to R_{5c} are the same as the specific examples of the alkyl group as R_{1c} to R_{5c} described above.

Specific examples of the cycloalkyl group in the cycloalkylcarbonyloxy group as R_{1c} to R_{5c} are the same as the specific examples of the cycloalkyl group as R_{1c} to R_{5c} described above.

Specific examples of the aryl group in the aryloxy group and the arylthio group as R_{1c} to R_{5c} are the same as the specific examples of the aryl group as R_{1c} to R_{5c} described above.

It is preferable that any of R_{1c} to R_{5c} is a linear or branched alkyl group, a cycloalkyl group, or a linear, branched, or cyclic alkoxy group. It is more preferable that the sum of the number of carbon atoms of R_{1c} to R_{5c} is 2 to 15. In a case where the number of carbon atoms is within the above range, the solubility in a solvent is further improved, and the occurrence of particles is inhibited at the time of storage.

Examples of the ring structure that any 2 out of R_{1c} to R_{5c} may form by being bonded to each other preferably include a 5- or 6-membered ring, and particularly preferably include a 6-membered ring (for example, a phenyl ring).

Examples of the ring structure that R_{5c} and R_{6c} may form by being bonded to each other include a ring constituted with 4 or more members (particularly preferably a 5- or 6-membered ring) that R_{5c} and R_{6c} form together with a carbonyl carbon atom and a carbon atom in Formula (ZI-3) by constituting a single bond or an alkylene group (a methylene group, an ethylene group, or the like) by being bonded to each other.

The aryl group as R_{6c} and R_{7c} preferably has 5 to 15 carbon atoms, and examples thereof include a phenyl group and a naphthyl group.

As an aspect of R_{6c} and R_{7c}, it is preferable that both of them are an alkyl group. Particularly, it is preferable that each of R_{6c} and R_{7c} is a linear or branched alkyl group having 1 to 4 carbon atoms. It is more preferable that both of R_{6c} and R_{7c} are a methyl group.

In a case where R_{6c} and R_{7c} form a ring by being bonded to each other, as the group formed by the bonding between R_{6c} and R_{7c}, an alkylene group having 2 to 10 carbon atoms is preferable, and examples thereof include an ethylene group, a propylene group, a butylene group, a pentylene group, a hexylene group, and the like. The ring formed by the bonding between R_{6c} and R_{7c} may have a heteroatom such as an oxygen atom in the ring.

Examples of the alkyl group and the cycloalkyl group as Rₓ and R_{y} include the same alkyl group and cycloalkyl group as represented by R_{1c} to R_{7c}.

Examples of the 2-oxoalkyl group and the 2-oxocycloalkyl group as Rₓ and R_{y} include a group having >C═O in the 2-position of the alkyl group and the cycloalkyl group as R_{1c} to R_{7c}.

Examples of the alkoxy group in the alkoxycarbonylalkyl group as Rₓ and R_{y} include the same alkoxy group as represented by R_{1c} to R_{5c}, and examples of the alkyl group in the alkoxycarbonylalkyl group include an alkyl group having 1 to 12 carbon atoms. Preferred examples of the alkyl group include a linear alkyl group having 1 to 5 carbon atoms (for example, a methyl group or an ethyl group).

The allyl group as Rₓ and R_{y} is not particularly limited, and is preferably an unsubstituted allyl group or an allyl group substituted with a monocyclic or polycyclic cycloalkyl group (preferably a cycloalkyl group having 3 to 10 carbon atoms).

The vinyl group as Rₓ and R_{y} is not particularly limited, and is preferably an unsubstituted vinyl group or a vinyl group substituted with a monocyclic or polycyclic cycloalkyl group (preferably a cycloalkyl group having 3 to 10 carbon atoms).

Examples of the ring structure that R_{5c} and Rₓ may form by being bonded to each other include a ring constituted with five or more members (particularly preferably a 5-membered ring) that R_{5c} and Rₓ form together with a sulfur atom and a carbonyl carbon atom in Formula (ZI-3) by constituting a single bond or an alkylene group (a methylene group, an ethylene group, or the like) by being bonded to each other.

Examples of the ring structure that Rₓ and R_{y} may form by being bonded to each other include a 5- or 6-membered ring that divalent Rₓ and R_{y} (for example, a methylene group, an ethylene group, or a propylene group) form together with a sulfur atom in Formula (ZI-3), and particularly preferably include a 5-membered ring (that is, a tetrahydrothiophene ring).

Each of Rₓ and R_{y} is preferably an alkyl group or a cycloalkyl group having 4 or more carbon atoms, more preferably an alkyl group or a cycloalkyl group having 6 or more carbon atoms, and even more preferably an alkyl group or a cycloalkyl group having 8 or more carbon atoms.

R_{1c} to R_{7c}, Rₓ, and R_{y} may further have a substituent, and examples of the substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group, and the like.

It is more preferable that, in Formula (ZI-3), R_{1c}, R_{2c}, R_{4c}, and R_{5c} each independently represent a hydrogen atom, and R_{3c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Specific examples of the cation of the compound represented by Formula (ZI-2) or (ZI-3) in the present invention will be shown below.

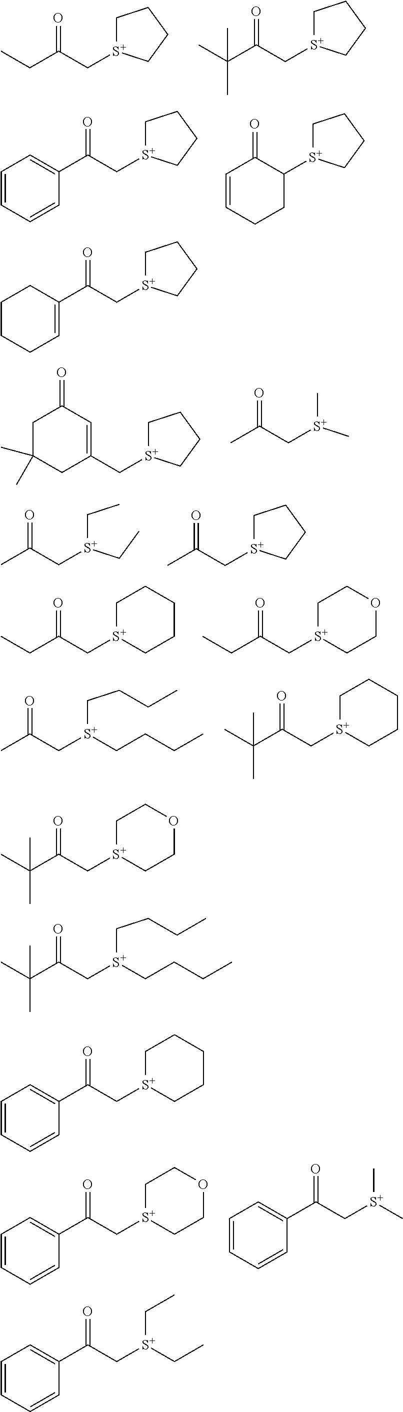

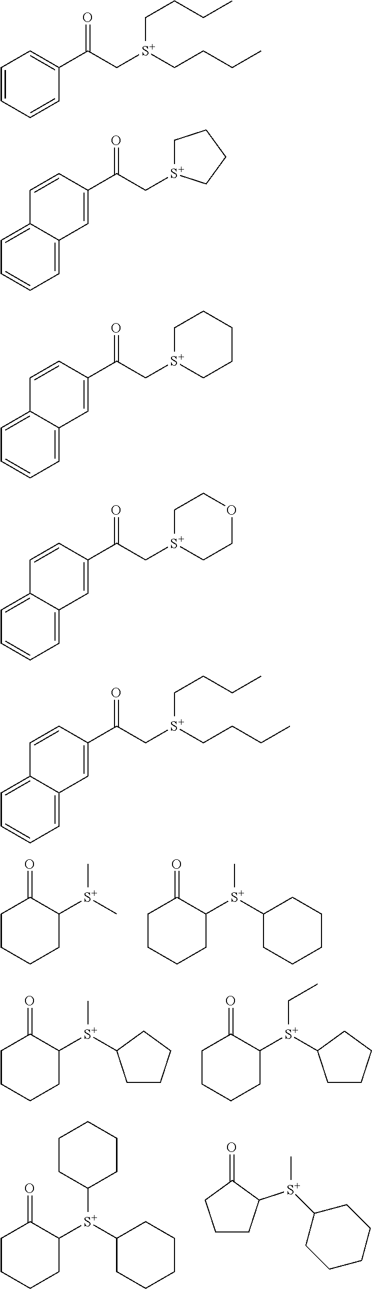

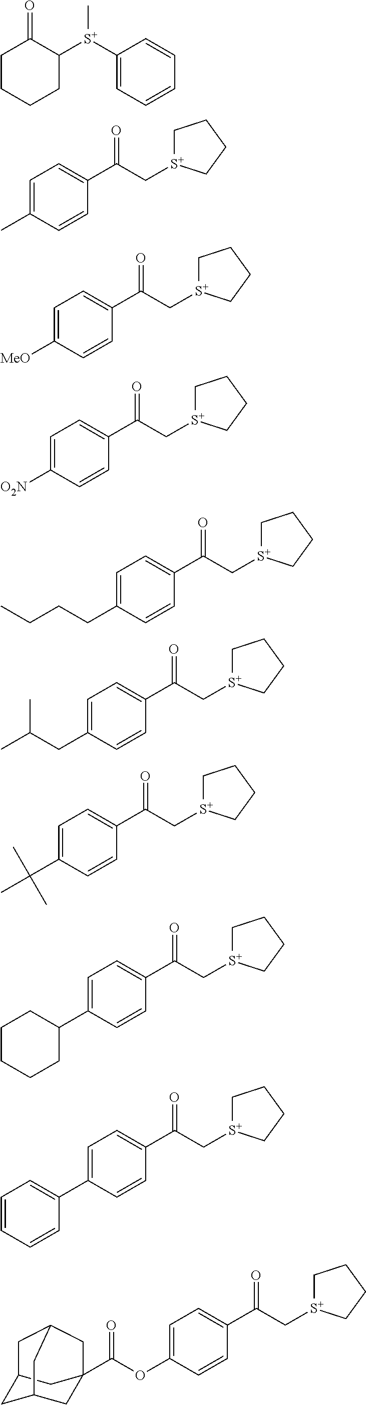

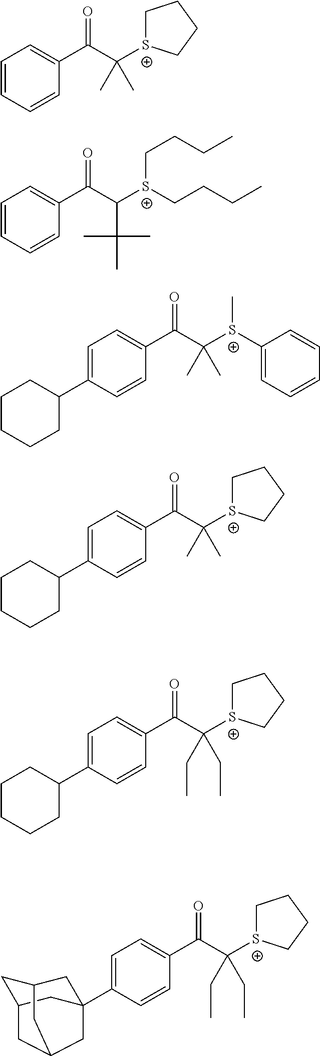 [SMILES: CC(C)(C(=O)c1ccccc1)[S+]1CCCC1 ; CCCC[S+](CCCC)C(C(=O)c1ccccc1)C(C)(C)C ; C[S+](c1ccccc1)C(C)(C)C(=O)c1ccc(C2CCCCC2)cc1 ; CC(C)(C(=O)c1ccc(C2CCCCC2)cc1)[S+]1CCCC1 ; CCC(CC)(C(=O)c1ccc(C2CCCCC2)cc1)[S+]1CCCC1 ; CCC(CC)(C(=O)c1ccc(C23CC4CC(CC(C4)C2)C3)cc1)[S+]1CCCC1]

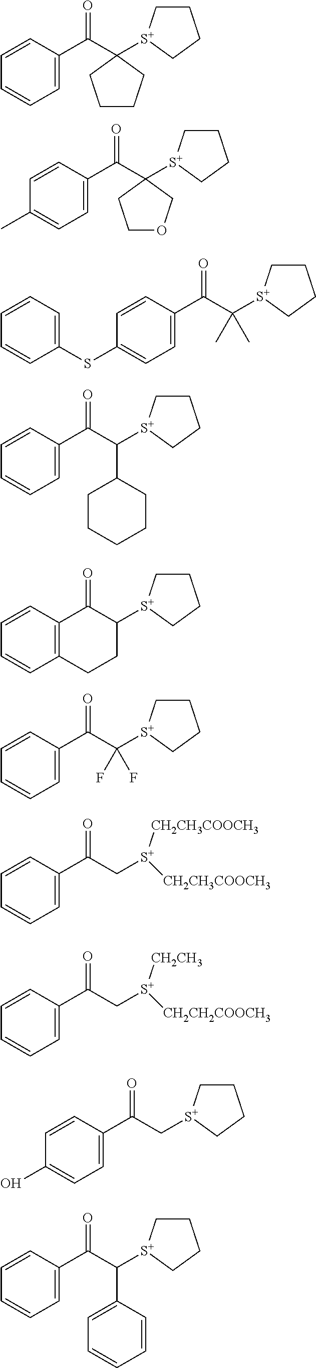

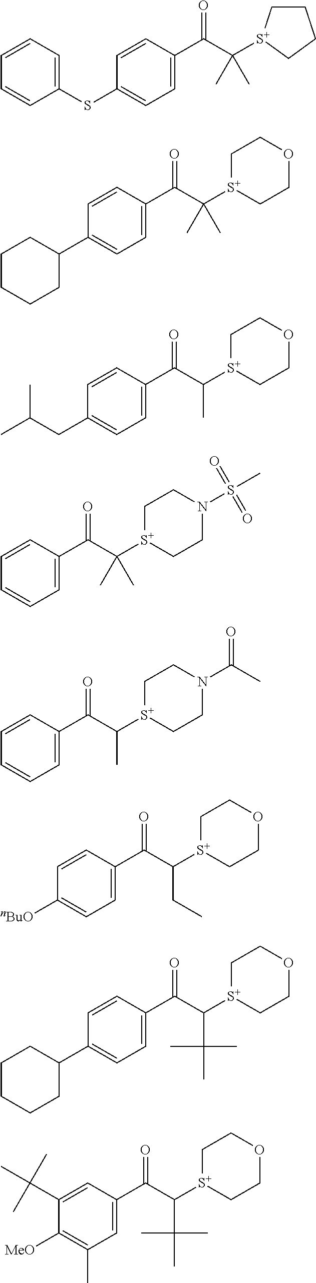

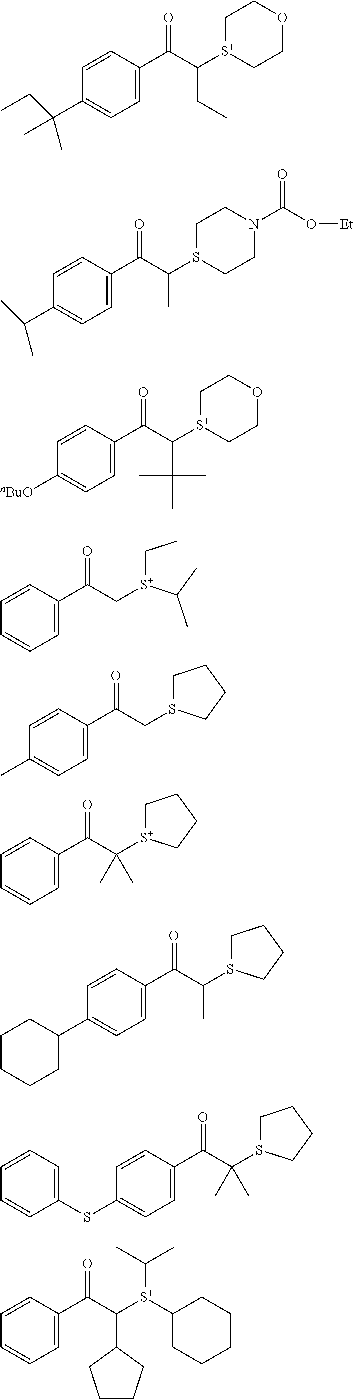

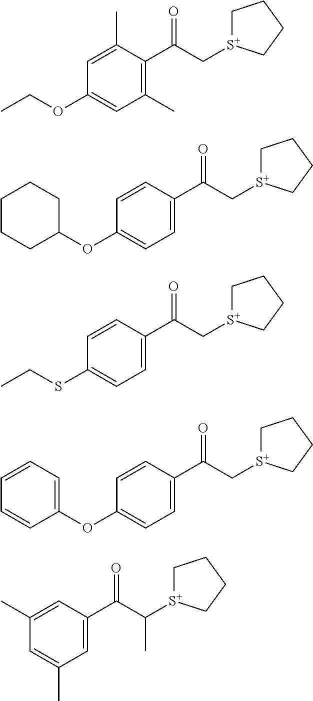 [SMILES: CCOc1cc(C)c(C(=O)C[S+]2CCCC2)c(C)c1 ; O=C(C[S+]1CCCC1)c1ccc(OC2CCCCC2)cc1 ; CCSc1ccc(C(=O)C[S+]2CCCC2)cc1 ; O=C(C[S+]1CCCC1)c1ccc(Oc2ccccc2)cc1 ; Cc1cc(C)cc(C(=O)C(C)[S+]2CCCC2)c1]

Next, the compound (ZI-4) will be described.

The compound (ZI-4) is represented by the following Formula (ZI-4).

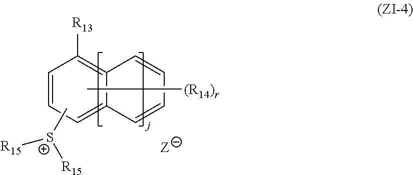

In Formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where there is a plurality of R₁₄'s, R₁₄ each independently represents a hydrogen atom, an alkyl group, a cycloalkyl group, an alkoxy group, an alkoxycarbonyl group, an alkylcarbonyl group, an alkylsulfonyl group, a cycloalkyl sulfonyl group, or a group having a cycloalkyl group. These groups may have a substituent.

R₁₅ each independently represents an alkyl group, a cycloalkyl group, or a naphthyl group. Two R₁₅'s may form a ring by being bonded to each other. These groups may have a substituent.

l represents an integer of 0 to 2.

r represents an integer of 0 to 8.

Z⁻ represents a non-nucleophilic anion, and examples thereof include the same non-nucleophilic anion as Z⁻ in Formula (ZI).

In Formula (ZI-4), the alkyl group as R₁₃, R₁₄, and R₁₅ is preferably a linear or branched alkyl group having 1 to 10 carbon atoms. The alkyl group is preferably a methyl group, an ethyl group, a n-butyl group, a t-butyl group, or the like.

Examples of the cycloalkyl group as R₁₃, R₁₄, and R₁₅ include a monocyclic or polycyclic cycloalkyl group (preferably a cycloalkyl group having 3 to 20 carbon atoms). The cycloalkyl group is particularly preferably cyclopropyl, cyclopentyl, cyclohexyl, cycloheptyl, or cyclooctyl.

The alkoxy group as R₁₃ and R₁₄ is preferably a linear or branched alkoxy group having 1 to 10 carbon atoms. The alkoxy group is preferably a methoxy group, an ethoxy group, a n-propoxy group, a n-butoxy group, or the like.

The alkoxycarbonyl group as R₁₃ and R₁₄ is preferably a linear or branched alkoxycarbonyl group having 2 to 11 carbon atoms. The alkoxycarbonyl group is preferably a methoxycarbonyl group, an ethoxycarbonyl group, a n-butoxycarbonyl group, or the like.

Examples of the group having a cycloalkyl group as R₁₃ and R₁₄ include a monocyclic or polycyclic cycloalkyl group (preferably a cycloalkyl group having 3 to 20 carbon atoms). Examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group as R₁₃ and R₁₄ preferably has 7 or more carbon atoms in total and more preferably has 7 to 15 carbon atoms in total, and preferably has a mooncyclic cycloalkyl group. The monocyclic cycloalkyloxy group having 7 or more carbon atoms in total is a monocyclic cycloalkyloxy group composed of a cycloalkyloxy group, such as a cyclopropyloxy group, a cyclobutyloxy group, a cyclopentyloxy group, a cyclohexyloxy group, a cycloheptyloxy group, a cyclooctyloxy group, or a cyclododecanyloxy group, which has any of substituents including an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, or an iso-amyl group, an alkoxy group such as a hydrogen atom, a halogen atom (fluorine, chlorine, bromine, or iodine), a nitro group, a cyano group, an amide group, a sulfonamide group, a methoxy group, an ethoxy group, a hydroxyethoxy group, a propoxy group, a hydroxypropoxy group, or a butoxy group, an alkoxycarbonyl group such as a methoxycarbonyl group or an ethoxycarbonyl group, an acyl group such as a formyl group, an acetyl group, or a benzoyl group, an acyloxy group such as an acetoxy group or a butyryloxy group, and a carboxy group. The cycloalkyloxy group as R₁₃ and R₁₄ is a cycloalkyloxy group in which a total number of carbon atoms including the carbon atoms of any substituent on the cycloalkyl group is equal to or greater than 7.

Examples of the polycyclic cycloalkyloxy group having 7 or more carbon atoms in total include a norbornyloxy group, a tricyclodecanyloxy group, a tetracyclodecanyloxy group, an adamantyloxy group, and the like.

The alkoxy group having the monocyclic or polycyclic cycloalkyl group as R₁₃ and R₁₄ preferably has 7 or more carbon atoms in total and more preferably has 7 to 15 carbon atoms in total, and the alkoxy group is preferably an alkoxy group having a monocyclic cycloalkyl group. The alkoxy group which has 7 or more carbon atoms in total and a monocyclic cycloalkyl group is an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, or iso-amyloxy, substituted with a monocyclic cycloalkyl group which may have the substituent described above. The alkoxy group refers to an alkoxy group in which a total number of carbon atoms including the carbon atoms of the substituent is equal to or greater than 7. Examples of the alkoxy group include a cyclohexylmethoxy group, a cyclopentylethoxy group, a cyclohexylethoxy group, and the like, and among these, a cyclohexylmethoxy group is preferable.

Examples of the alkoxy group having a polycyclic cycloalkyl group having 7 or more carbon atoms in total include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group, and the like. Among these, a norbornylmethoxy group, a norbornylethoxy group, and the like are preferable.

Specific examples of the alkyl group of the alkylcarbonyl group as R₁₄ are the same as the specific examples of the alkyl group as R₁₃ to R₁₅ described above.

The alkylsulfonyl group and the cycloalkylsulfonyl group as R₁₄ are preferably linear, branched, or cyclic and preferably have 1 to 10 carbon atoms. Preferred examples thereof include a methanesulfonyl group, an ethanesulfonyl group, a n-propanesulfonyl group, a n-butanesulfonyl group, a cyclopenanesulfonyl group, a cyclohexanesulfonyl group, and the like.

Examples of the substituent that each of the above groups may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, and the like.

Examples of the aforementioned alkoxy group include a linear, branched, or cyclic alkoxy group having 1 to 20 carbon atoms, such as a methoxy group, an ethoxy group, a n-propoxy group, an i-propoxy group, a n-butoxy group, a 2-methylpropoxy group, a 1-methylpropoxy group, a t-butoxy group, a cyclopentyloxy group, or a cyclohexyloxy group.

Examples of the aforementioned alkoxyalkyl group include a linear, branched, or cyclic alkoxyalkyl group having 2 to 21 carbon atoms, such as a methoxymethyl group, an ethoxyethyl group, a 1-methoxyethyl group, a 2-methoxyethyl group, a 1-ethoxyethyl group, or a 2-ethoxyethyl group.

Examples of the aforementioned alkoxycarbonyl group include a linear, branched, or cyclic alkoxycarbonyl group having 2 to 21 carbon atoms, such as a methoxycarbonyl group, an ethoxycarbonyl group, a n-propoxycarbonyl group, an i-propoxycarbonyl group, a n-butoxycarbonyl group, a 2-methylpropoxycarbonyl group, a 1-methylpropoxycarbonyl group, a t-butoxycarbonyl group, a cyclopentyloxycarbonyl group, or a cyclohexyloxycarbonyl group.

Examples of the aforementioned alkoxycarbonyloxy group include a linear, branched, or cyclic alkoxycarbonyloxy group having 2 to 21 carbon atoms, such as a methoxycarbonyloxy group, an ethoxycarbonyloxy group, a n-propoxycarbonyloxy group, an i-propoxycarbonyloxy group, a n-butoxycarbonyloxy group, a t-butoxycarbonyloxy group, a cyclopentyloxycarbonyloxy group, or a cyclohexyloxycarbonyloxy group.

Examples of the ring structure that two R₁₅'s may form by being bonded to each other include a 5- or 6-membered ring that two R₁₅'s form together with a sulfur atom in Formula (ZI-4), and particularly preferably include a 5-membered ring (that is, a tetrahydrothiophene ring). The ring structure may be condensed with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group, and the like. There may be a plurality of substituents for the ring structure, and the substituents may form a ring (an aromatic or non-aromatic hydrocarbon ring, an aromatic or non-aromatic heterocyclic ring, or a polycyclic condensed ring in which two or more of these rings are combined) by being bonded to each other.

As R₁₅ in Formula (ZI-4), a methyl group, an ethyl group, a naphthyl group, a divalent group in which two R₁₅'s form a tetrahydrothiophene ring structure together with a sulfur atom by being bonded to each other, and the like are preferable.

As the substituent that R₁₃ and R₁₄ may have, a hydroxyl group, an alkoxy group, an alkoxycarbonyl group, or a halogen atom (particularly, a fluorine atom) is preferable.

l is preferably 0 or 1, and more preferably 1.

r is preferably 0 to 2.

Specific examples of the cation of the compound represented by Formula (ZI-4) in the present invention will be shown below.

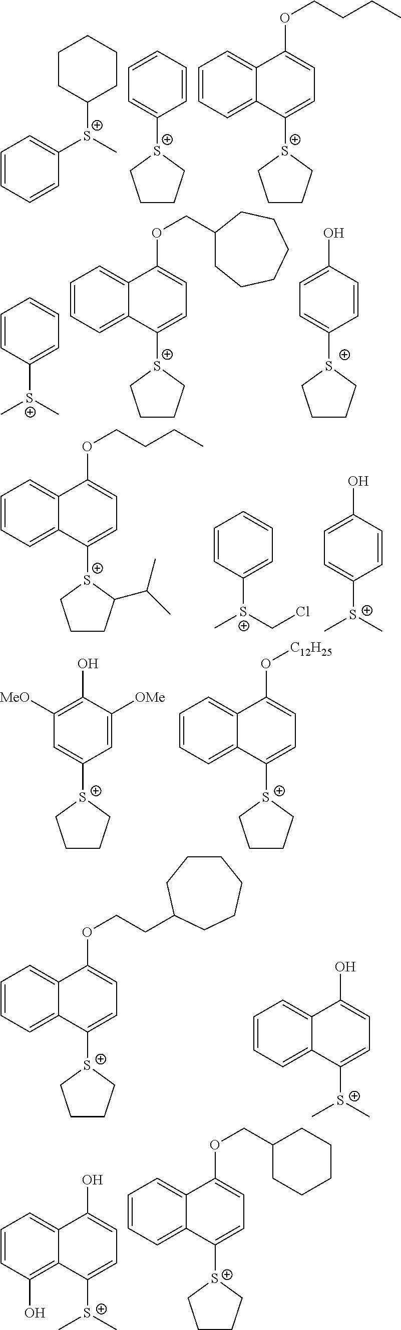

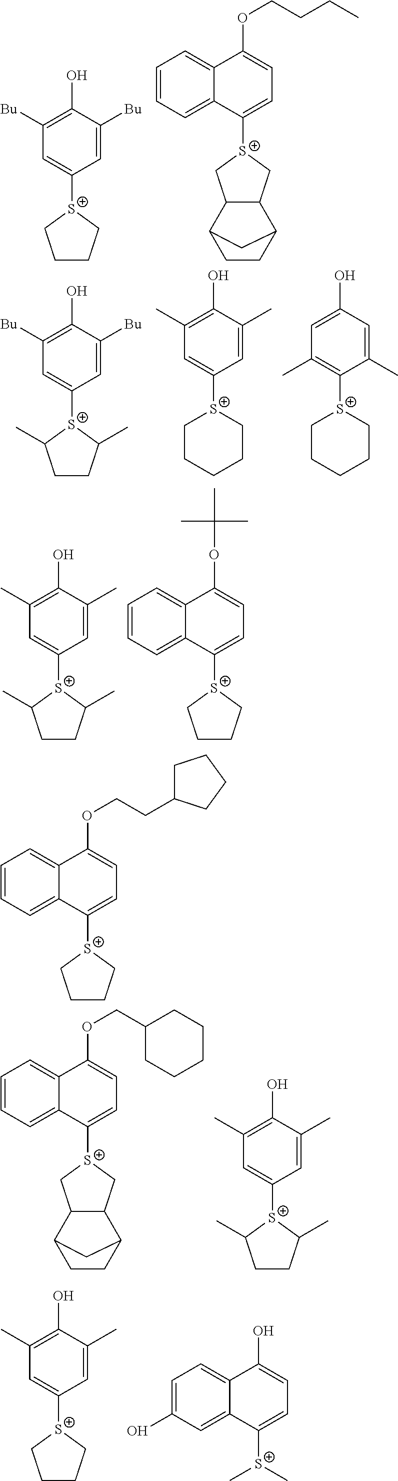

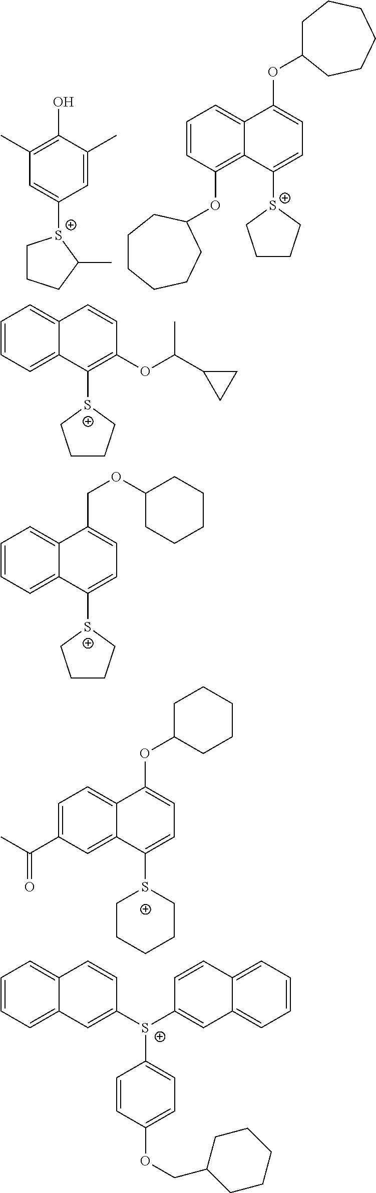

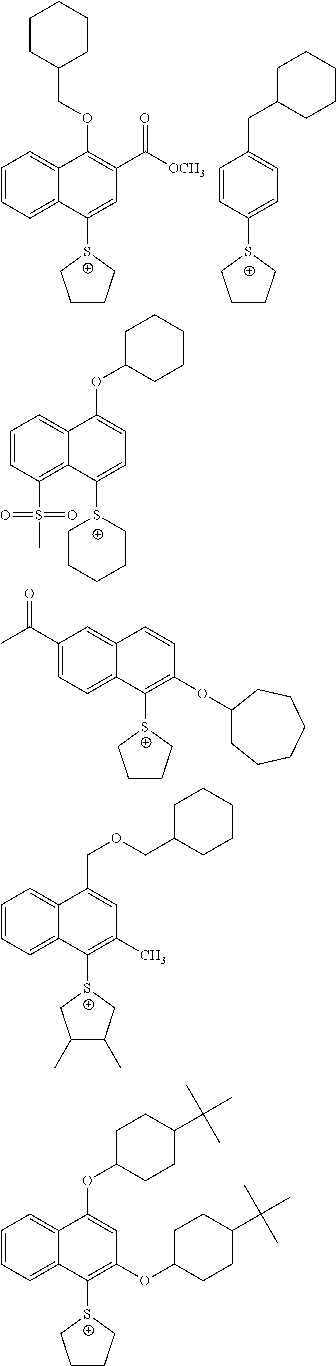 [SMILES: COC(=O)c1cc([S+]2CCCC2)c2ccccc2c1OCC1CCCCC1 ; c1cc([S+]2CCCC2)ccc1CC1CCCCC1 ; CS(=O)(=O)c1cccc2c(OC3CCCCC3)ccc([S+]3CCCCC3)c12 ; CC(=O)c1ccc2c([S+]3CCCC3)c(OC3CCCCCC3)ccc2c1 ; Cc1cc(COCC2CCCCC2)c2ccccc2c1[S+]1CC(C)C(C)C1 ; CC(C)(C)C1CCC(Oc2cc(OC3CCC(C(C)(C)C)CC3)c3ccccc3c2[S+]2CCCC2)CC1]

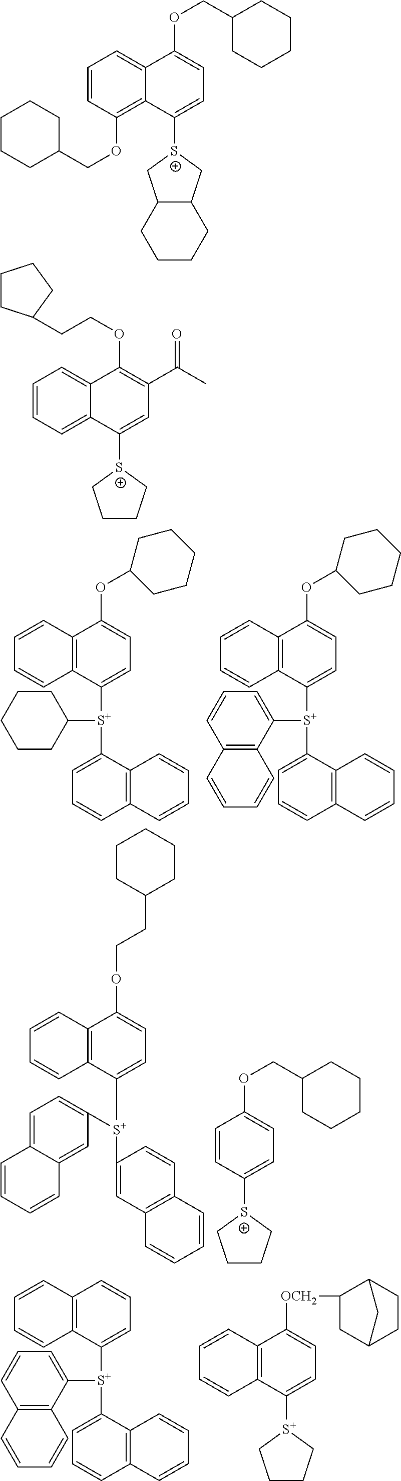

Next, Formulae (ZII) and (ZIII) will be described.

In Formulae (ZII) and (ZIII), R₂₀₄ to R₂₀₇ each independently represent an aryl group, an alkyl group, or a cycloalkyl group.

The aryl group as R₂₀₄ to R₂₀₇ is preferably a phenyl group or a naphthyl group, and more preferably a phenyl group. The aryl group as R₂₀₄ to R₂₀₇ is preferably an aryl group having a heterocyclic structure having an oxygen atom, a nitrogen atom, a sulfur atom, or the like. Examples of the skeleton of the aryl group having the heterocyclic structure include pyrrole, furan, thiophene, indole, benzofuran, benzothiophene, and the like.

Preferred examples of the alkyl group and the cycloalkyl group as R₂₀₄ to R₂₀₇ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

The aryl group, the alkyl group, and the cycloalkyl group as R₂₀₄ to R₂₀₇ may have a substituent. Examples of the substituent that the aryl group, the alkyl group, and the cycloalkyl group as R₂₀₄ to R₂₀₇ may have include an alkyl group (for example, preferably having 1 to 15 carbon atoms), a cycloalkyl group (for example, preferably having 3 to 15 carbon atoms), an aryl group (for example, preferably having 6 to 15 carbon atoms), an alkoxy group (for example, preferably having 1 to 15 carbon atoms), a halogen atom, a hydroxyl group, a phenyl group, and the like.

Z⁻ represents a non-nucleophilic anion, and examples thereof include the same non-nucleophilic anion as Z⁻ in Formula (ZI).

Examples of the acid generator also include compounds represented by the following Formulae (ZIV), (ZV), and (ZVI).

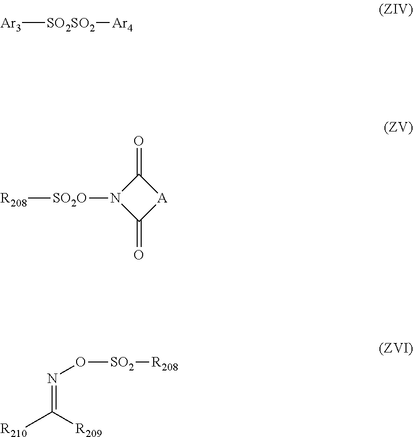

In Formulae (ZIV) to (ZVI), Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

Specific examples of the aryl group as Ar₃, Ar₄, R₂₀₈, R₂₀₉, and R₂₁₀ include are the same as the specific examples of the aryl group as R₂₀₁, R₂₀₂, and R₂₀₃ in Formula (ZI-1) described above.

Specific examples of the alkyl group and the cycloalkyl group as R₂₀₈, R₂₀₉, and R₂₁₀ are the same as the specific examples of the alkyl group and the cycloalkyl group as R₂₀₁, R₂₀₂, and R₂₀₃ in Formula (ZI-2) described above.

Examples of the alkylene group as A include an alkylene group having 1 to 12 carbon atoms (for example, a methylene group, an ethylene group, a propylene group, an isopropylene group, a butylene group, or an isobutylene group). Examples of the alkenylene group as A include an alkenylene group having 2 to 12 carbon atoms (for example, an ethenylene group, a propenylene group, or a butenylene group). Examples of the arylene group as A include an arylene group having 6 to 10 carbon atoms (for example, a phenylene group, a tolylene group, or a naphthylene group).

Among the above acid generators, the compounds represented by Formulae (ZI) to (ZIII) are more preferable.

The acid generator is preferably a compound generating 1 sulfonic acid group or 1 imide group, more preferably a compound generating monovalent perfluoroalkanesulfonic acid, a compound generating aromatic sulfonic acid substituted with a monovalent fluorine atom or a fluorine atom-containing group, or a compound generating imidic acid substituted with a monovalent fluorine atom or a fluorine atom-containing group, even more preferably a sulfonium salt of fluorine-substituted alkanesulfonic acid, fluorine-substituted benzenesulfonic acid, fluorine-substituted imidic acid, or fluorine-substituted methide acid. As a usable acid generator, fluorine-substituted alkanesulfonic acid, fluorine-substituted benzenesulfonic acid, or fluorine-substituted imidic acid generating an acid having a pKa of equal to or less than −1 is particularly preferable, and these improve sensitivity.

Particularly preferred examples of the acid generator will be shown below.

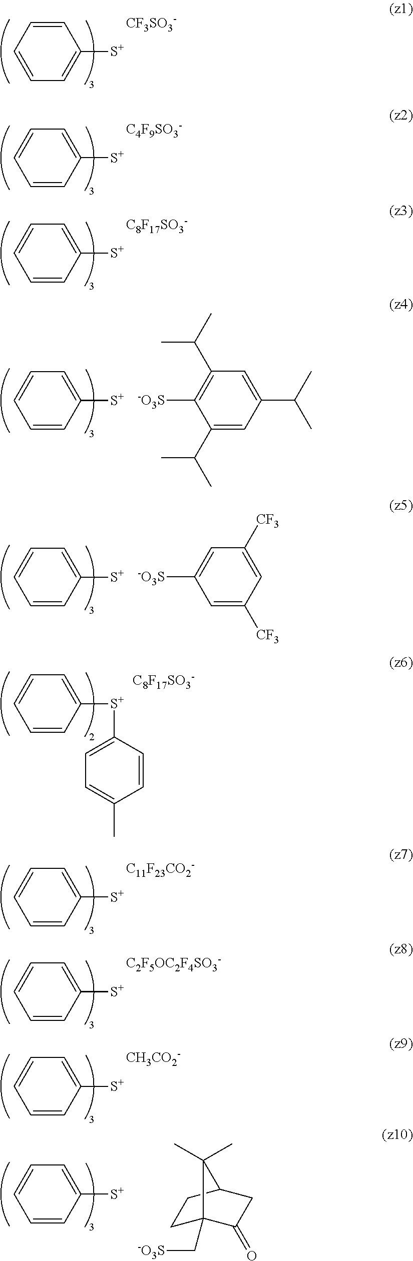

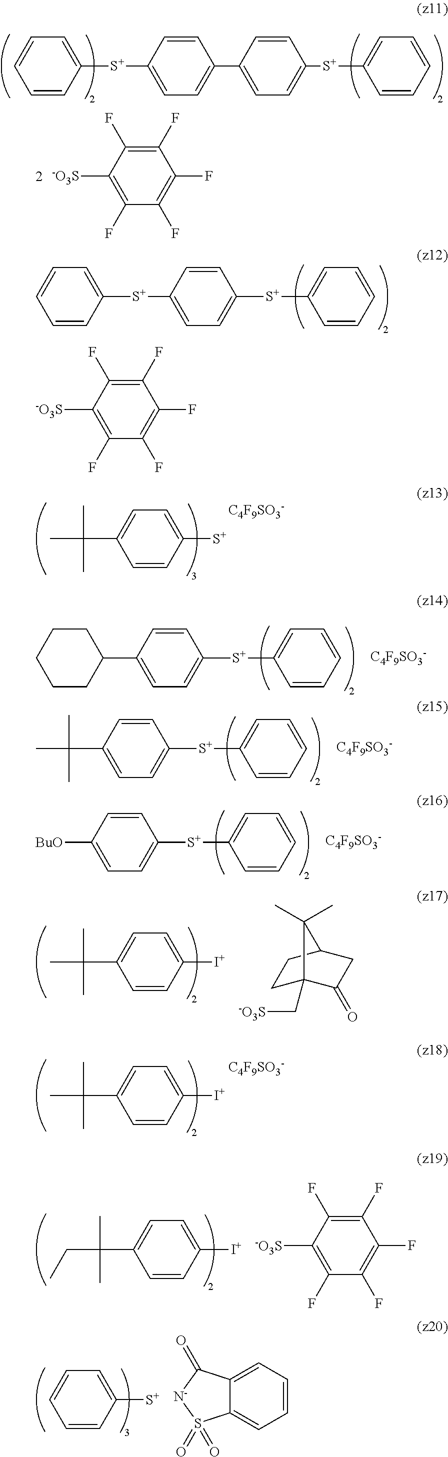

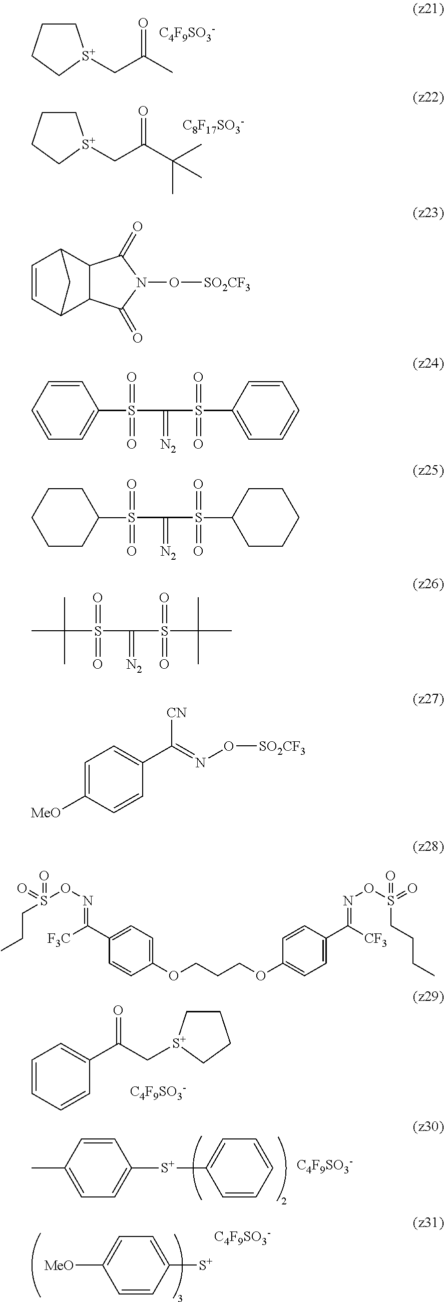

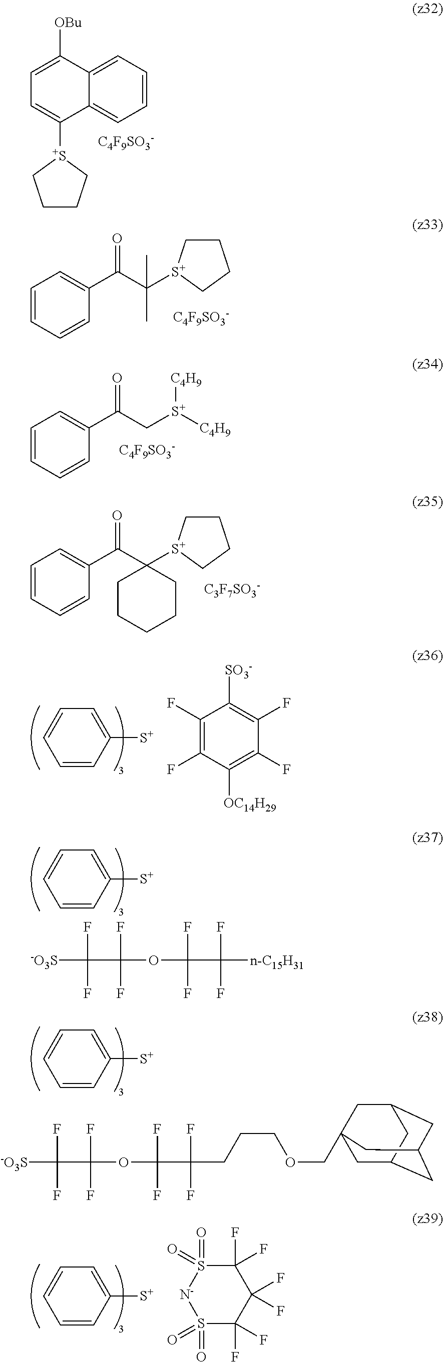

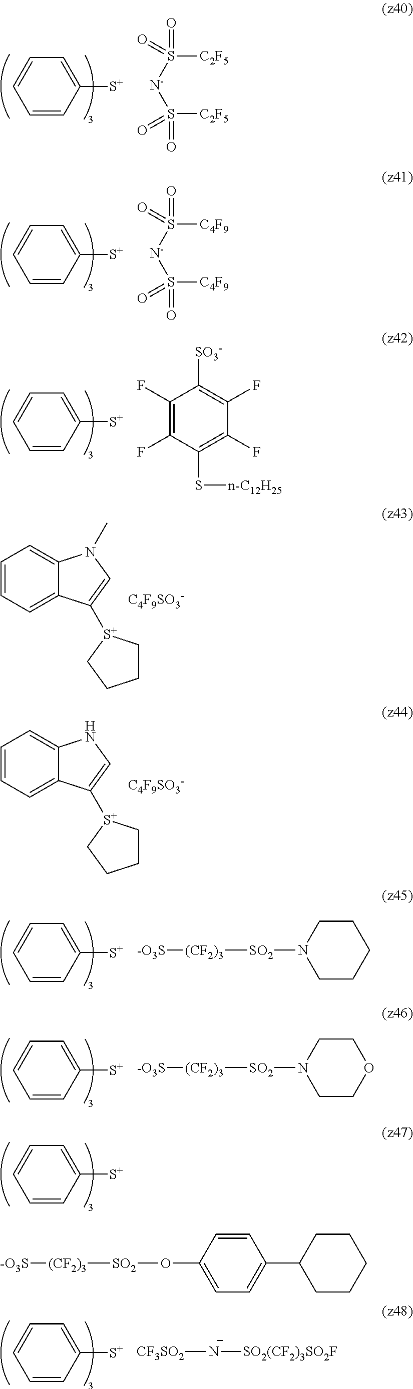

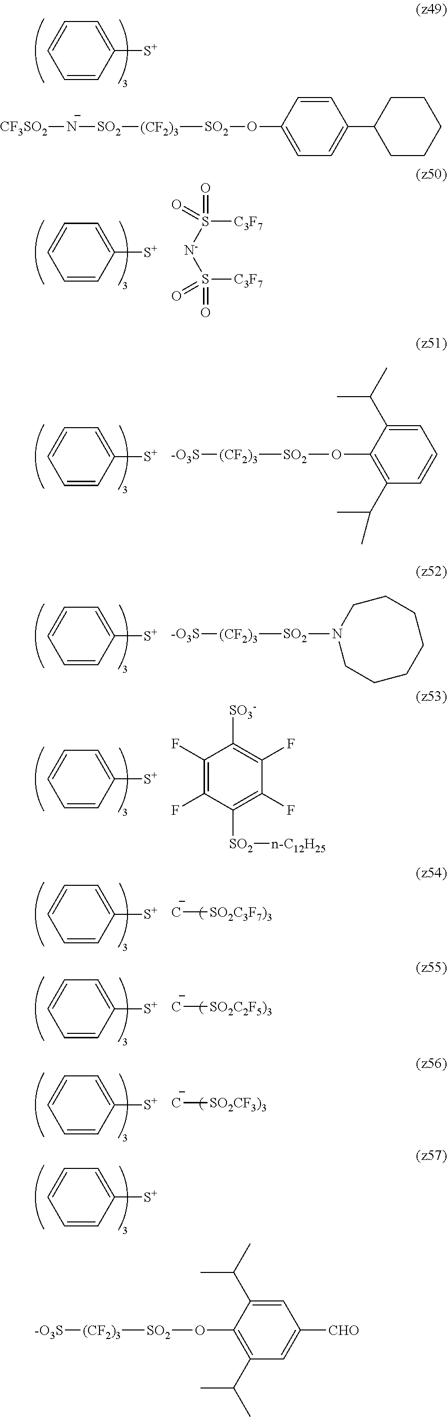

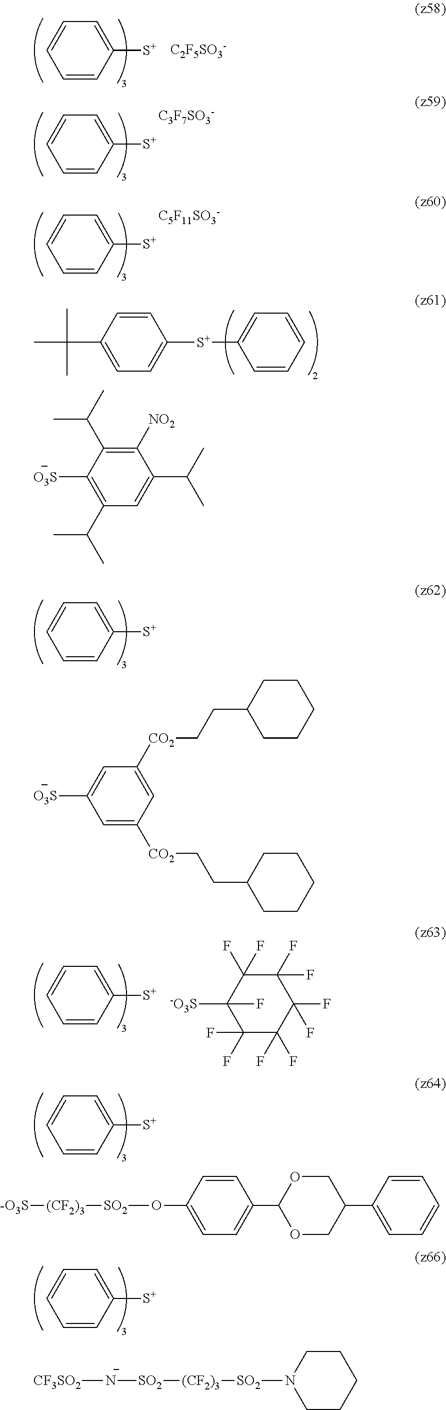

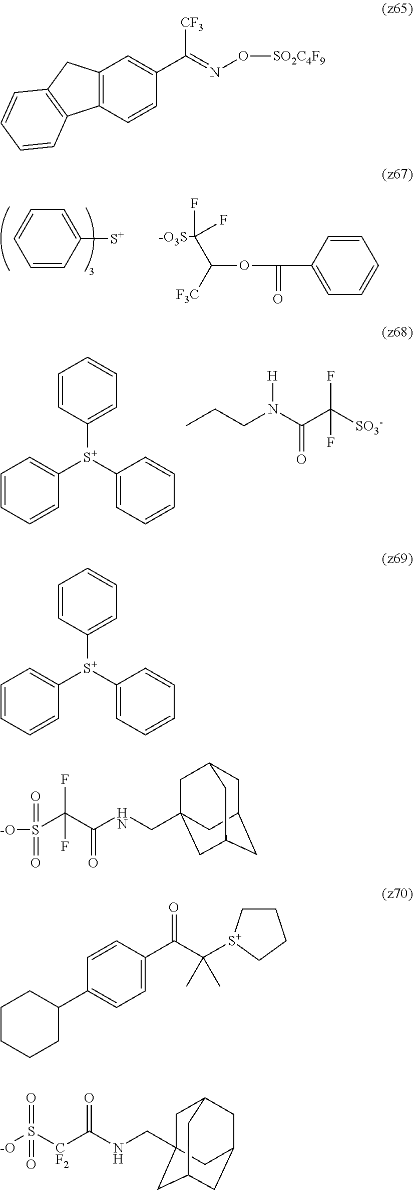

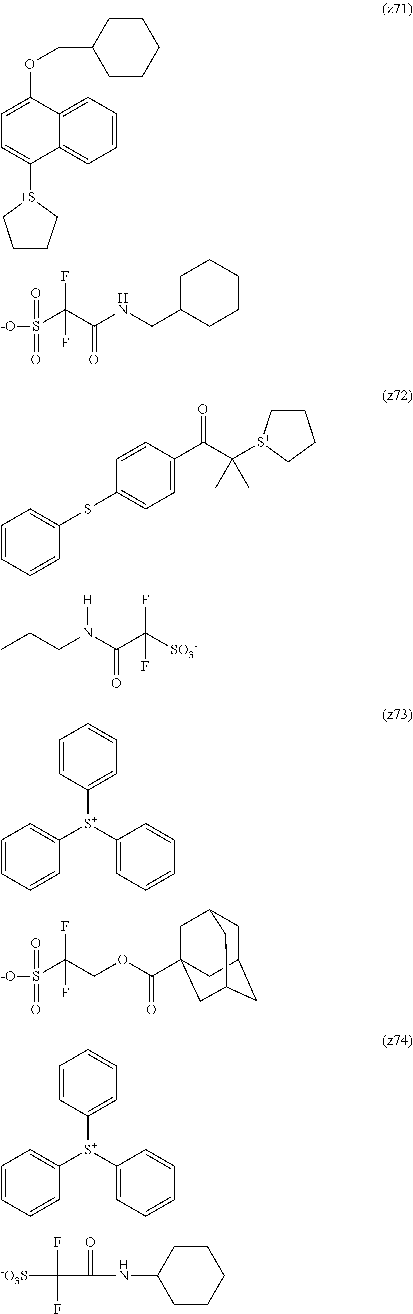

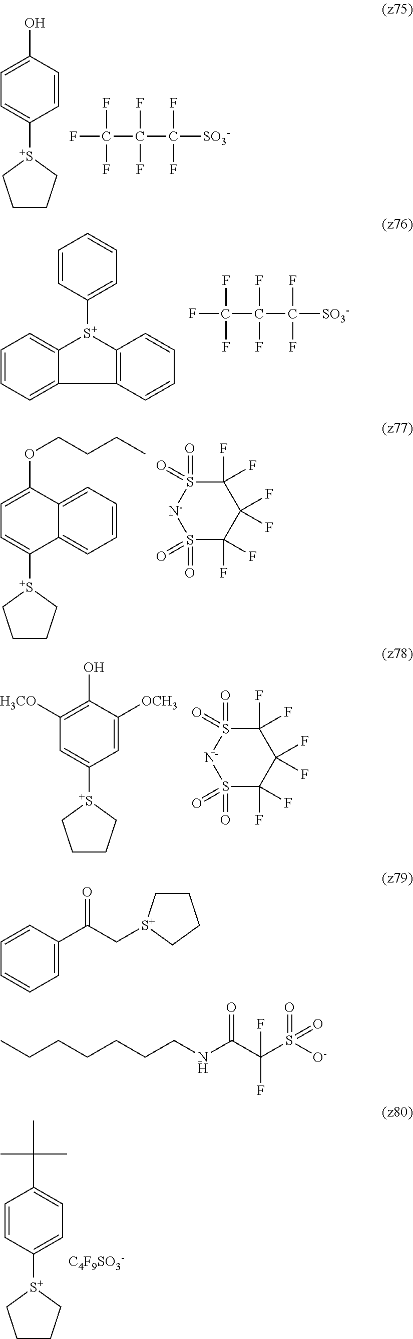

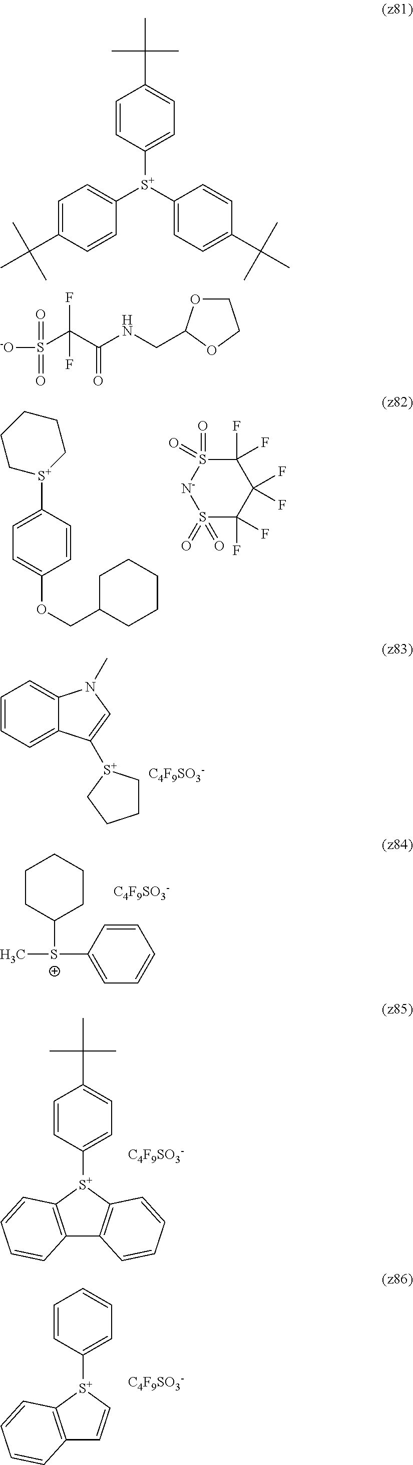

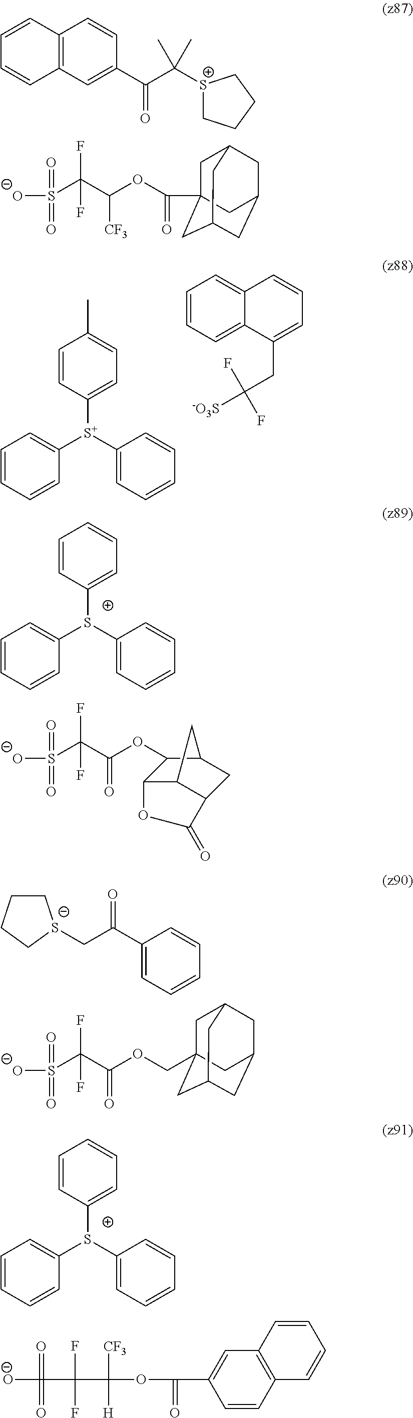

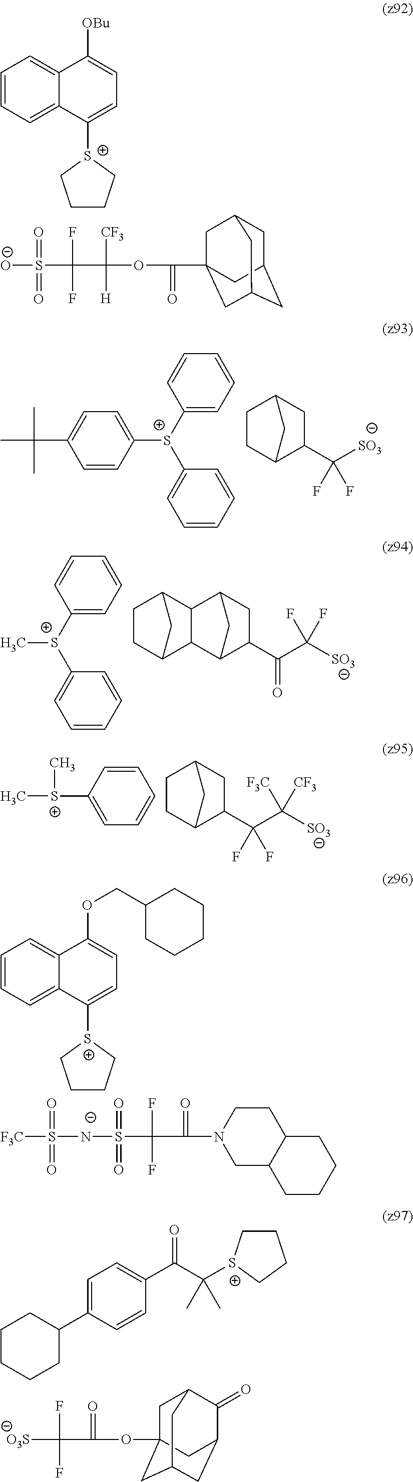

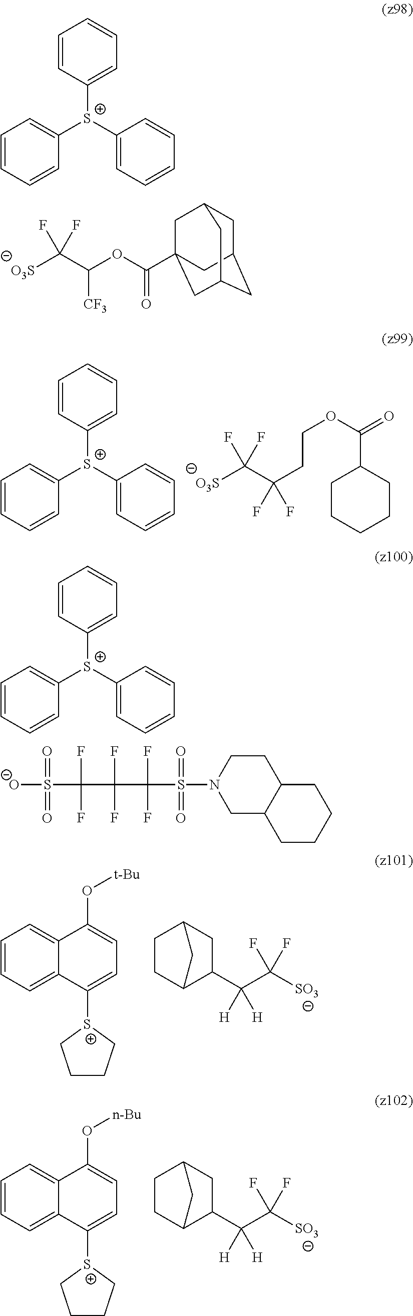

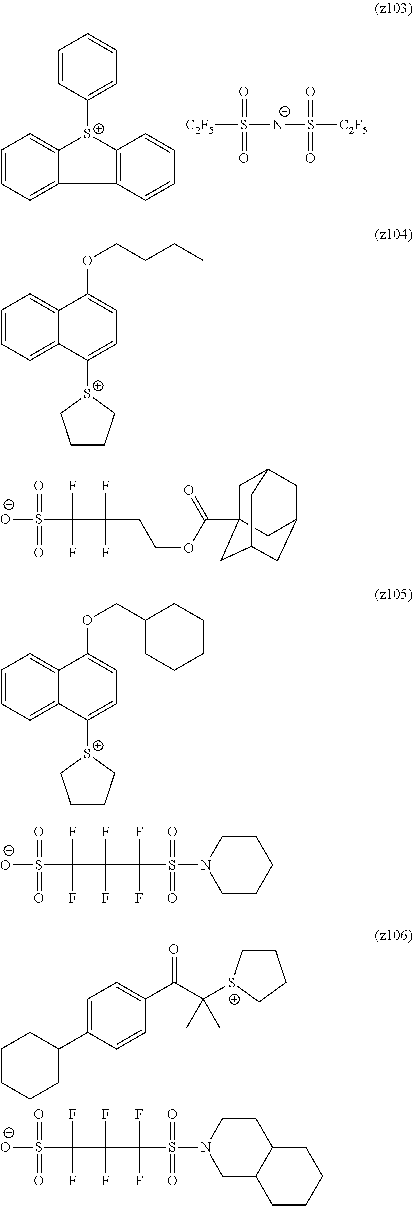

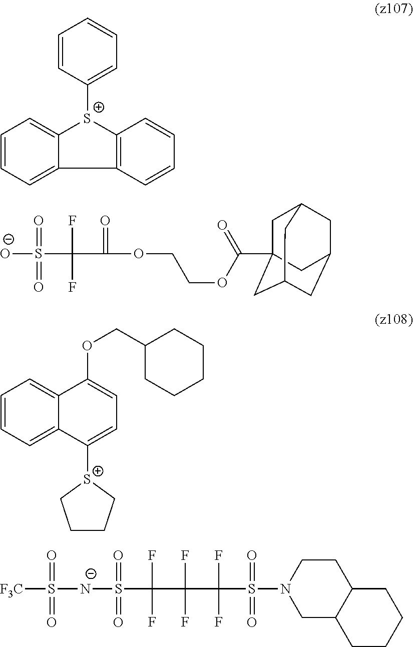 [SMILES: c1ccc(-[s+]2c3ccccc3c3ccccc32)cc1 ; O=C(OCCOC(=O)C(F)(F)S(=O)(=O)[O-])C12CC3CC(CC(C3)C1)C2 ; c1ccc2c([S+]3CCCC3)ccc(OCC3CCCCC3)c2c1 ; O=S(=O)([N-]S(=O)(=O)C(F)(F)C(F)(F)C(F)(F)S(=O)(=O)N1CCC2CCCCC2C1)C(F)(F)F]

Particularly preferred examples of the compound (B) having the anion represented by any one of Formulae (B-1) to (B-3) described above will be shown below, but the present invention is not limited thereto.

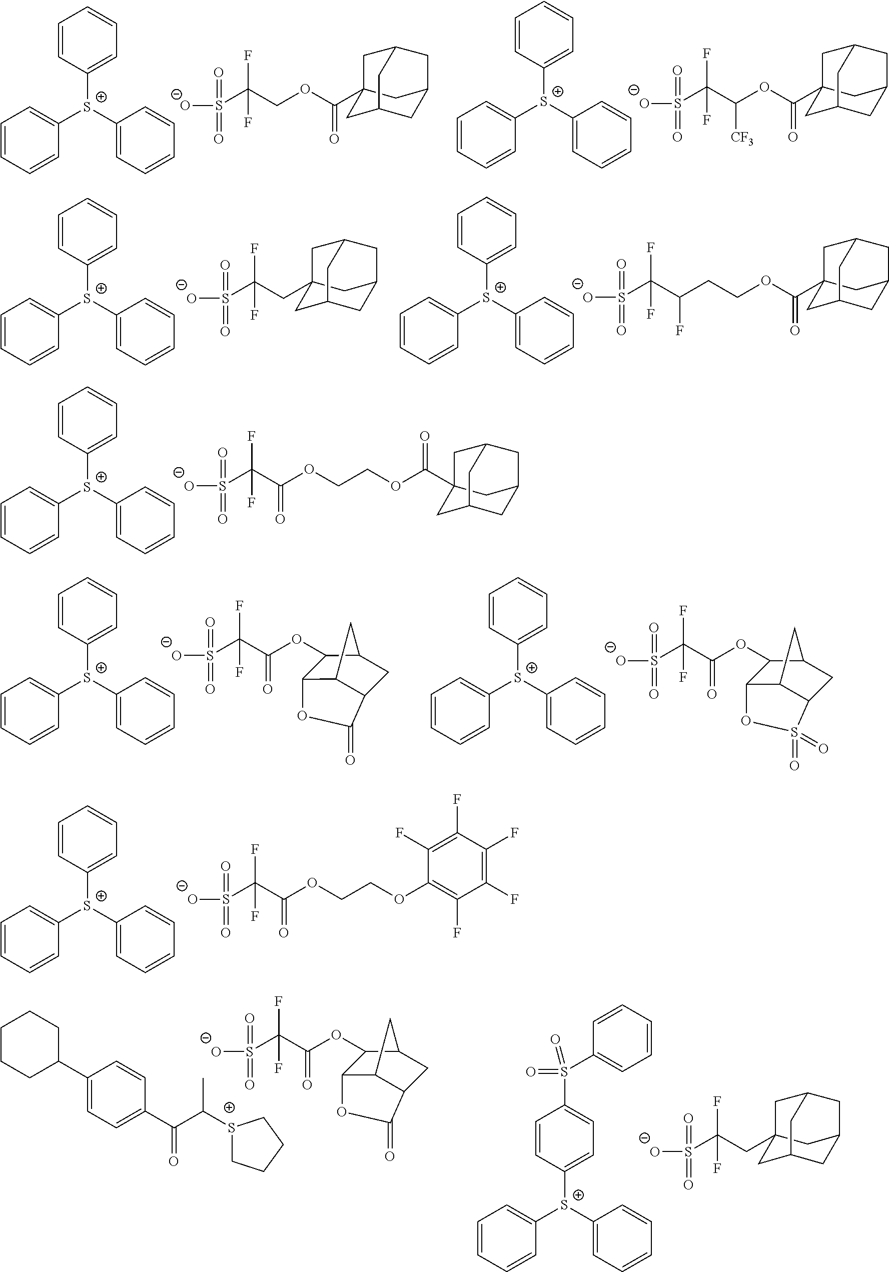

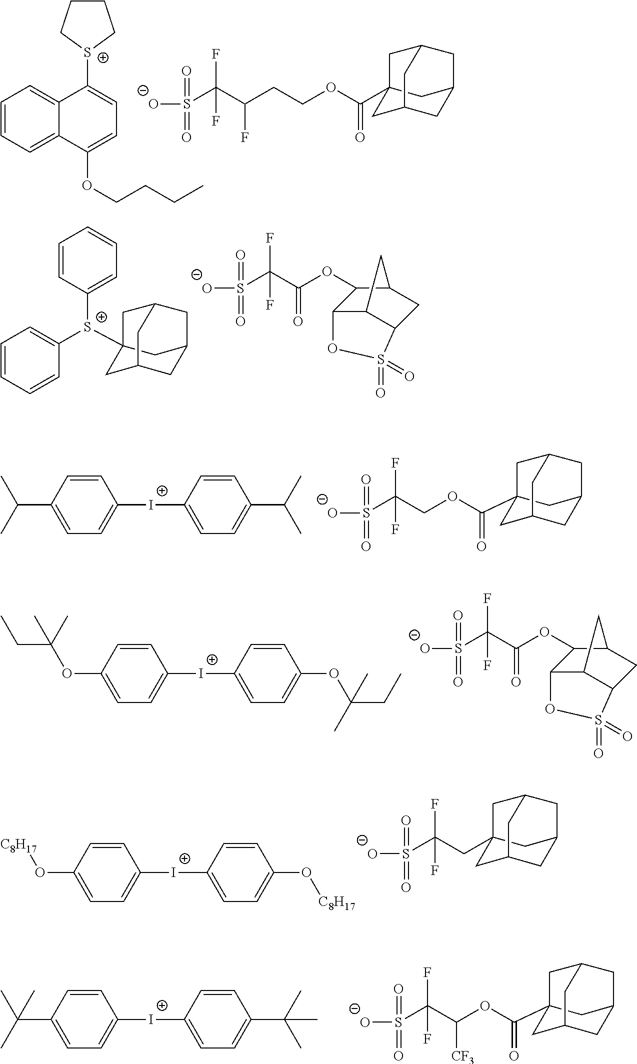

The acid generator can be synthesized by a known method. For example, the acid generator can be synthesized based on the methods described in JP2007-161707A, paragraphs “0200” to “0210” of JP2010-100595A, paragraphs “0051” to “0058” of WO2011/093280A, paragraphs “0382” to “0385” of WO2008/153110A, JP2007-161707A, and the like.

One kind of acid generator can be used singly, or two or more kinds thereof may be used in combination.

A content of the compound generating an acid by being irradiated with actinic rays or radiation in the composition is, with respect to the total solid content of the first resist composition, preferably equal to or greater than 0.1% by mass, more preferably equal to or greater than 0.5% by mass, even more preferably equal to or greater than 2% by mass, and particularly preferably equal to or greater than 5% by mass. In a case where the content is within the above range, particularly by performing the step (C′) described above, it is possible to form a negative pattern that is not easily damaged due to the solvent in the composition for forming a planarization layer (a). In contrast, the content of the compound generating an acid by being irradiated with actinic rays or radiation in the composition is, with respect to the total solid content of the first resist composition, preferably equal to or less than 30% by mass, more preferably equal to or less than 25% by mass, and even more preferably equal to or less than 15% by mass, because then the volumetric shrinkage of the negative pattern that results from the decomposition of the compound generating an acid by being irradiated with actinic rays or radiation can be inhibited particularly in a case where the step (C′) is performed.

[3] (C) Solvent

The first resist composition generally contains a solvent (C).

Examples of the solvent which can be used at the time of preparing the first resist composition include an organic solvent such as alkylene glycol monoalkyl ether carboxylate, alkylene glycol monoalkyl ether, a lactic acid alkyl ester, alkyl alkoxypropionate, cyclic lactone (preferably having 4 to 10 carbon atoms), a monoketone compound which may have a ring (preferably having 4 to 10 carbon atoms), alkylene carbonate, alkyl alkoxyacetate, or alkyl pyruvate.

Specific examples of these solvents include those described in paragraphs “0441” to “0455” is US2008/0187860A”. As the solvent, methyl 2-hydroxyisobutyrate can also be used.

In the present invention, a mixed solvent obtained by mixing a solvent, which contains a hydroxyl group in the structure, as an organic solvent with a solvent not containing a hydroxyl group may be used.

The solvent containing a hydroxyl group and the solvent not containing a hydroxyl group can be appropriately selected from the compounds exemplified above. The solvent containing a hydroxyl group is preferably an alkylene glycol monoalkyl ether, alkyl lactate, or the like, and more preferably propylene glycol monomethyl ether (PGME, in another name, 1-methoxy-2-propanol) or ethyl lactate. The solvent not containing a hydroxyl group is preferably alkylene glycol monoalkyl ether acetate, alkyl alkoxypropionate, a monoketone compound which may contain a ring, cyclic lactone, alkyl acetate, or the like. Among these, propylene glycol monomethyl ether acetate (PGMEA, in another name, 1-methoxy-2-acetoxypropane), ethyl ethoxy propionate, 2-heptanone, γ-butyrolactone, cyclohexanone, and butyl acetate are particularly preferable, and propylene glycol monomethyl ether acetate, ethyl ethoxypropionate, and 2-heptanone are most preferable.

A mixing ratio (mass) between the solvent containing a hydroxyl group and the solvent not containing a hydroxyl group is 1/99 to 99/1, preferably 10/90 to 90/10, and more preferably 20/80 to 60/40. In view of coating uniformity, a mixed solvent in which a content of the solvent not containing a hydroxyl group is equal to or greater than 50% by mass is particularly preferable.

It is preferable that the solvent contains propylene glycol monomethyl ether acetate. Furthermore, it is preferable that the solvent is a solvent composed only of propylene glycol monomethyl ether acetate or a mixed solvent composed of two or more kinds of solvents containing propylene glycol monomethyl ether acetate.

[4] Hydrophobic Resin (D)

The first resist composition according to the present invention may contain a hydrophobic resin (hereinafter, referred to as a “hydrophobic resin (D)” or simply referred to as a “resin (D)” as well) particularly when the composition is subjected to liquid immersion exposure. It is preferable that the hydrophilic resin (D) is different from the resin (A).

In a case where the composition contains the hydrophobic resin (D), the hydrophobic resin (D) is localized in the surface layer of a film. As a result, in a case where water is used as an immersion medium, a static/dynamic contact angle of the resist film surface with respect to water is improved, and hence the conformity to the immersion liquid can be improved.

It is preferable to design the hydrophobic resin (D) such that the resin is localized within an interface as described above. However, unlike a surfactant, the hydrophobic resin (D) does not need to have a hydrophilic group in a molecule and may not make a contribution to the homogeneous mixing of a polar substance with a nonpolar substance.

From the viewpoint of being localized within the surface layer of a film, the hydrophobic resin (D) preferably has any one or more kinds among a “fluorine atom”, a “silicon atom”, and a “CH₃ partial structure contained in a side chain portion of the resin”, and more preferably has two or more kinds among the above.

In a case where the hydrophobic resin (D) contains a fluorine atom and/or a silicon atom, the fluorine atom and/or the silicon atom in the hydrophobic resin (D) may be contained in a main chain or a side chain of the resin.

In a case where the hydrophobic resin (D) contains a fluorine atom, the hydrophobic resin (D) is preferably a resin which has, as a partial structure having the fluorine atom, a fluorine atom-containing alkyl group, a fluorine atom-containing cycloalkyl group, or a fluorine atom-containing aryl group.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom and which may further have a substituent other than a fluorine atom.

The fluorine atom-containing cycloalkyl group is a monocyclic or polycyclic cycloalkyl group in which at least one hydrogen atom is substituted with a fluorine atom and which may further have a substituent other than a fluorine atom.

Examples of the fluorine atom-containing aryl group include an aryl group in which at least one hydrogen atom is substituted with a fluorine atom, such as a phenyl group or a naphthyl group. The fluorine atom-containing aryl group may further have a substituent other than a fluorine atom.

Preferred examples of the fluorine atom-containing alkyl group, the fluorine atom-containing cycloalkyl group, and the fluorine atom-containing aryl group include groups represented by the following Formulae (F2) to (F4), but the present invention is not limited thereto.

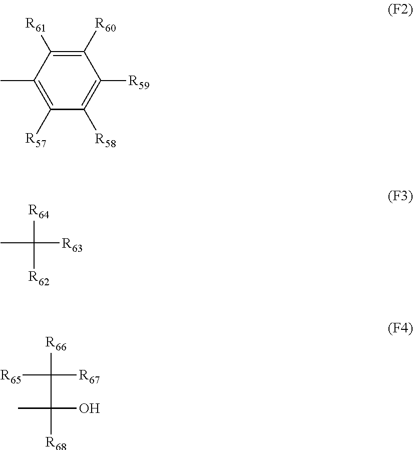

In Formulae (F2) to (F4), R₅₇ to R₆₈ each independently represent a hydrogen atom, a fluorine atom, or an alkyl group (linear or branched). Here, at least one of R₅₇, R₅₈, R₅₉, R₆₀, or R₆₁, at least one of R₆₂, R₆₃, or R₆₄, and at least one of R₆₅, R₆₆, R₆₇, or R₆₈ each independently represent a fluorine atom or an alkyl group (preferably having 1 to 4 carbon atoms) in which at least 1 hydrogen atom is substituted with a fluorine atom.

It is preferable that all of R₅₇ to R₆₁ and R₆₅ to R₆₇ represent a fluorine atom. R₆₂, R₆₃, and R₆₈ preferably represent an alkyl group (preferably having 1 to 4 carbon atoms) in which at least one hydrogen atom is substituted with a fluorine atom, and more preferably represent a perfluoroalkyl group having 1 to 4 carbon atoms. R₆₂ and R₆₃ may form a ring by being bonded to each other.

Specific examples of the group represented by Formula (F2) include a p-fluorophenyl group, a pentafluorophenyl group, a 3,5-di(trifluoromethyl)phenyl group, and the like.

Specific examples of the group represented by Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. Among these, a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable, and a hexafluoroisopropyl group and a heptafluoroisopropyl group are more preferable.

Specific examples of the group represented by Formula (F4) include —C(CF₃)₂OH, —C(C₂F₅)₂OH, —C(CF₃)(CH₃)OH, —CH(CF₃)OH, and the like. Among these, —C(CF₃)₂OH is preferable.

The fluorine atom-containing partial structure may be directly bonded to a main chain or may be bonded to a main chain through a group selected from the group consisting of an alkylene group, a phenylene group, an ether bond, a thioether bond, a carbonyl group, an ester bond, an amide bond, a urethane bond, and a ureilene bond or through a group obtained by combining two or more of the above groups.

Specific examples of the fluorine atom-containing repeating unit will be shown below, but the present invention is not limited thereto.

In the specific examples, X₁ represents a hydrogen atom, —CH₃, —F, or —CF₃. X₂ represents —F or —CF₃.

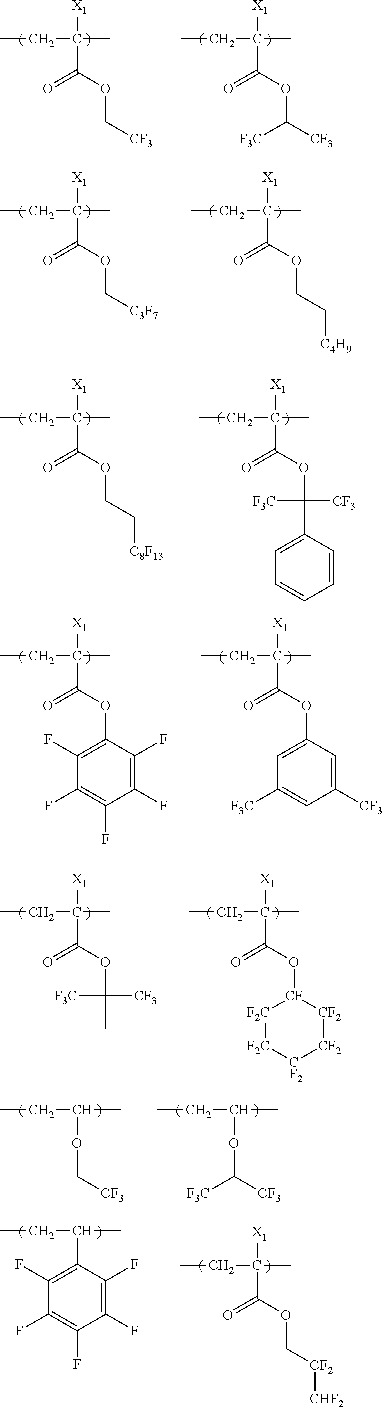

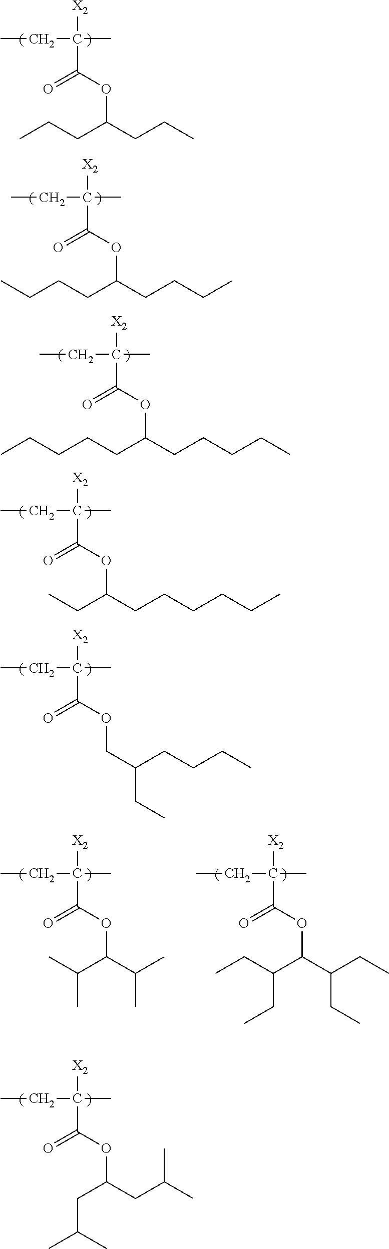

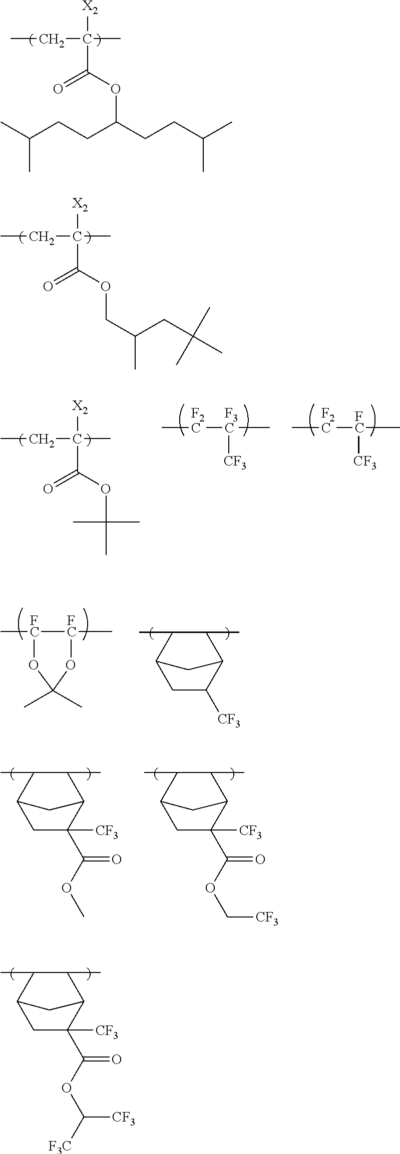

The hydrophobic resin (D) may contain a silicon atom. The hydrophobic resin (D) is preferably a resin which has, as a silicon atom-containing partial structure, an alkylsilyl structure (preferably a trialkylsilyl group) or a cyclic siloxane structure.

Specific examples of the alkylsilyl structure or the cyclic siloxane structure include groups represented by the following Formulae (CS-1) to (CS-3).

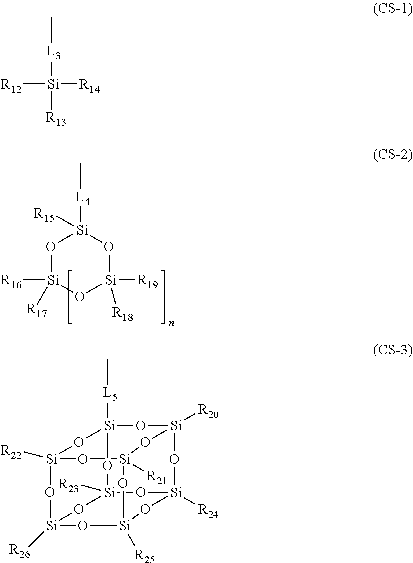

In Formulae (CS-1) to (CS-3), R₁₂ to R₂₆ each independently represent a linear or branched alkyl group (preferably having 1 to 20 carbon atoms) or a cycloalkyl group (preferably having 3 to 20 carbon atoms).

L₃ to L₅ represent a single bond or a divalent linking group. Examples of the divalent linking group include a linking group, which is composed only of a group selected from the group consisting of an alkylene group, a phenylene group, an ether bond, a thioether bond, a carbonyl group, an ester bond, an amide bond, an urethane bond, and a urea bond, or a linking group (preferably having 12 or less carbon atoms in total) obtained by combining two or more of the above groups.

n represents an integer of 1 to 5. n is preferably an integer of 2 to 4.

Specific examples of repeating units having the group represented by Formulae (CS-1) to (CS-3) will be shown below, but the present invention is not limited thereto. In the specific examples, X₁ represents a hydrogen atom, —CH₃, —F, or —CF₃.

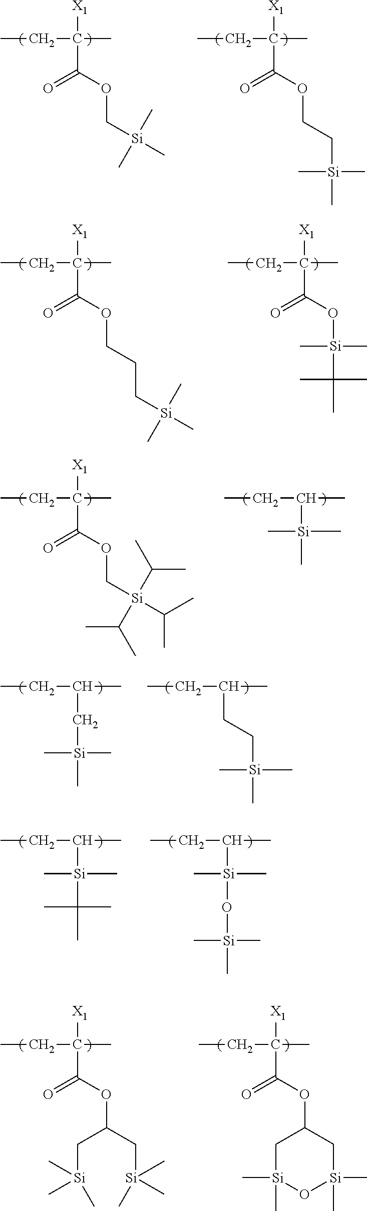

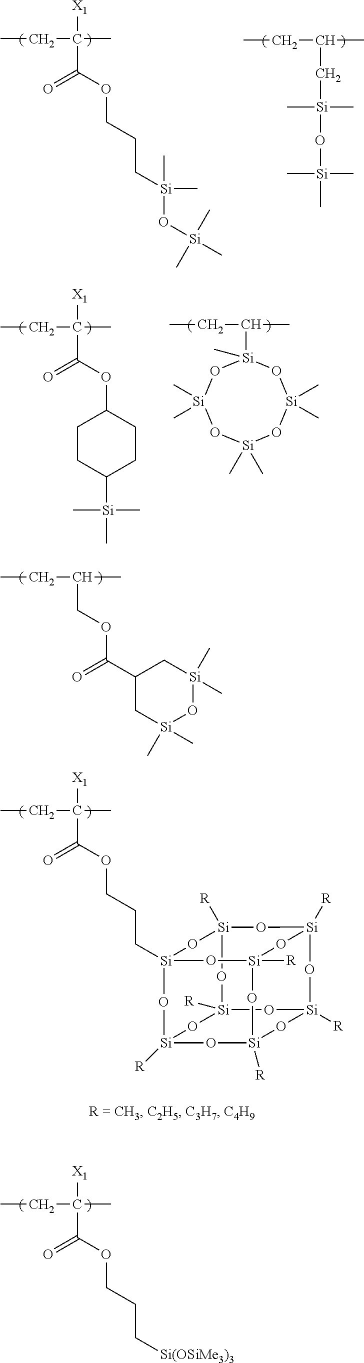

As described above, it is also preferable that the hydrophobic resin (D) contains a CH₃ partial structure in a side chain portion.

Herein, the CH₃ partial structure that the hydrophobic resin (D) has in a side chain portion (hereinafter, simply referred to as a “side chain CH₃ partial structure” as well) also includes a CH₃ partial structure that an ethyl group, a propyl group, or the like has.

A methyl group directly bonded to a main chain of the resin (D) (for example, an α-methyl group of a repeating unit having a methacrylic acid structure) makes a small contribution to the surface localization of the resin (D) due to the influence of the main chain. Accordingly, such a methyl group is not included in the CH₃ partial structure in the present invention.

More specifically, in a case where the resin (D) contains a repeating unit, which is derived from a monomer having a polymerizable moiety having a carbon-carbon double bond, such as a repeating unit represented by the following Formula (M), and R₁₁ to R₁₄ represent CH₃, the CH₃ is not included in the CH₃ partial structure that the side chain portion in the present invention has.

In contrast, a CH₃ partial structure linked to a C—C main chain through some atoms is regarded as corresponding to the CH₃ partial structure in the present invention. For example, in a case where R₁₁ represents an ethyl group (CH₂CH₃), the ethyl group is regarded as having “one” CH₃ partial structure in the present invention.

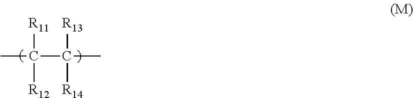

In Formula (M), R₁₁ to R₁₄ each independently represent a side chain portion.

Examples of R₁₁ to R₁₄ as a side chain portion include a hydrogen atom, a monovalent organic group, and the like.

Examples of the monovalent organic group as R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group, and the like. These groups may further have a substituent.

The hydrophobic resin (D) is preferably a resin having a repeating unit having the CH₃ partial structure in a side chain portion. It is more preferable that the hydrophobic resin (D) has, as such a repeating unit, at least one kind of repeating unit (x) between a repeating unit represented by the following Formula (II) and a repeating unit represented by the following Formula (III).

Hereinafter, the repeating unit represented by Formula (II) will be specifically described.

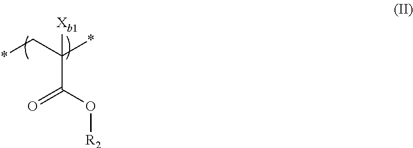

In Formula (II), X_{b1} represents a hydrogen atom, an alkyl group, a cyano group, or a halogen atom, and R₂ represents an organic group which has one or more CH₃ partial structures and is stable against an acid. Herein, it is preferable that the organic group stable against an acid is more specifically an organic group which does not have the “group generating a polar group by being decomposed by the action of an acid” described above for the resin (A).

The alkyl group as X_{b1} preferably has 1 to 4 carbon atoms, and examples thereof include a methyl group, an ethyl group, a propyl group, a hydroxymethyl group, a trifluoromethyl group, and the like. The alkyl group is preferably a methyl group.

X_{b1} is preferably a hydrogen atom or a methyl group.

Examples of R₂ include an alkyl group, a cycloalkyl group, an alkenyl group, a cycloalkenyl group, an aryl group, and an aralkyl group which have at least one or more CH₃ partial structures. The above cycloalkyl group, alkenyl group, cycloalkenyl group, aryl group, and aralkyl group may further have an alkyl group has a substituent.

R₂ is preferably an alkyl group or an alkyl-substituted cycloalkyl group having at least one or more CH₃ partial structures.

The organic group as R₂ that has one or more CH₃ partial structures and is stable against an acid preferably has 2 to 10 CH₃ partial structures and more preferably has 2 to 8 CH₃ partial structures.

The alkyl group as R₂ that has one or more CH₃ partial structures is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. Among these, an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group are more preferable.

The cycloalkyl group as R₂ that has one or more CH₃ partial structures may be monocyclic or polycyclic. Specific examples thereof include a group having a monocyclo, bicyclo, tricyclo, or tetracyclo structure having 5 or more carbon atoms. The number of carbon atoms of the cycloalkyl group is preferably 6 to 30, and particularly preferably 7 to 25. Examples of the preferred cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group, and a cyclododecanyl group. Among these, an adamantyl group, a norbornyl group, a cyclohexyl group, a cyclopentyl group, a tetracyclododecanyl group, and a tricyclodecanyl group are more preferable, and a norbornyl group, a cyclopentyl group, and a cyclohexyl group are even more preferable.

The alkenyl group as R₂ that has one or more CH₃ partial structures is preferably a linear or branched alkenyl group having 1 to 20 carbon atoms, and more preferably a branched alkenyl group.

The aryl group as R₂ that has one or more CH₃ partial structures is preferably an aryl group having 6 to 20 carbon atoms. Examples thereof include a phenyl group and a naphthyl group, and between these, a phenyl group is preferable.

The aralkyl group as R₂ that has one or more CH₃ partial structures is preferably an aralkyl group having 7 to 12 carbon atoms. Examples thereof include a benzyl group, a phenethyl group, a naphthyl methyl group, and the like.

Specific examples of the alkyl group as R₂ that has two or more CH₃ partial structures include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t butylcyclohexyl group, an isobornyl group, and the like. The hydrocarbon group is more preferably an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di tert-butylcyclohexyl group, a 4-isopropylcyclohexyl group, a 4-t butylcyclohexyl group, or an isobornyl group.

Specific examples preferred as the repeating unit represented by Formula (II) will be shown below, but the present invention is not limited thereto.

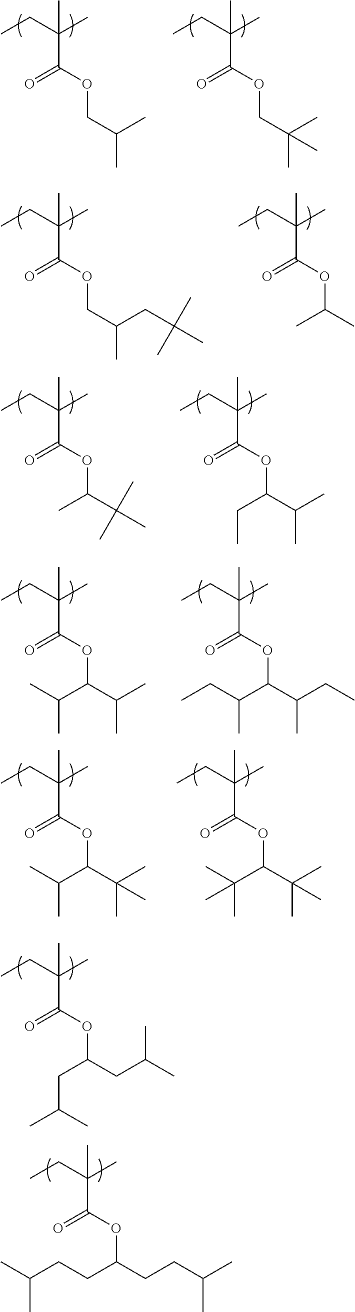

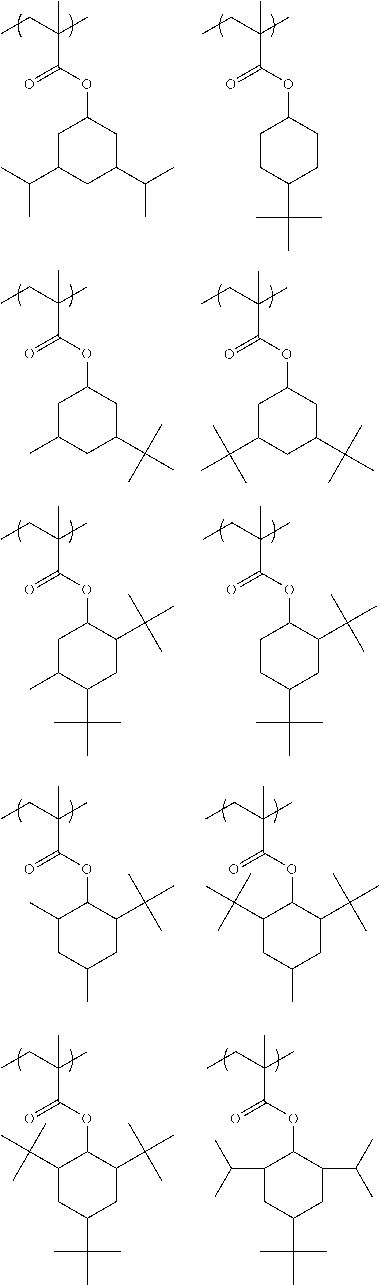

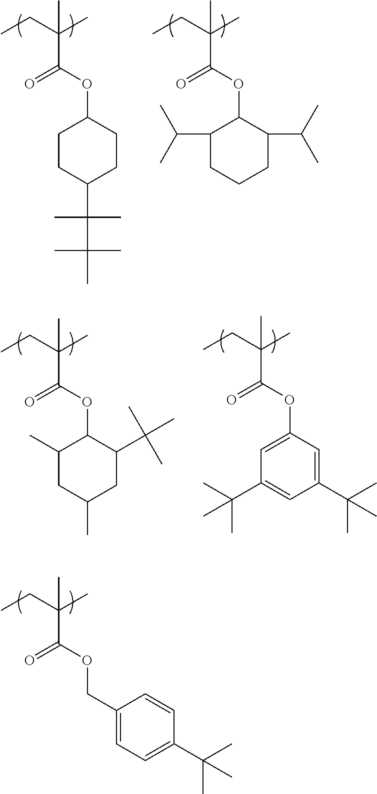

The repeating unit represented by Formula (II) is preferably a (non-acid-decomposable) repeating unit stable against an acid. Specifically, the repeating unit is preferably a repeating unit which does not have a group generating a polar group by being decomposed by the action of an acid.

Hereinafter, the repeating unit represented by Formula (III) will be specifically described.

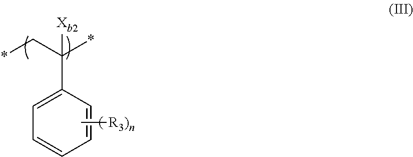

In Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group as X_{b2} is preferably an alkyl group having 1 to 4 carbon atoms, and examples thereof include a methyl group, an ethyl group, a propyl group, a hydroxymethyl group, a trifluoromethyl group, and the like. X_{b2} is preferably a hydrogen atom.

R₃ is an organic group stable against an acid. Therefore, more specifically, R₃ is preferably an organic group which does not have the “group generating a polar group by being decomposed by the action of an acid” described above for the resin (A).

Examples of R₃ include an alkyl group having one or more CH₃ partial structures.

The organic group as R₃ that has one or more CH₃ partial structures and is stable against an acid preferably has 1 to 10 CH₃ partial structures, more preferably has 1 to 8 CH₃ partial structures, and even more preferably has 1 to 4 CH₃ partial structures.

The alkyl group as R₃ that has one or more CH₃ partial structures is preferably a branched alkyl group having 3 to 20 carbon atoms. Specific examples of the preferred alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. The alkyl group is more preferably an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

Specific examples of the alkyl group as R₃ that has two or more CH₃ partial structures include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and the like. The alkyl group is more preferably an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, or a 2,6-dimethylheptyl group.

n represents an integer of 1 to 5. n preferably represents an integer of 1 to 3, and more preferably represents 1 or 2.

Specific examples preferred as the repeating unit represented by Formula (III) will be shown below, but the present invention is not limited thereto.

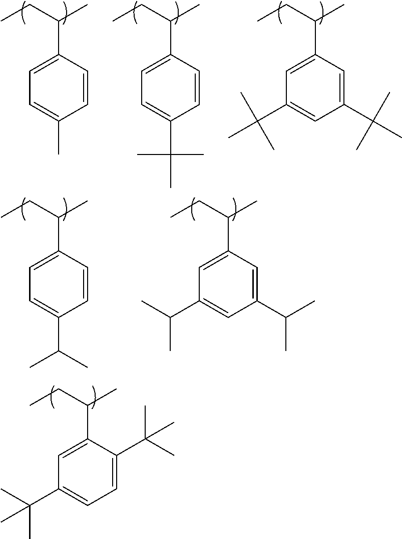

The repeating unit represented by Formula (III) is preferably a (non-acid-decomposable) repeating unit stable against an acid. Specifically, the repeating unit is preferably a repeating unit which does not have a group generating a polar group by being decomposed by the action of an acid.

In a case where the resin (D) contains a CH₃ partial structure in a side chain portion and particularly does not have a fluorine atom and a silicon atom, a content of at least 1 kind of repeating unit (x) between the repeating unit represented by Formula (II) and the repeating unit represented by Formula (III) is, with respect to all of the repeating units of the resin (D), preferably equal to or greater than 90 mol %, and more preferably equal to or greater than 95 mol %. The content is generally equal to or less than 100 mol % with respect to all of the repeating units of the resin (D).

In a case where the resin (D) contains at least 1 kind of repeating unit (x) between the repeating unit represented by Formula (II) and the repeating unit represented by Formula (III) in an amount of equal to or greater than 90 mol % with respect to all of the repeating units of the resin (D), the surface free energy of the resin (D) is increased. As a result, the resin (D) is not easily localized within the surface of a resist film, and it is possible to reliably improve a static/dynamic contact angle of the resist film with respect to water and to improve the conformity to the immersion liquid.

In both of (i) a case where the hydrophobic resin (D) contains a fluorine atom and/or a silicon atom and (ii) a case where the hydrophilic resin (D) contains a CH₃ partial structure in a side chain portion, the resin (D) may have at least one group selected from the group consisting of the following (x) to (z).

(x) an acid group

(y) a group having a lactone structure, an acid anhydride group, or an acid imide group

(z) a group decomposed by the action of an acid

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of the preferred acid group include a fluorinated alcohol group (preferably a hexafluoroisopropanol group), a sulfonimide group, and a bis(alkylcarbonyl)methylene group.

Examples of the repeating unit having the acid group (x) include a repeating unit in which an acid group is directly bonded to a main chain of a resin, such as a repeating unit composed of an acrylic acid or a methacrylic acid, a repeating unit in which an acid group is bonded to a main chain of a resin through a linking group, and the like. Furthermore, by using a polymerization initiator or a chain transfer agent having an acid group, the repeating unit can be introduced into a terminal of a polymer chain. All of the aforementioned repeating units are preferable. The repeating unit having the acid group (x) may have at least either a fluorine atom or a silicon atom.

A content of the repeating unit having the acid group (x) is, with respect to all of the repeating units in the hydrophobic resin (D), preferably 1 to 50 mol %, more preferably 3 to 35 mol %, and even more preferably 5 to 20 mol %.

Specific examples of the repeating unit having the acid group (x) will be shown below, but the present invention is not limited thereto. In the formulae, Rx represents a hydrogen atom, CH₃, CF₃, or CH₂OH.

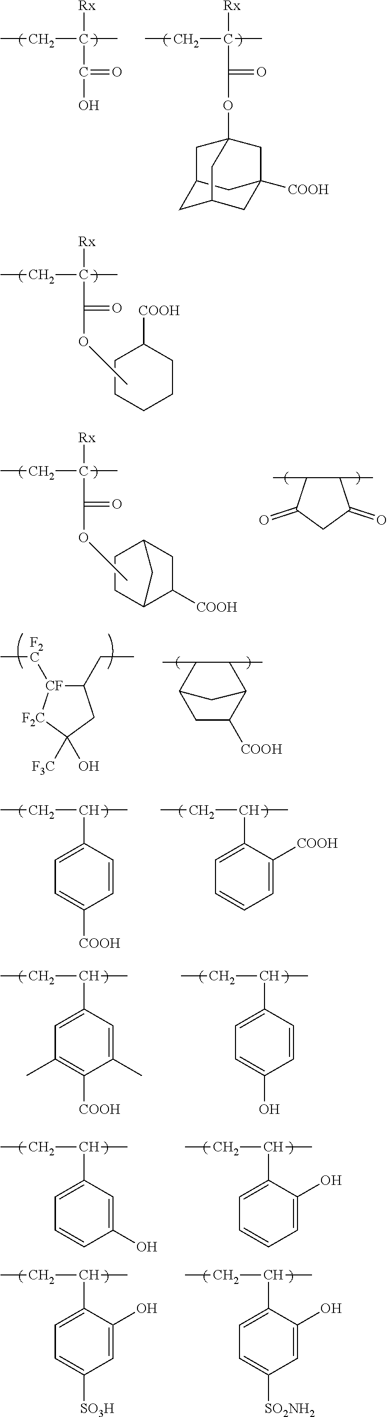

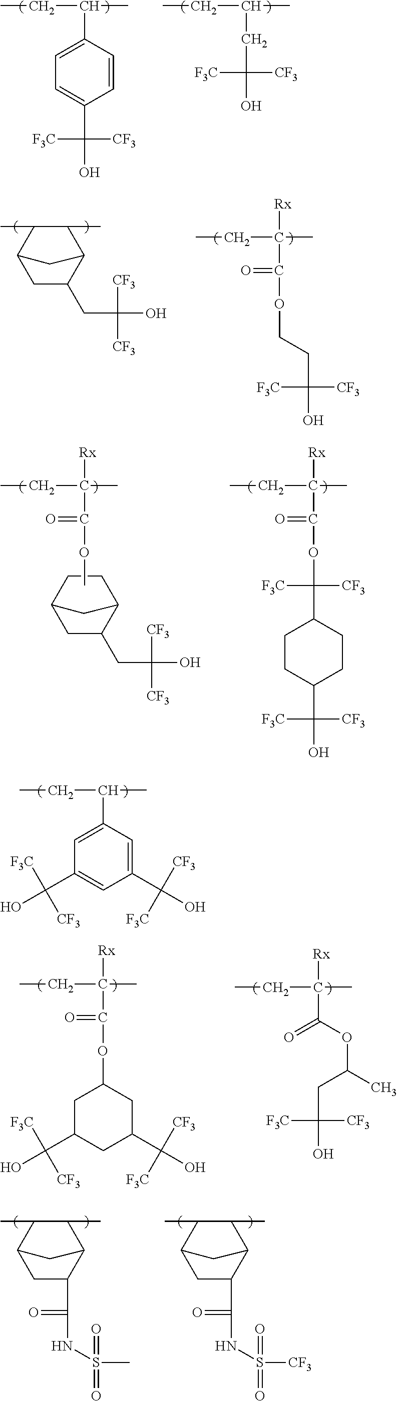

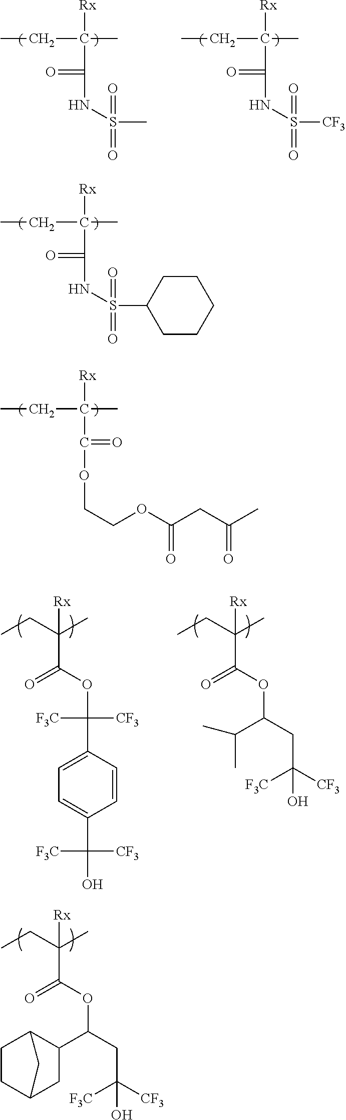

As the group having a lactone structure, the acid anhydride group, or the imide group (y), a group having a lactone structure is particularly preferable.

The repeating unit having these groups is, for example, a repeating unit in which these groups are directly bonded to a main chain of a resin, such as a repeating unit composed of an acrylic acid ester or a methacrylic acid ester. Alternatively, the repeating unit may be a repeating unit in which these groups are bonded to a main chain of a resin through a linking group. Otherwise, the repeating unit may be introduced into a terminal of a resin at the time of polymerization by using a polymerization initiator or a chain transfer agent having these groups.

Examples of the repeating unit having the group having a lactone structure are the same as the examples of the repeating unit having a lactone structure described above for the resin (A).

A content of the repeating unit having the group having a lactone structure, the acid anhydride group, and the imide group is, based on all of the repeating units in the hydrophobic resin (D), preferably 1 to 100 mol %, more preferably 3 to 98 mol %, and even more preferably 5 to 95 mol %.

Examples of the repeating unit, which has the group (z) decomposed by the action of an acid, in the hydrophobic resin (D) are the same as the examples of the repeating unit having an acid-decomposable group exemplified above for the resin (A). The repeating unit which has the group (z) decomposed by the action of an acid may have at least either a fluorine atom or a silicon atom. A content of the repeating unit, which has the group (z) decomposed by the action of an acid, in the hydrophobic resin (D) is, with respect to all of the repeating units in the resin (D), is preferably 1 to 80 mol %, more preferably 10 to 80 mol %, and even more preferably 20 to 60 mol %.

The hydrophobic resin (D) may further have a repeating unit represented by the following Formula (III).

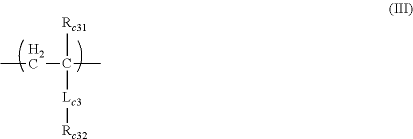

In Formula (III), R₆₁ represents a hydrogen atom, an alkyl group (may be substituted with a fluorine atom or the like), a cyano group, or a —CH₂—O-Rac₂ group. In the formula, Rac₂ represents a hydrogen atom, an alkyl group, or an acyl group. R₆₁ is preferably a hydrogen atom, a methyl group, a hydroxymethyl group, or a trifluoromethyl group, and particularly preferably a hydrogen atom or a methyl group.

R_{c32} represents an alkyl group, a cycloalkyl group, an alkenyl group, a cycloalkenyl group, or an aryl group. These groups may be substituted with a group containing a fluorine atom or a silicon atom.

L_{c3} represents a single bond or a divalent linking group.

The alkyl group as R_{c32} in Formula (III) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphtyl group. These may have a substituent.

R_{c32} is preferably an unsubstituted alkyl group or an alkyl group substituted with a fluorine atom.

The divalent linking group as L_{c3} is preferably an alkylene group (preferably having 1 to 5 carbon atoms), an ether bond, a phenylene group, or an ester bond (group represented by —COO—).

A content of the repeating unit represented by Formula (III) is, based on all of the repeating units in the hydrophobic resin, preferably 1 to 100 mol %, more preferably 10 to 90 mol %, and even more preferably 30 to 70 mol %.

It is also preferable that the hydrophobic resin (D) has a repeating unit represented by the following Formula (CII-AB).

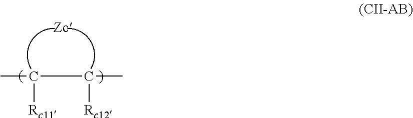

In Formula (CII-AB), R_{c11}′ and R_{c12}′ each independently represent a hydrogen atom, a cyano group, a halogen atom, or an alkyl group.

Zc′ represents an atomic group which contains two carbon atoms (C—C) bonded and is for forming an alicyclic structure.

A content of the repeating unit represented by Formula (CII-AB) is, based on all of the repeating units in the hydrophobic resin, preferably 1 to 100 mol %, more preferably 10 to 90 mol %, and even more preferably 30 to 70 mol %.

Specific examples of the repeating units represented by Formulae (III) and (CII-AB) will be shown below, but the present invention is not limited thereto. In the formulae, Ra represents H, CH₃, CH₂OH, CF₃, or CN.

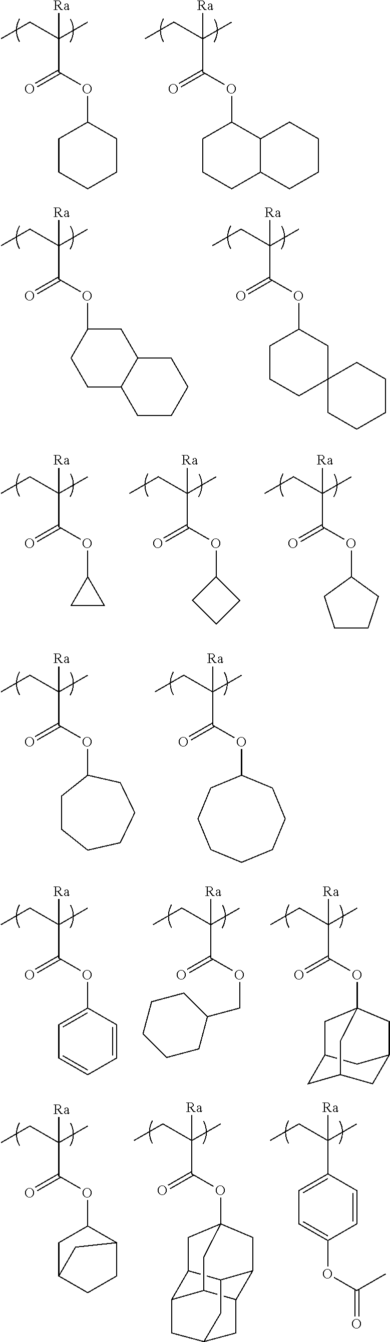

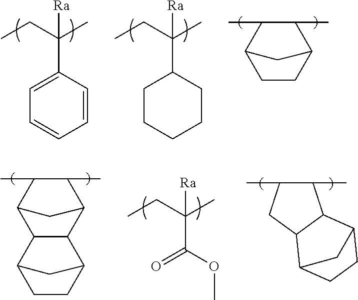

In a case where the hydrophobic resin (D) has a fluorine atom, a content of the fluorine atom is, with respect to a weight-average molecular weight of the hydrophobic resin (D), preferably 5% to 80% by mass, and more preferably 10% to 80% by mass. A content of the repeating unit containing a fluorine atom is preferably 10 to 100 mol %, and more preferably 30 to 100 mol % with respect to all of the repeating units contained in the hydrophobic resin (D).

In a case where the hydrophobic resin (D) has a silicon atom, a content of the silicon atom is, with respect to a weight-average molecular weight of the hydrophobic resin (D), preferably 2% to 50% by mass, and more preferably 2% to 30% by mass. A content of the repeating unit containing a silicon atom is preferably 10 to 100 mol %, and more preferably 20 to 100 mol % with respect to all of the repeating units contained in the hydrophobic resin (D).

Particularly, in a case where the resin (D) contains a CH₃ partial structure on a side chain portion, it is preferable that the resin (D) substantially does not contain a fluorine atom and a silicon atom. In this case, specifically, a content of the repeating unit having a fluorine atom or a silicon atom is, with respect to all of the repeating units in the resin (D), preferably equal to or less than 5 mol %, more preferably equal to or less than 3 mol %, and even more preferably equal to or less than 1 mol %. Ideally, the content of the aforementioned repeating unit is 0 mol %, that is, the resin (D) does not contain a fluorine atom and a silicon atom. Furthermore, it is preferable that the resin (D) is substantially constituted only with a repeating unit which is constituted only with an atom selected from a carbon atom, an oxygen atom, a hydrogen atom, a nitrogen atom, and a sulfur atom. More specifically, a content of the repeating unit which is constituted only with an atom selected from a carbon atom, an oxygen atom, a hydrogen atom, a nitrogen atom, and a sulfur atom is preferably, with respect to all of the repeating units of the resin (D), preferably equal to or greater than 95 mol %, more preferably equal to or greater than 97 mol %, even more preferably equal to or greater than 99 mol %, and ideally 100 mol %.

A weight-average molecular weight of the hydrophobic resin (D) expressed in terms of standard polystyrene is preferably 1,000 to 100,000, more preferably 1,000 to 50,000, and even more preferably 2,000 to 15,000.

One kind of the hydrophobic resin (D) may be used singly, or plural kinds thereof may be used in combination.

A content of the hydrophobic resin (D) in the composition is, with respect to the total solid content in the first resist composition, preferably 0.01% to 35% by mass, more preferably 0.05% to 30% by mass, and even more preferably 0.1% to 25% by mass.

Although it goes without saying that the hydrophobic resin (D) hardly contains impurities such as a metal just like the resin (A), a content of a residual monomer or an oligomer component in the resin (D) is preferably 0.01% to 5% by mass, more preferably 0.01% to 3% by mass, and even more preferably 0.05% to 1% by mass. In a case where the content of the residual monomer or the oligomer component is within the above range, a first resist composition is obtained in which impurities, sensitivity, and the like do not change over time. In view of the resolution, resist shape, side wall of the resist pattern, roughness, and the like, a molecular weight distribution (Mw/Mn, referred to as a dispersity as well) of the resin (D) is preferably within a range of 1 to 5, more preferably 1 to 3, and even more preferably within a range of 1 to 2.

Various commercially available products can be used as the hydrophobic resin (D). Furthermore, the hydrophobic resin (D) can be synthesized according to a common method (for example, radical polymerization). Examples of the general synthesis method include a batch polymerization method in which polymerization is performed by dissolving a monomer species and an initiator in a solvent and heating the solution, a dropping polymerization method in which a solution containing a monomer species and an initiator is added dropwise to a heated solvent for 1 to 10 hours, and the like. Among these, a dropping polymerization method is preferable.

The reaction solvent, the polymerization initiator, the reaction conditions (temperature, concentration, and the like), and the purification method used after the reaction are the same as those described above for the resin (A). In synthesizing the hydrophobic resin (D), the concentration or reaction is preferably 30% to 50% by mass.

Specific examples of the hydrophobic resin (D) will be shown below. In addition, a molar ratio (corresponding to each repeating unit in order form the left) of a repeating unit in each resin, a weight-average molecular weight, and a dispersity will be shown in the following table.

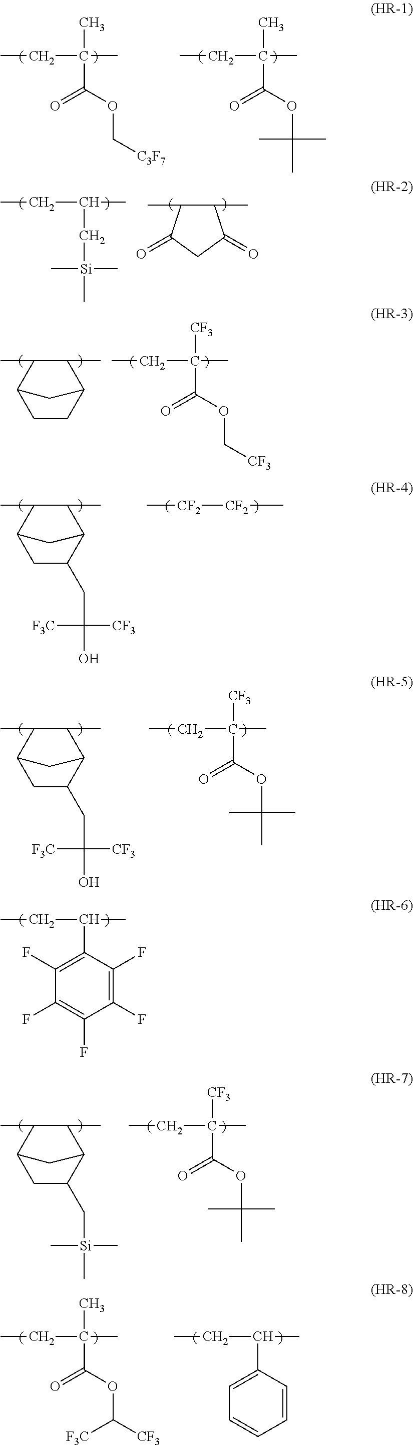

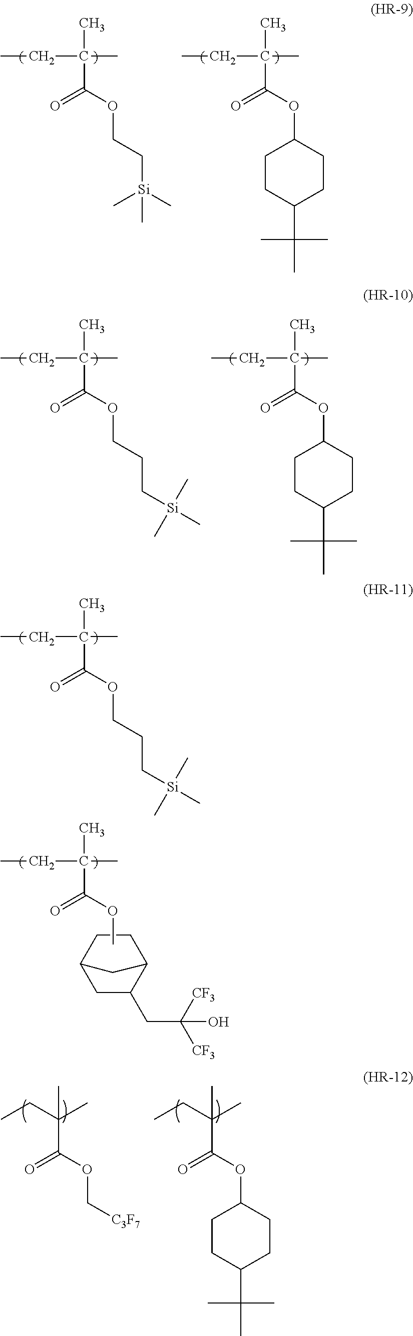

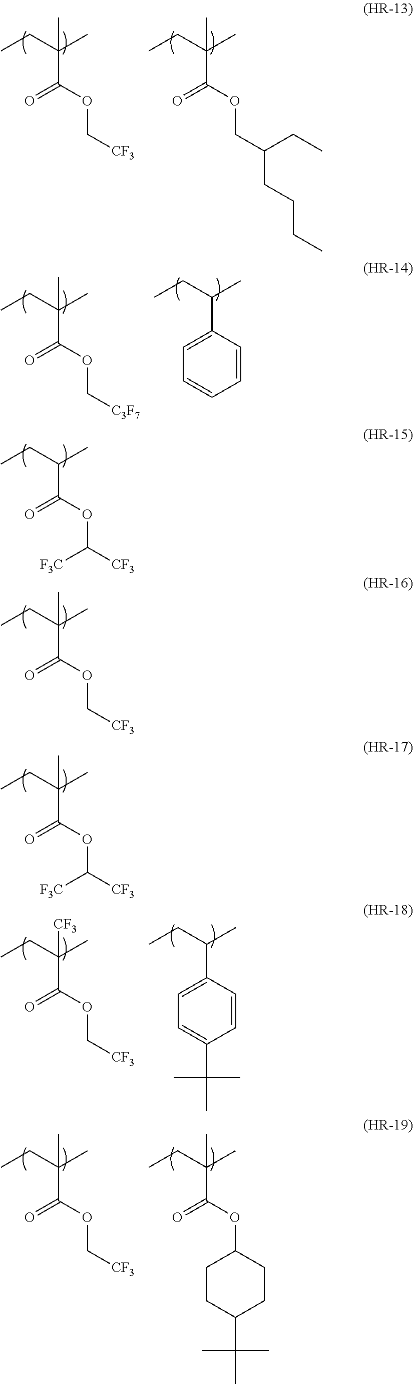

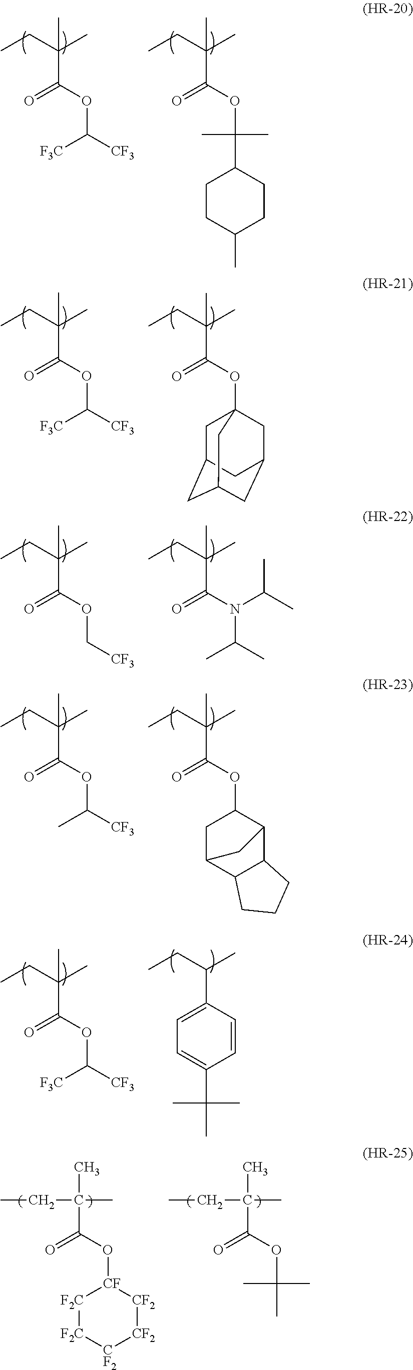

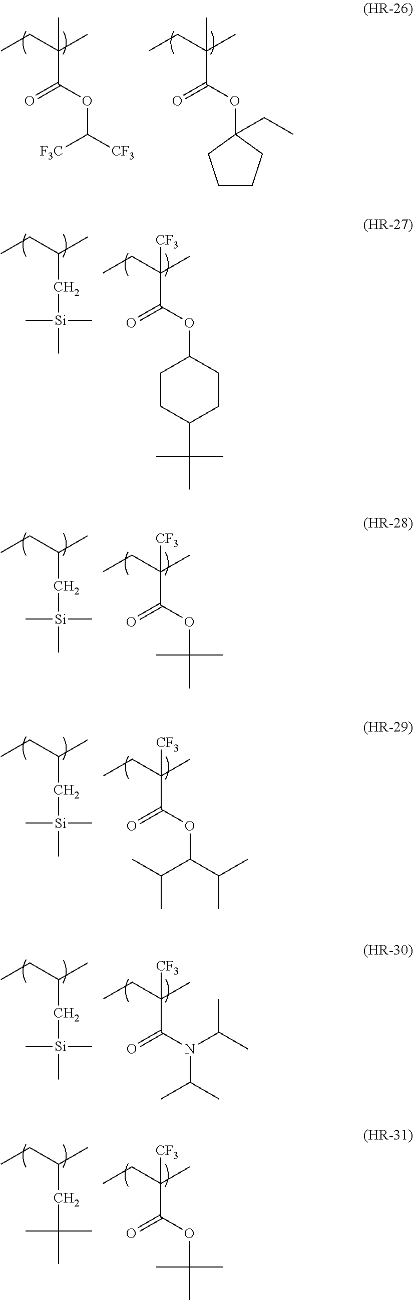

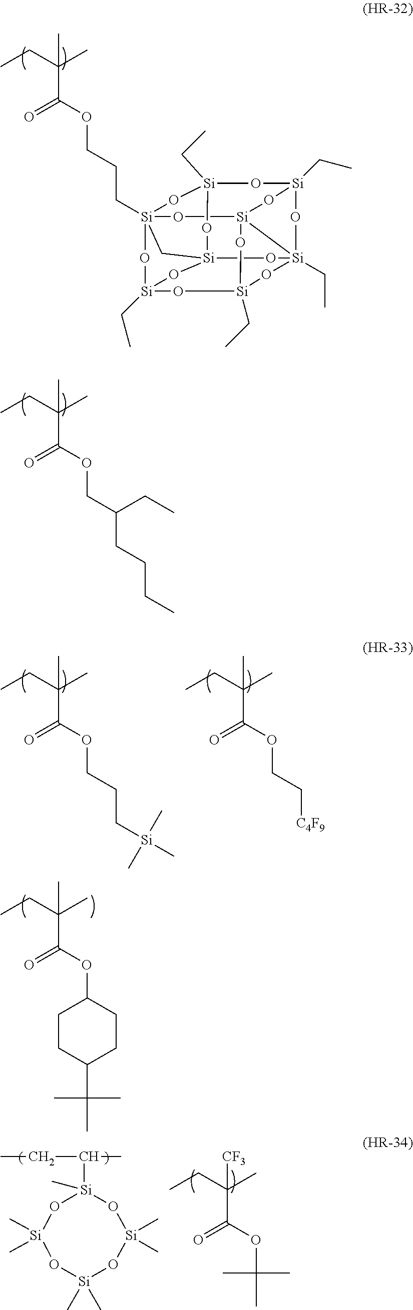

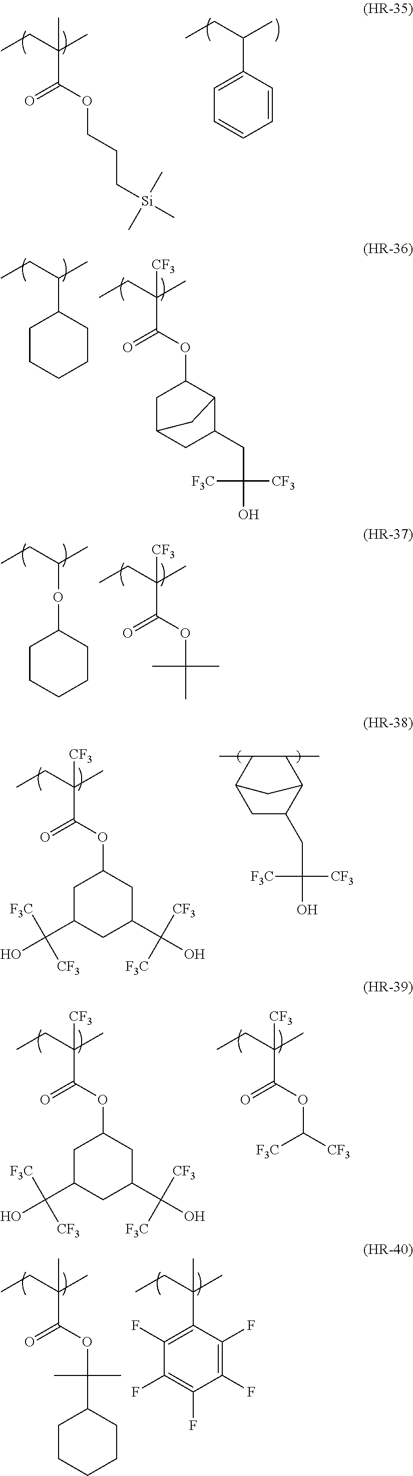

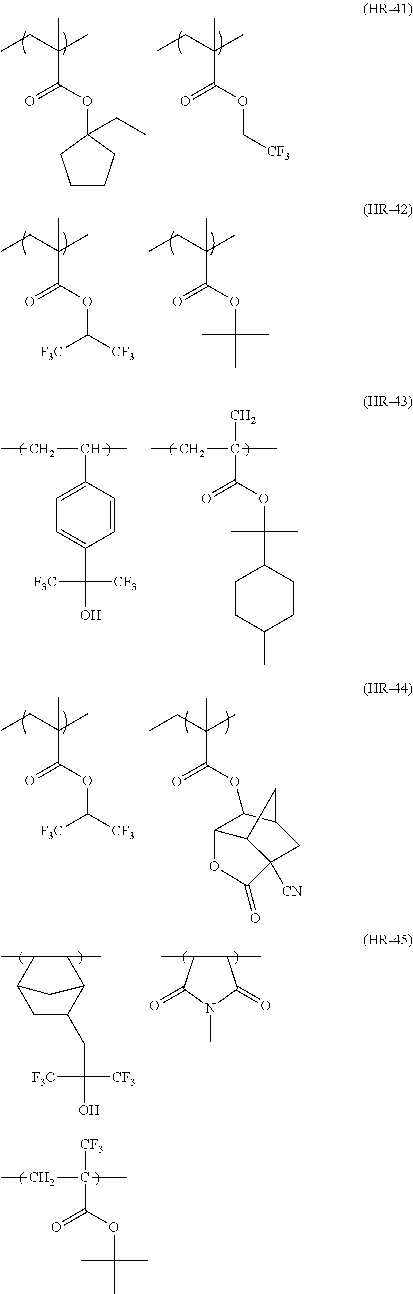

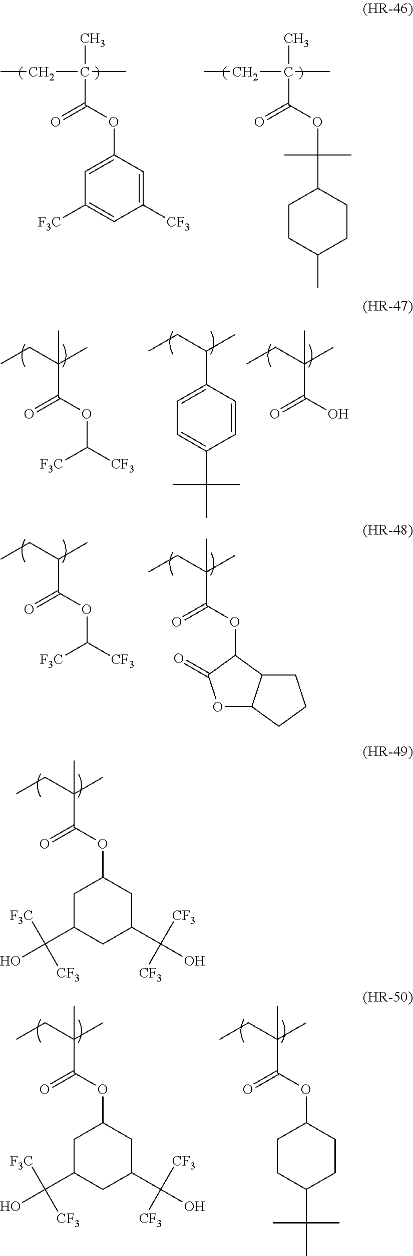

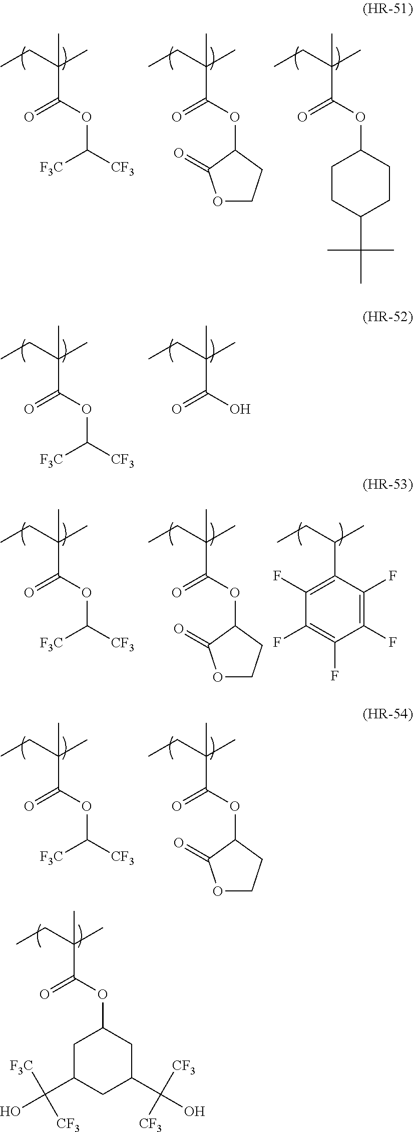

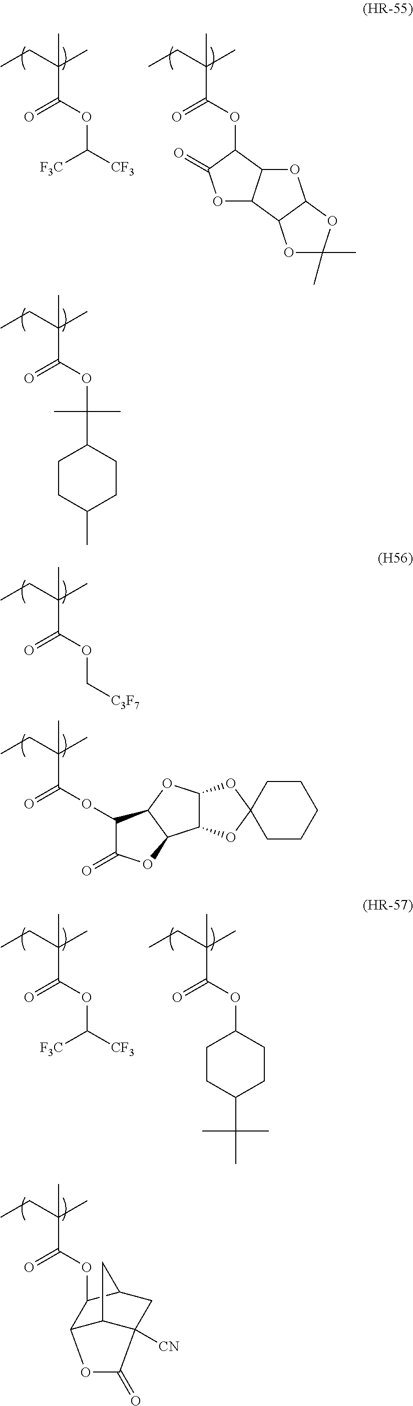

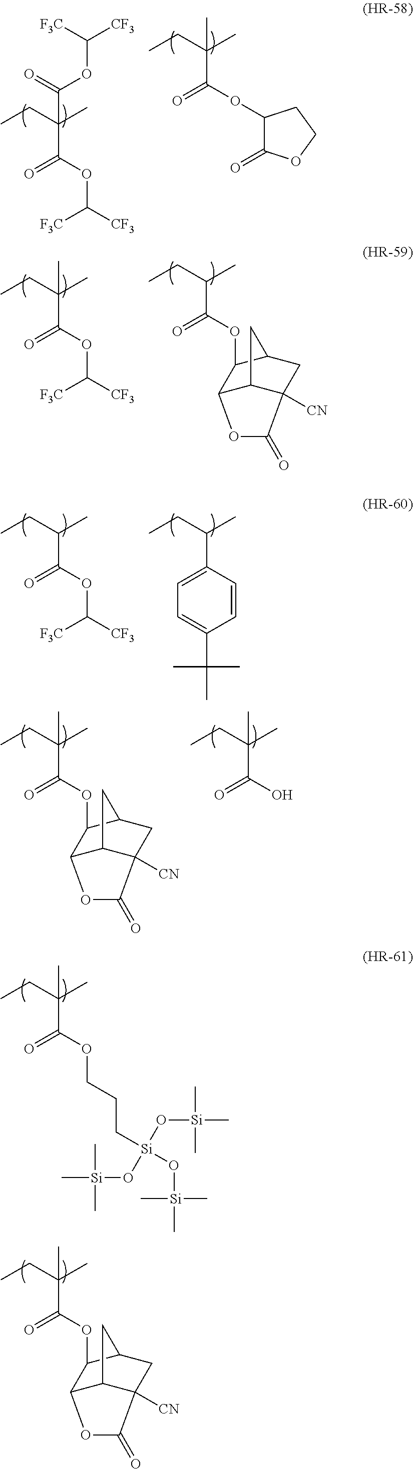

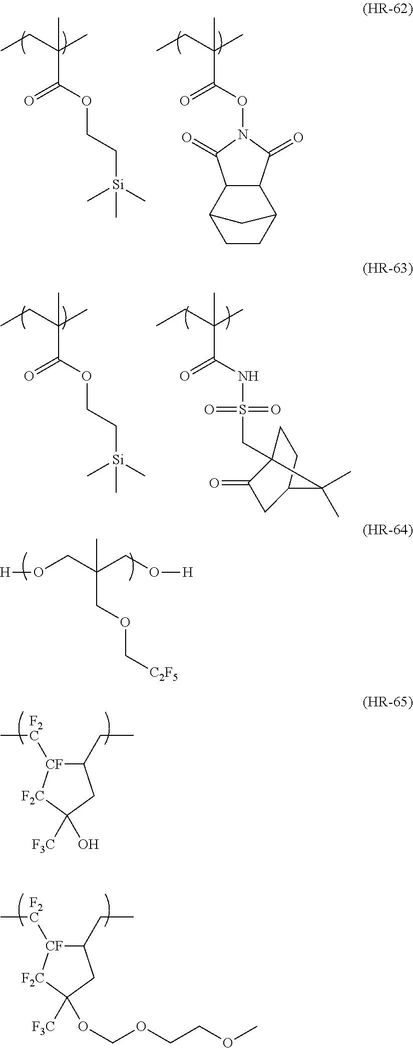

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

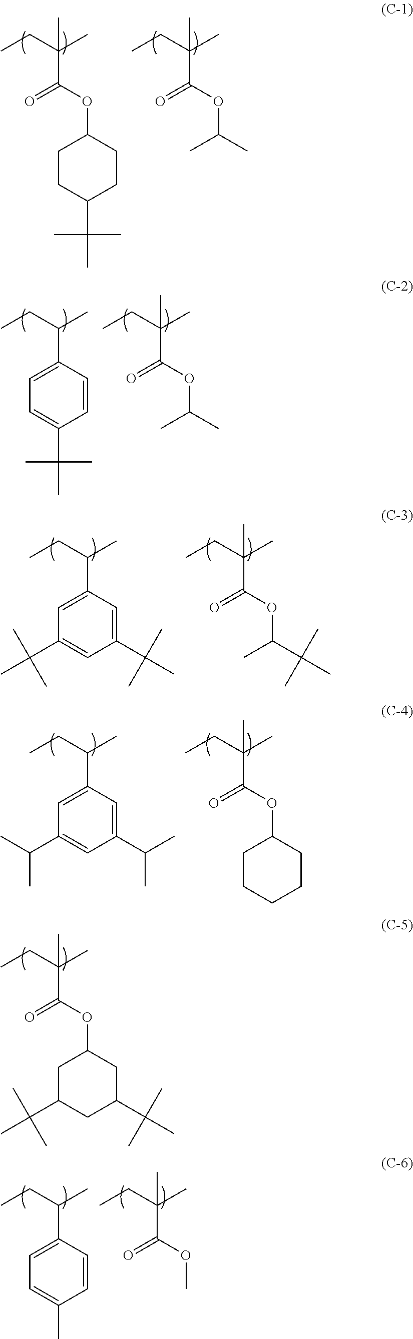

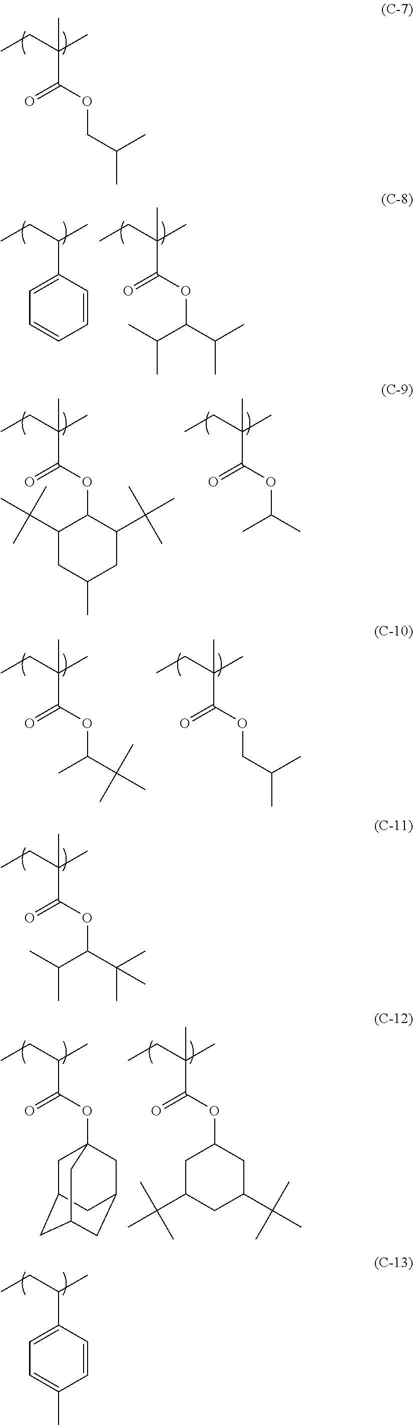

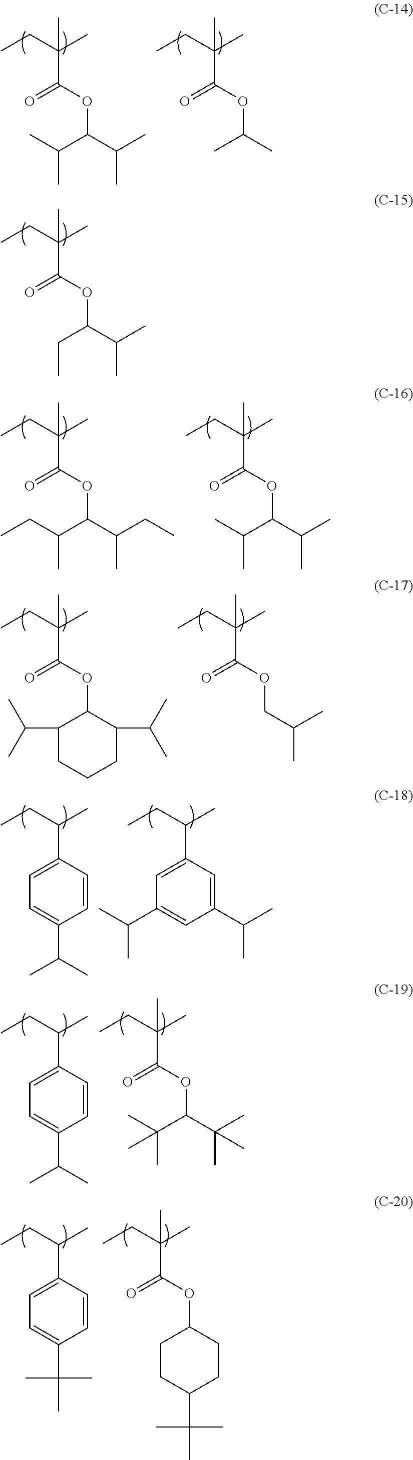

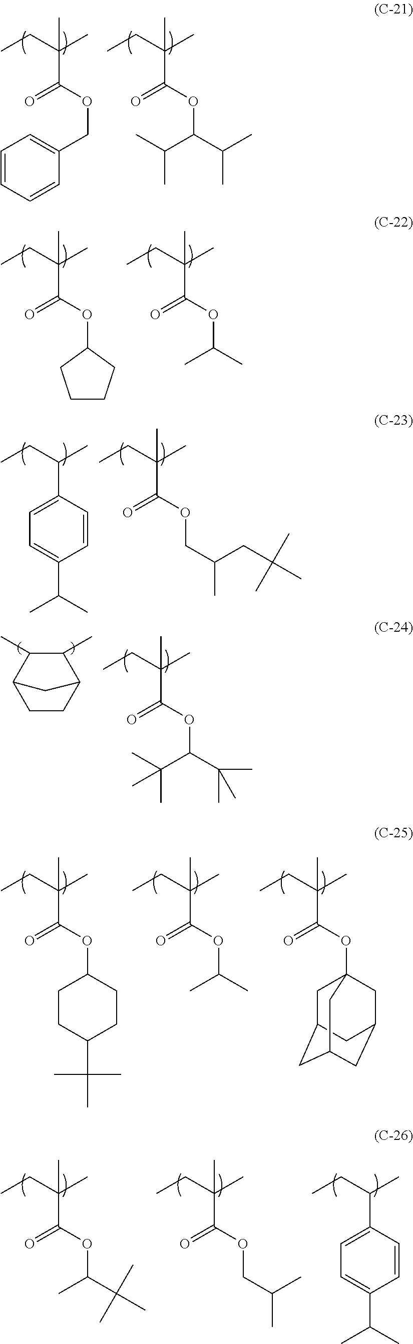

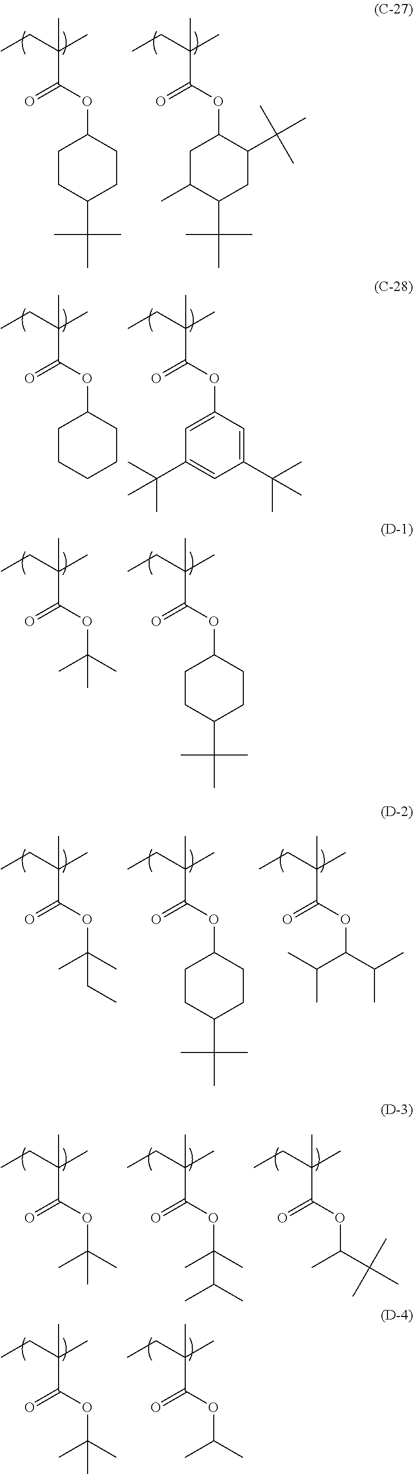

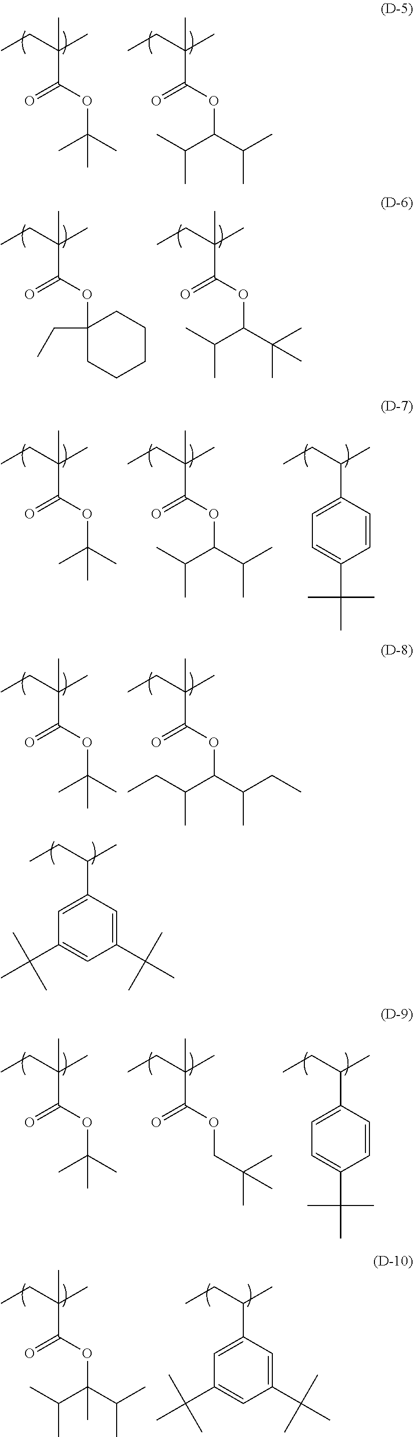

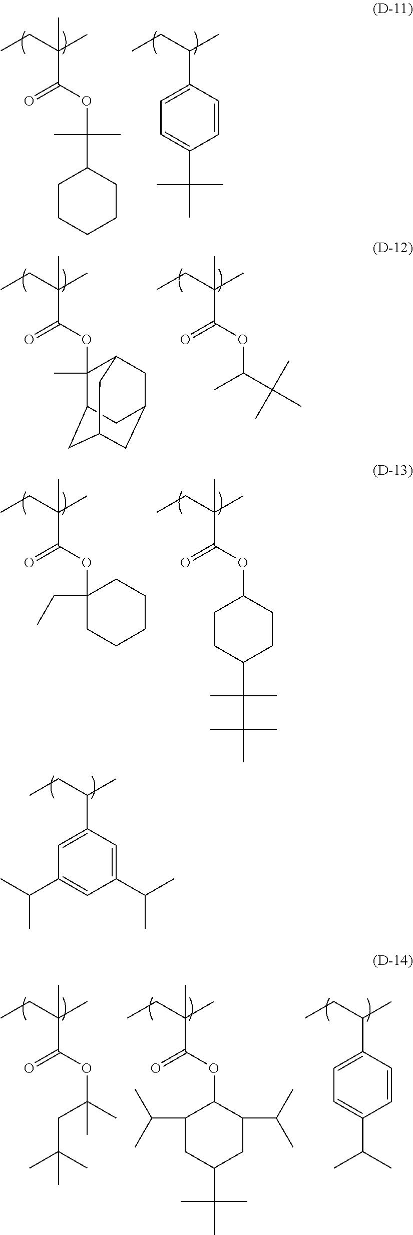

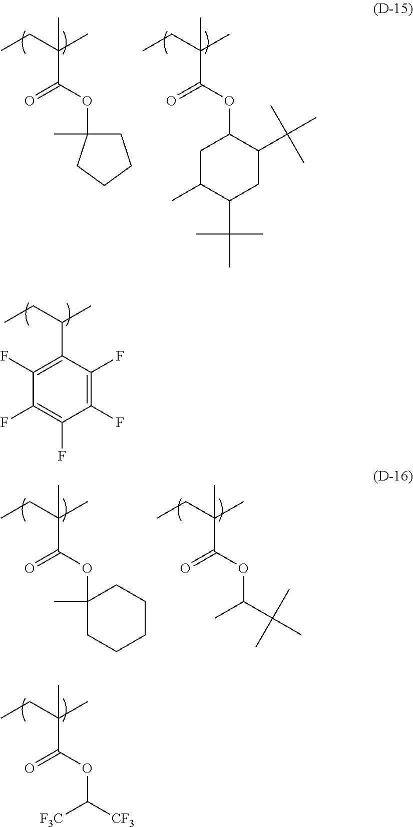

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5-1] Basic Compound or Ammonium Salt Compound (N) Undergoing Decrease in Basicity by being Irradiated with Actinic Rays or Radiation

It is preferable that the first resist composition in the present invention contains a basic compound or an ammonium salt compound (hereinafter, referred to as a “compound (N)” as well) which undergoes a decrease in basicity by being irradiated with actinic rays and radiation.

The compound (N) is preferably a compound (N-1) which has a basic functional group or an ammonium group and a group generating an acidic functional group by being irradiated with actinic rays or radiation. That is, the compound (N) is preferably a basic compound which has a basic functional group and a group generating an acidic functional group by being irradiated with actinic rays or radiation or an ammonium salt compound which has an ammonium group and a group generating an acidic functional group by being irradiated with actinic rays or radiation.

Examples of a compound which is generated by the decomposition of the compound (N) or (N−1) irradiated with actinic rays or radiation and undergoes a decrease in basicity include a compound represented by the following Formula (PA-I), (PA-II), or (PA-III). Particularly, a compound represented by Formula (PA-II) or (PA-III) is preferable, because this compound makes it possible to high-dimensionally establish all of LWR, the dimensional uniformity of the local pattern, and excellent effects involved in DOF.

First, the compound represented by Formula (PA-I) will be described.

Q-A₁-(X)ₙ—B—R (PA-I)

In Formula (PA-I), A₁ represents a single bond or a divalent linking group.

Q represents —SO₃H or —CO₂H. Q corresponds to an acidic functional group generated by the irradiation of actinic rays or radiation.

X represents —SO₂— or —CO—.

n represents 0 or 1.

B represents a single bond, an oxygen atom, or —N(Rx)-.

Rx represents a hydrogen atom or a monovalent organic group.

R represents a monovalent organic group having a basic functional group or a monovalent organic group having an ammonium group.

The divalent linking group as A₁ is preferably a divalent linking group having 2 to 12 carbon atoms, and examples thereof include an alkylene group, a phenylene group, and the like. The divalent linking group is more preferably an alkylene group having at least one fluorine atom, and the alkylene group preferably has 2 to 6 carbon atoms and more preferably has 2 to 4 carbon atoms. The alkylene group may have a linking group such as an oxygen atom or a sulfur atom in the alkylene chain. The alkylene group is particularly preferably an alkylene group in which 30% to 100% of the number of hydrogen atoms are substituted with a fluorine atom. It is more preferable that in the alkylene group, a carbon atom bonded to the Q moiety has a fluorine atom. The alkylene group is even more preferably a perfluoroalkylene group, and still more preferably a perfluoroethylene group, a perfluoropropylene group, or a perfluorobutylene group.

The monovalent organic group as Rx preferably has 4 to 30 carbon atoms, and examples thereof include an alkyl group, a cycloalkyl group, an aryl group, an aralkyl group, an alkenyl group, and the like.

The alkyl group as Rx may have a substituent, and is preferably a linear or branched alkyl group having 1 to 20 carbon atoms. The alkyl group may have an oxygen atom, a sulfur atom, or a nitrogen atom in the alkyl chain.

Examples of the alkyl group having a substituent particularly include a linear or branched alkyl group substituted with a cycloalkyl group (for example, an adamantyl methyl group, an adamantyl ethyl group, a cyclohexyl ethyl group, or a camphor residue).

The cycloalkyl group as Rx may have a substituent, and is preferably a cycloalkyl group having 3 to 20 carbon atoms. The cycloalkyl group may have an oxygen atom in the ring.

The aryl group as Rx may have a substituent, and is preferably an aryl group having 6 to 14 carbon atoms.

The aralkyl group as Rx may have a substituent, and preferred examples thereof include an aralkyl group having 7 to 20 carbon atoms.

The alkenyl group as Rx may have a substituent, and examples thereof include a group having a double bond in any position of the alkyl group exemplified above as Rx.

Examples of preferred partial structure of the basic functional group include structures of crown ether, primary to tertiary amine, and nitrogen-containing heterocyclic rings (pyridine, imidazole, pyrazine, and the like).

Examples of the preferred partial structure of the ammonium group include structures of primary to tertiary ammonium, pyridinium, imidazolinium, pyrazinium, and the like.

As the basic functional group, a nitrogen atom-containing functional group is preferable, and a structure having primary to tertiary amino group or a nitrogen-containing heterocyclic ring structure is more preferable. In these structures, from the viewpoint of improving basicity, it is preferable that all of the atoms adjacent to nitrogen atoms contained in the structures are carbon atoms or hydrogen atoms. Furthermore, from the viewpoint of improving basicity, it is preferable that an electron-withdrawing functional group (carbonyl group, a sulfonyl group, a cyano group, a halogen atom, or the like) is not directly bonded to a nitrogen atom.

The monovalent organic group in the monovalent organic group (group R) having the above structure preferably has 4 to 30 carbon atoms, and examples thereof include an alkyl group, a cycloalkyl group, an aryl group, an aralkyl group, an alkenyl group, and the like. Each of these groups may have a substituent.

Each of the alkyl group, the cycloalkyl group, the aryl group, the aralkyl group, and the alkyl group in the alkenyl group, the cycloalkyl group, the aryl group, the aralkyl group, and the alkenyl group containing the basic functional group or the ammonium group in R is the same as each of the alkyl group, the cycloalkyl group, the aryl group, the aralkyl group, and the alkenyl group exemplified above as Rx.

Examples of the substituent that each of the above groups may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 20 carbon atoms), and the like. The cyclic structure in the aryl group, the cycloalkyl group, and the like can further have, for example, an alkyl group (preferably having 1 to 20 carbon atoms) as a substituent. The aminoacyl group can further have, for example, 1 or 2 alkyl groups (preferably having 1 to 20 carbon atoms) as a substituent.

When B represents —N(Rx)—, R and Rx may form a ring by being bonded to each other. In a case where R and Rx form a ring structure, stability is enhanced, and the storage stability of the composition using the compound is improved. The number of carbon atoms forming the ring is preferably 4 to 20. The ring may be monocyclic or polycyclic and may contain an oxygen atom, a sulfur atom, or a nitrogen atom in the ring.

Examples of the monocyclic structure include a 4-to 8-membered ring containing a nitrogen atom and the like. Examples of the polycyclic structure include a structure formed of a combination of 2 or 3 or more monocyclic structures. The monocyclic structure and the polycyclic structure may have a substituent, and the substituent is preferably a halogen atom, a hydroxyl group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms), and the like. The cyclic structure in the aryl group, the cycloalkyl group, and the like can further have, for example, an alkyl group (preferably having 1 to 15 carbon atoms) as a substituent. The aminoacyl group can further have, for example, 1 or 2 alkyl groups (preferably having 1 to 15 carbon atoms) as a substituent.

Among the compounds represented by Formula (PA-I), a compound in which the Q moiety is a sulfonic acid can be synthesized using a general sulfonamidation reaction. For example, such a compound can be obtained by a method of forming a sulfonamide bond by selectively reacting one sulfonyl halide portion of a bissulfonyl halide compound with an amine compound and then hydrolyzing the other sulfonyl halide portion or a method of reacting a cyclic sulfonic anhydride with an amine compound so as to open the ring.

Next, the compound represented by Formula (PA-II) will be described.

Q₁-X₁—NH—X₂-Q₂ (PA-II)

In Formula (PA-II), Q₁ and Q₂ each independently represent a monovalent organic group. Here, either Q₁ or Q₂ has a basic functional group. Q₁ and Q₂ may form a ring by being bonded to each other, and the formed ring may have a basic functional group.

X₁ and X₂ each independently represent —CO— or —SO₂—.

—NH— corresponds to an acidic functional group generated by the irradiation of actinic rays or radiation.

The monovalent organic group as Q₁ and Q₂ in Formula (PA-II) preferably has 1 to 40 carbon atoms, and examples thereof include an alkyl group, a cycloalkyl group, an aryl group, an aralkyl group, an alkenyl group, and the like.

The alkyl group as Q₁ and Q₂ may have a substituent, and is preferably a linear or branched alkyl group having 1 to 30 carbon atoms. The alkyl group may have an oxygen atom, a sulfur atom, or a nitrogen atom in the alkyl chain.

The cycloalkyl group as Q₁ and Q₂ may have a substituent, and is preferably a cycloalkyl group having 3 to 20 carbon atoms. The cycloalkyl group may have an oxygen atom or a nitrogen atom in the ring.

The aryl group as Q₁ and Q₂ may have a substituent, and is preferably an aryl group having 6 to 14 carbon atoms.

The aralkyl group as Q₁ and Q₂ may have a substituent, and examples thereof include an aralkyl group having 7 to 20 carbon atoms.

The alkenyl group as Q₁ and Q₂ may have a substituent, and examples thereof include a group having a double bond in any position of the aforementioned alkyl group.

Examples of the substituent that each of the above groups may have include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 10 carbon atoms), and the like. The cyclic structure in the aryl group, the cycloalkyl group, or the like can have, for example, an alkyl group (preferably having 1 to 10 carbon atoms) as a substituent. The aminoacyl group can further have, for example, an alkyl group (preferably having 1 to 10 carbon atoms) as a substituent. Examples of the alkyl group having a substituent include a perfluoroalkyl group such as a perfluoromethyl group, a perfluoroethyl group, a perfluoropropyl group, or a perfluorobutyl group.

Examples of the preferred partial structure of the basic functional group that either Q₁ or Q₂ has include the same partial structure as described above as the basic functional group that R in Formula (PA-I) has.

Examples of the structure, in which Q₁ and Q₂ form a ring by being bonded to each other and the formed ring has a basic functional group, include the structure in which the organic groups as Q₁ and Q₂ are further bonded to each other through an alkylene group, an oxy group, an imino group, or the like.

It is preferable that, in Formula (PA-II), at least either X₁ or X₂ is —SO₂—.

Next, the compound represented by Formula (PA-III) will be described.

Q₁-X₁—NH—X₂-A₂-(X₃)ₘ—B-Q₃ (PA-III)

In Formula (PA-III), Q₁ and Q₃ each independently represent a monovalent organic group. Here, either Q₁ or Q₃ has a basic functional group. Q₁ and Q₃ may form a ring by being bonded to each other, and the formed ring may have a basic functional group.

X₁, X₂, and X₃ each independently represent —CO— or —SO₂—.

A₂ represents a divalent linking group.

B represents a single bond, an oxygen atom, or —N(Qx)-.

Qx represents a hydrogen atom or a monovalent organic group.

When B is —N(Qx)-, Q₃ and Qx may form a ring by being bonded to each other.

m represents 0 or 1.

—NH— corresponds to an acidic functional group generated by the irradiation of actinic rays or radiation.

Q₁ has the same definition as Q₁ in Formula (PA-II).

Examples of the organic group as Q₃ are the same as the examples of the organic group represented by Q₁ and Q₂ in Formula (PA-II).

Examples of the structure, in which Q₁ and Q₃ form a ring by being bonded to each other and the formed ring has a basic functional group, include a structure in which the organic groups as Q₁ and Q₃ are further bonded to each other through an alkylene group, an oxy group, an imino group, or the like.

The divalent linking group as A₂ is preferably a fluorine atom-containing divalent linking group having 1 to 8 carbon atoms, and examples thereof include a fluorine atom-containing alkylene group having 1 to 8 carbon atoms, a fluorine atom-containing phenylene group, and the like. The divalent linking group is more preferably a fluorine atom-containing alkylene group, and the alkylene group preferably has 2 to 6 carbon atoms and more preferably has 2 to 4 carbon atoms. The alkylene group may have a linking group such as an oxygen atom or a sulfur atom in the alkylene chain. The alkylene group is preferably an alkylene group in which 30% to 100% of the number of hydrogen atoms are substituted with a fluorine atom, more preferably a perfluoroalkylene group, and particularly preferably a perfluoroalkylene group having 2 to 4 carbon atoms.

The monovalent organic group as Qx is preferably an organic group having 4 to 30 carbon atoms, and examples thereof include an alkyl group, a cycloalkyl group, an aryl group, an aralkyl group, an alkenyl group, and the like. Examples of the alkyl group, the cycloalkyl group, the aryl group, the aralkyl group, and the alkenyl group are the same as the examples of those represented by Rx in Formula (PA-I).

It is preferable that, in Formula (PA-III), X₁, X₂, and X₃ each represent —SO₂—.

The compound (N) is preferably a sulfonium salt compound of the compound represented by Formula (PA-I), (PA-II), or (PA-III) or an iodonium salt compound of the compound represented by (PA-I), (PA-II), or (PA-III), and more preferably a compound represented by the following Formula (PA1) or (PA2).

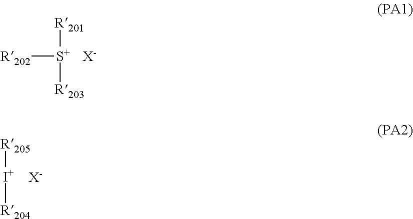

In Formula (PA1), R′₂₀₁, R′₂₀₂, and R′₂₀₃ each independently represent an organic group and are specifically the same as R₂₀₁, R₂₀₂, and R₂₀₃ in Formula ZI in the component (B) described above.

X⁻ represents a sulfonate anion or a carbonate anion formed by the elimination of a hydrogen atom of a —SO₃H moiety or a —COOH moiety of the compound represented by Formula (PA-I), or an anion formed by the elimination of a hydrogen atom from a —NH— moiety of the compound represented by Formula (PA-II) or (PA-III).

In Formula (PA2), R′₂₀₄ and R′₂₀₅ each independently represent an aryl group, an alkyl group, or a cycloalkyl group, and are specifically the same as R₂₀₄ and R₂₀₅ of Formula ZII in the component (B) described above.

X⁻ represents a sulfonate anion or a carbonate anion formed by the elimination of a hydrogen atom of a —SO₃H moiety or a —COOH moiety of the compound represented by Formula (PA-I), or an anion formed by the elimination of a hydrogen atom from a —NH— moiety of the compound represented by Formula (PA-II) or (PA-III).

By being decomposed by being irradiated with actinic rays or radiation, the compound (N) generates a compound represented by, for example, Formula (PA-I), (PA-II), or (PA-III).

The compound represented by Formula (PA-I) is a compound which has a sulfonic acid group or a carboxylic acid group together with a basic functional group or an ammonium group. Therefore, the basicity of the compound represented by Formula (PA-I) becomes lower than the basicity of the compound (N), or the compound represented by Formula (PA-I) loses basicity or is changed to an acidic compound from a basic compound.

The compound represented by Formula (PA-II) or (PA-III) is a compound which has a basic functional group and an organic sulfonylimino group or an organic carbonylimino group. Therefore, the basicity of the compound represented by Formula (PA-II) or (PA-III) becomes lower than the basicity of the compound (N), or the compound represented by Formula (PA-II) or (PA-III) loses basicity or is changed to an acidic compound from a basic compound.

In the present invention, to undergo a decrease in basicity by the irradiation of actinic rays or radiation means that the proton (acid generated by the irradiation of actinic rays or radiation) acceptability of the compound (N) decreases by the irradiation of actinic rays or radiation. The decrease in acceptability means that, when an equilibrium reaction occurs in which a noncovalent bond complex as a proton adduct is generated from a compound having a basic functional group and a proton, or when an equilibrium reaction occurs in which a countercation of a compound having an ammonium group is exchanged with a proton, an equilibrium constant in the chemical equilibrium decreases.

In a case where a resist film contains the compound (N) which undergoes a decrease in basicity by being irradiated with actinic rays or radiation, the acceptability of the compound (N) is sufficiently exhibited in an unexposed portion, the occurrence of an unintended reaction between an acid diffused from an exposed portion or the like and the resin (A) can be inhibited, and the acceptability of the compound (N) decreases in an exposed portion. Presumably, for this reason, an intended reaction may more reliably occur between an acid and the resin (A), and due to the contribution of this mechanism of action, a pattern may be obtained which is excellent in the line width roughness (LWR), dimensional uniformity of a local pattern, depth of focus (DOF), and pattern shape.

The basicity can be confirmed by measuring pH, or a value of basicity can be calculated using commercially available software.

Specific examples of the compound (N) generating the compound represented by Formula (PA-I) by being irradiated with actinic rays or radiation will be shown below, but the present invention is not limited thereto.

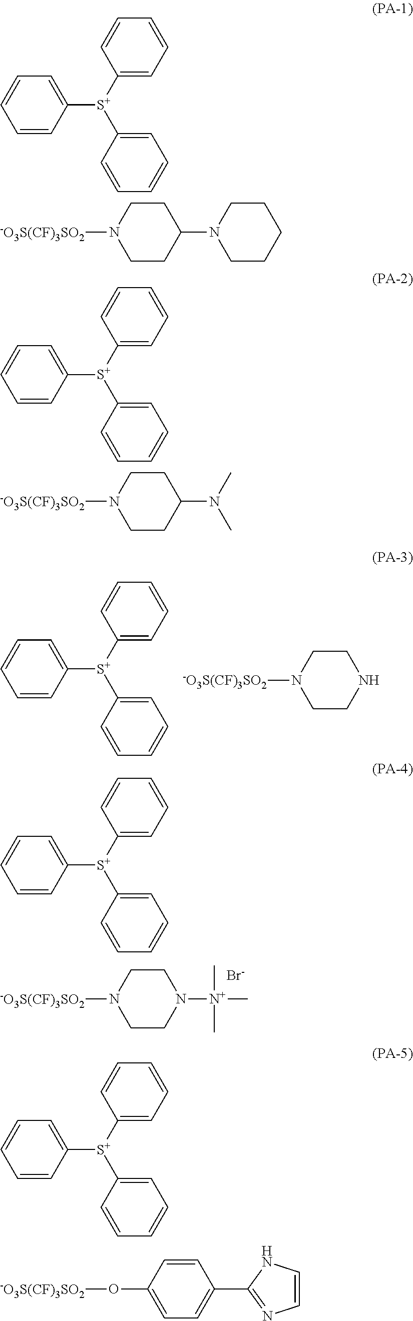

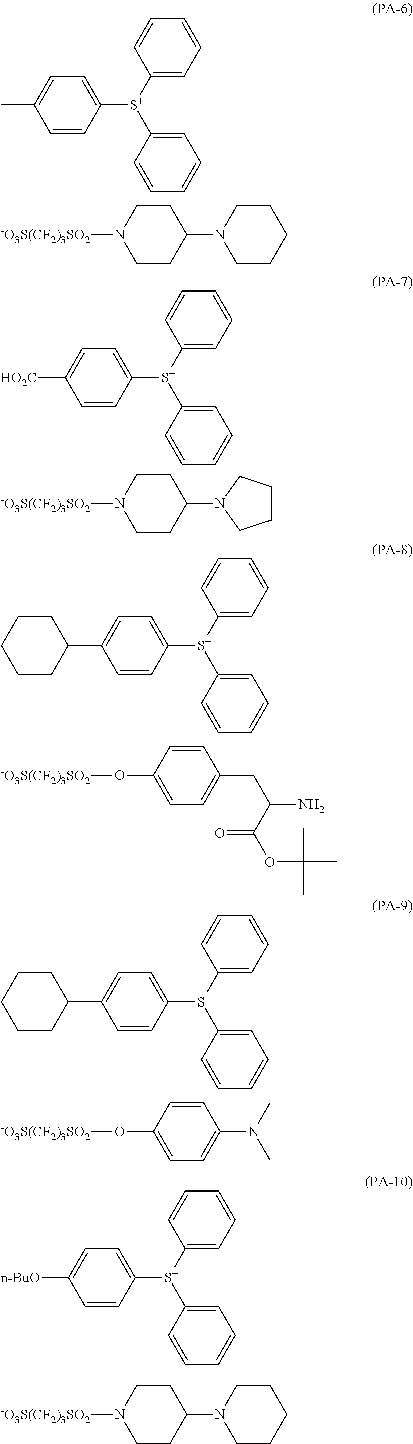

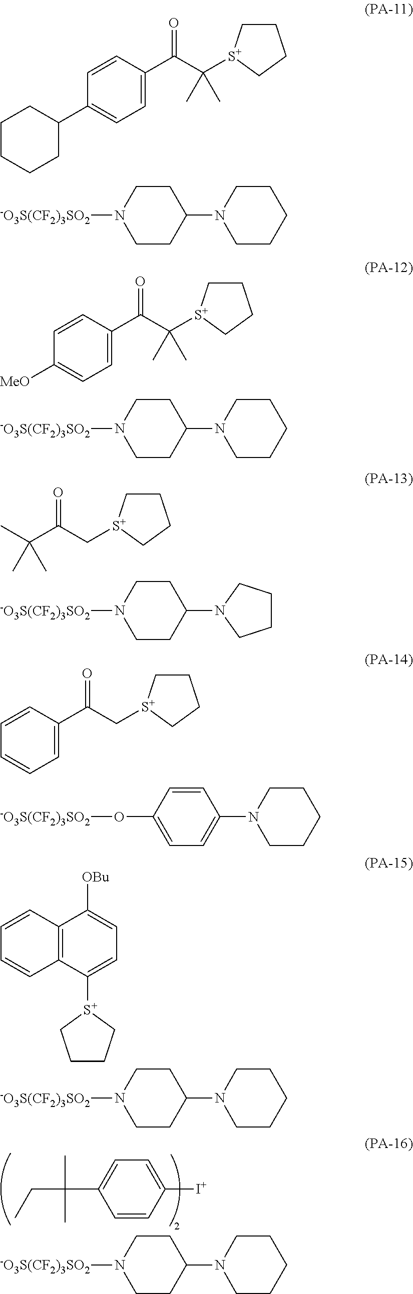

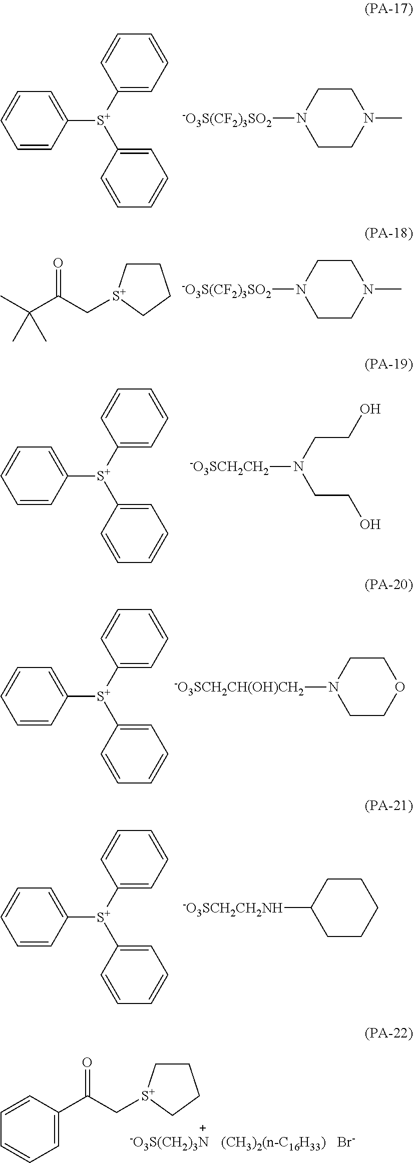

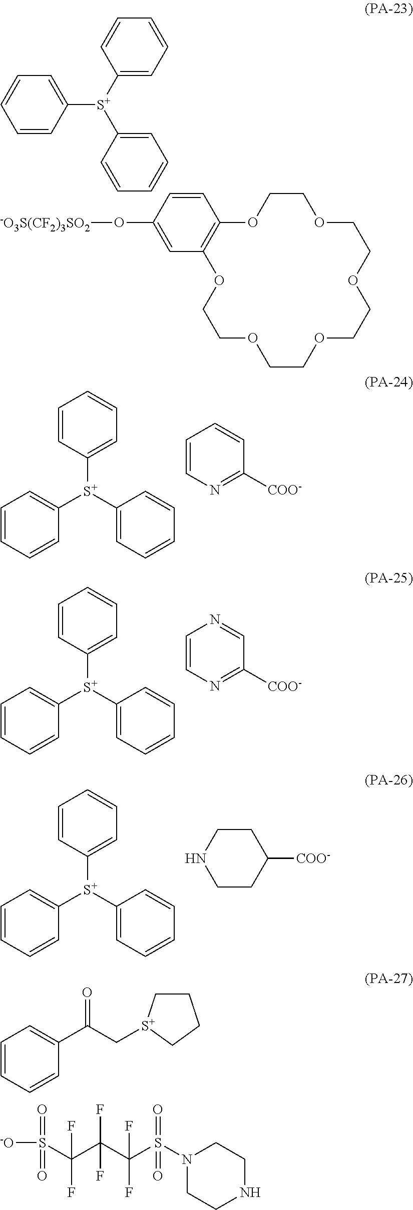

These compounds can be easily synthesized from the compound represented by Formula (PA-I) or a lithium, sodium, or potassium salt thereof and a hydroxide, bromide, chloride, or the like of iodonium or sulfonium, by using the salt exchange method described in JP1999-501909A (JP-H11-501909A) or JP2003-246786A. Furthermore, these compounds can be synthesized based on the synthesis method described in JP1995-333851A (JP-H07-333851A).

Specific examples of the compound (N) generating the compound represented by Formula (PA-II) or (PA-III) by being irradiated with actinic rays or radiation will be shown below, but the present invention is not limited thereto.

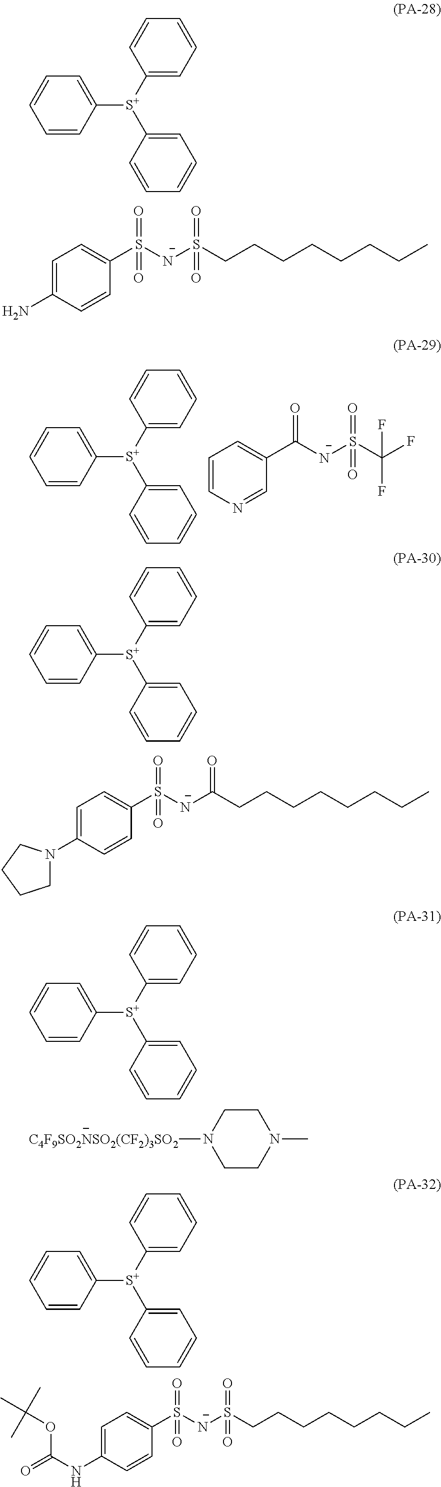

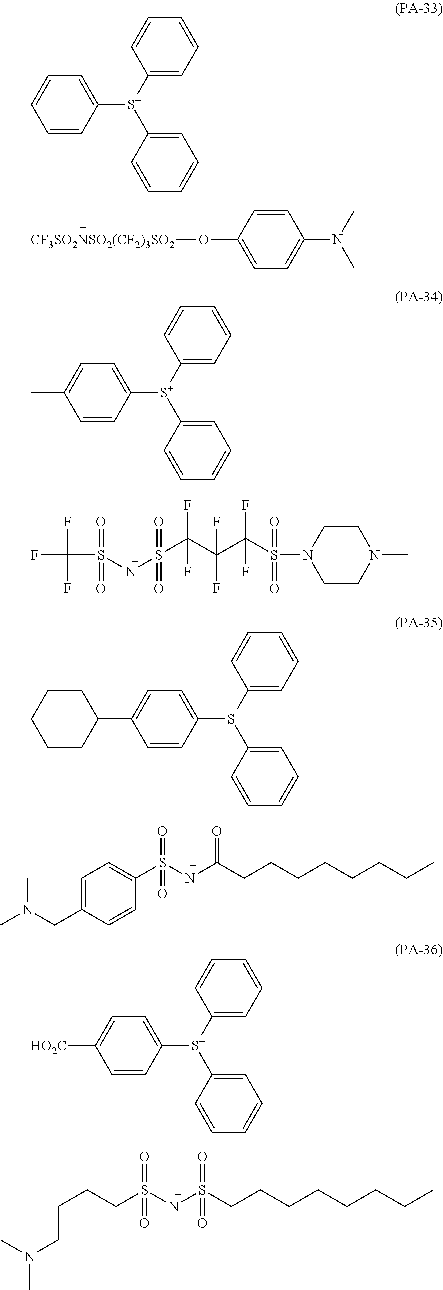

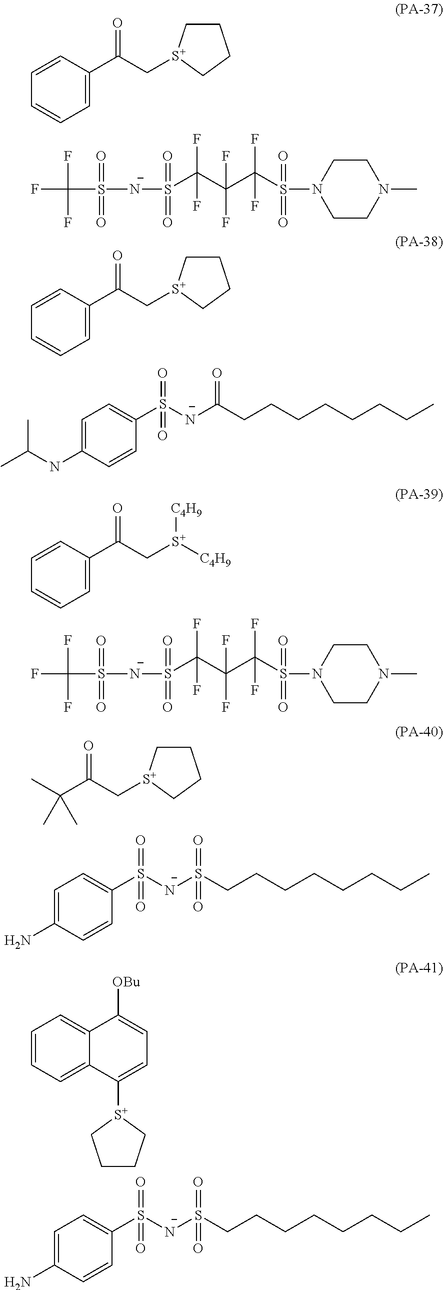

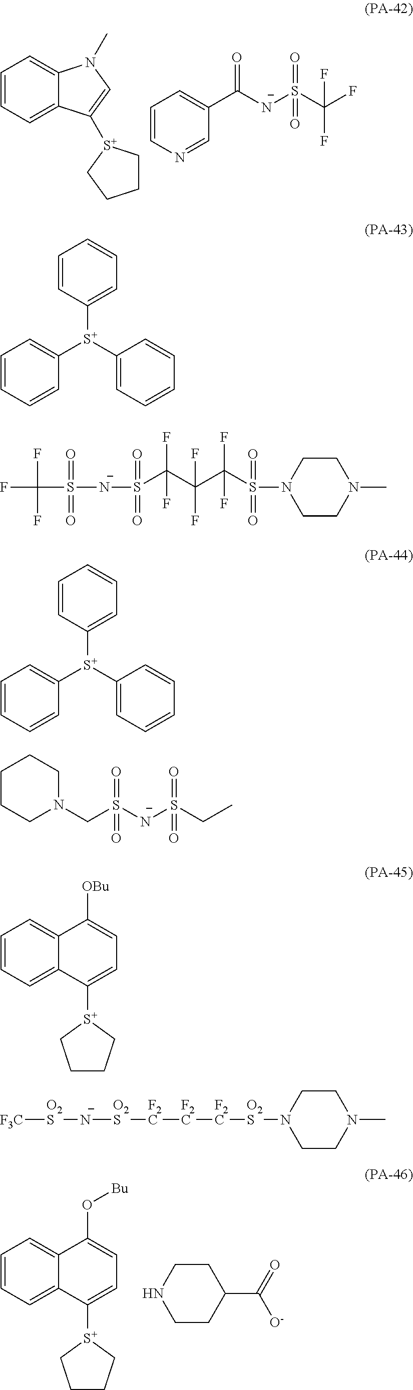

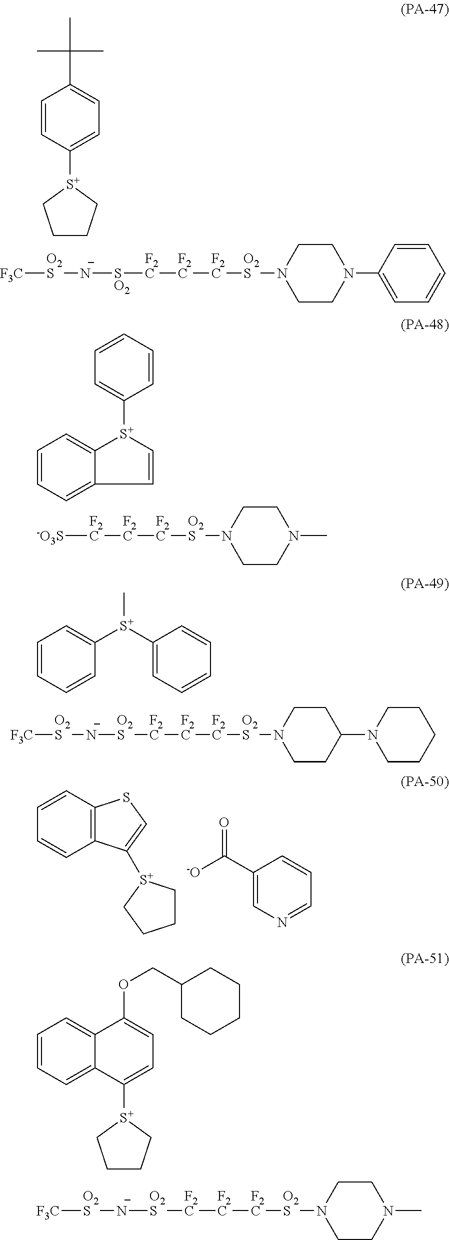

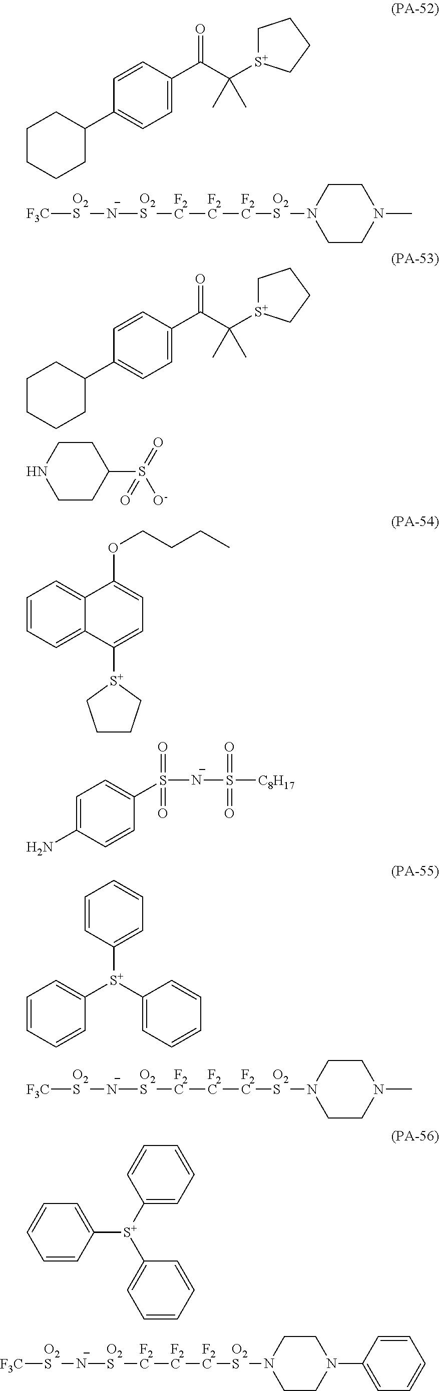

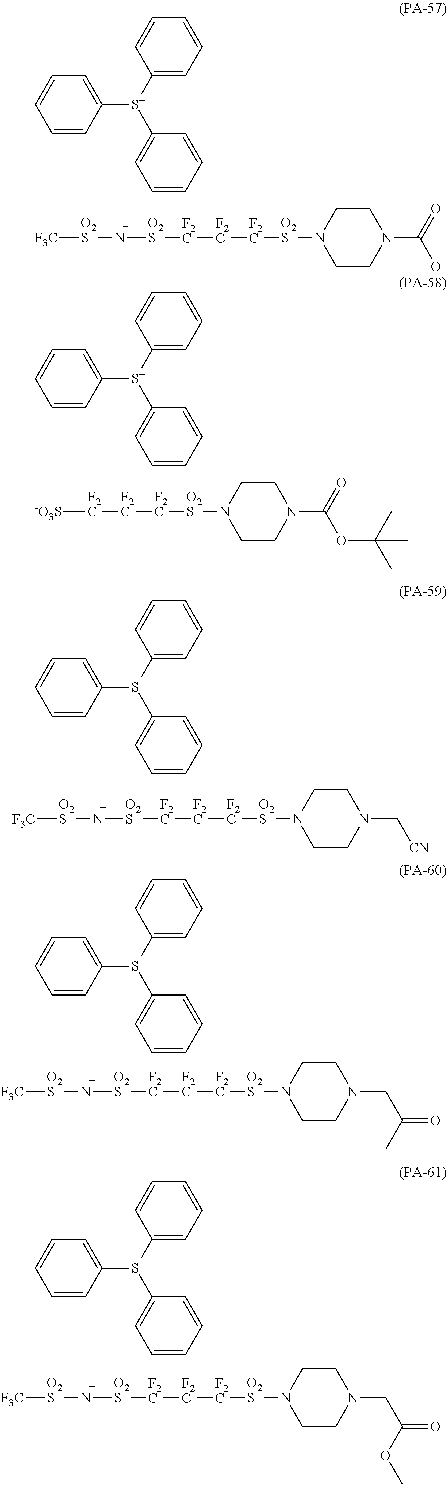

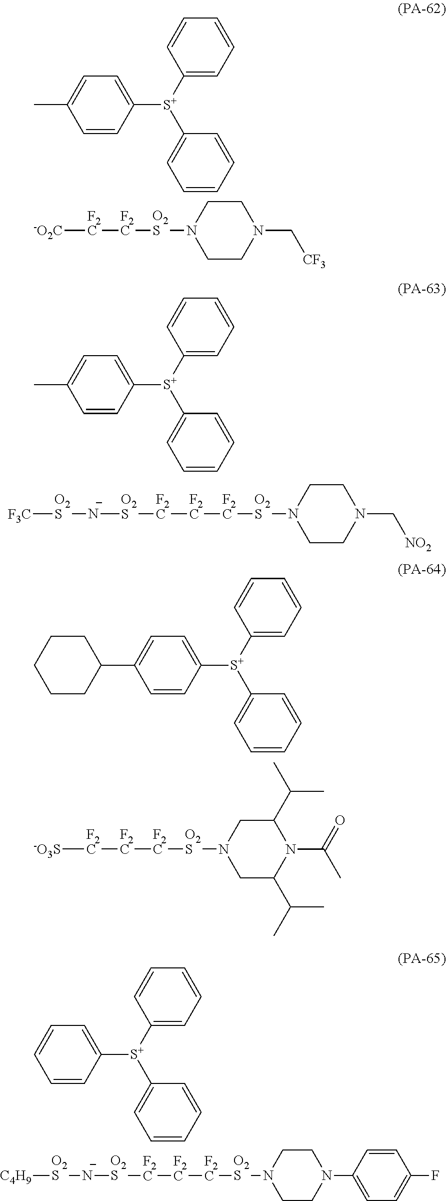

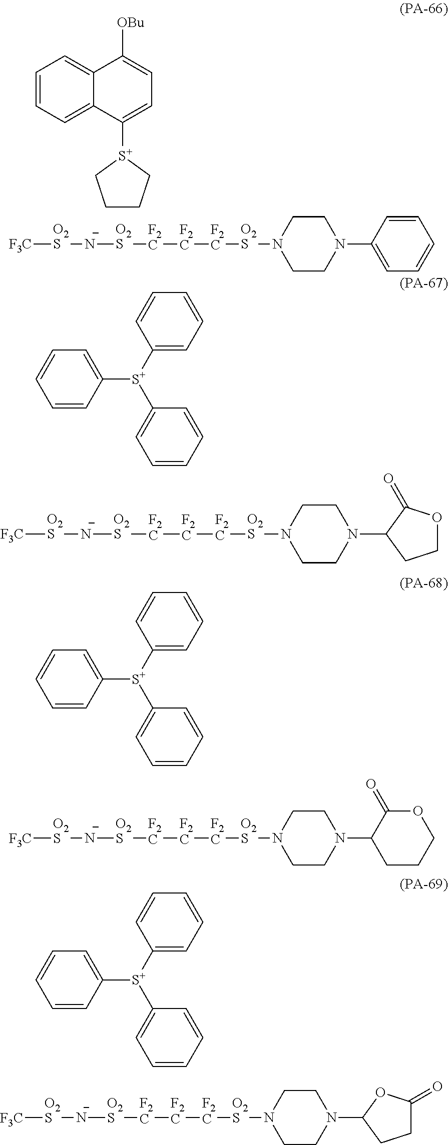

These compounds can be easily synthesized using a general sulfonic acid esterification reaction or a sulfonamidation reaction. For example, these compounds can be obtained by a method in which one sulfonyl halide portion of a bissulfonyl halide compound is selectively reacted with an amine, an alcohol, or the like having a partial structure represented by Formula (PA-II) or (PA-III) such that a sulfonamide bond or a sulfonic acid ester bond is formed, and then the other sulfonyl halide portion is hydrolyzed, or a method in which the ring of a cyclic sulfonic anhydride is opened using an amine or alcohol having a partial structure represented by Formula (PA-II). The amine or alcohol having a partial structure represented by Formula (PA-II) or (PA-III) can be synthesized by reacting an amine or an alcohol with an anhydride such as (R′O₂C)₂O or (R′SO₂)₂O or with an acid chloride compound such as R′O₂CCl or R′SO₂Cl in a basic environment (R′ represents a methyl group, a n-octyl group, a trifluoromethyl group, or the like). Particularly, these compounds can be synthesized based on the synthesis examples and the like of JP2006-330098A.

A molecular weight of the compound (N) is preferably 500 to 1,000.

The first resist composition in the present invention may or may not contain the compound (N). In a case where the composition contains the compound (N), a content of the compound (N) based on the solid content of the first resist composition is preferably 0.1% to 20% by mass, and more preferably 0.1% to 10% by mass.

[5-2] Basic compound (N′)

In order to reduce a performance change that occurs as time passes from exposure to heating, the first resist composition in the present invention may contain a basic compound (N′) different from the compound (N) described above.

Preferred examples of the basic compound (N′) include compounds having structures represented by the following Formulae (A′) to (E′).

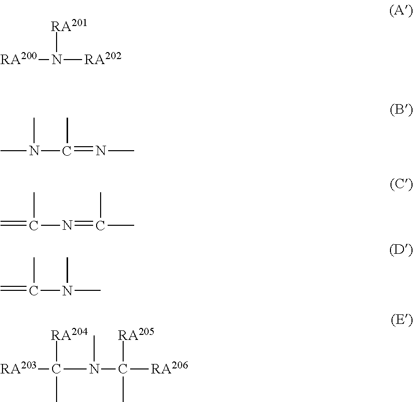

In Formulae (A′) and (E′), RA²⁰⁰, RA²⁰¹, and RA²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms). RA²⁰¹ and RA²⁰² may form a ring by being bonded to each other. RA²⁰³, RA²⁰⁴, RA²⁰⁵, and RA²⁰⁶ may be the same as or different from each other, and each represent an alkyl group (preferably having 1 to 20 carbon atoms).

The alkyl group may have a substituent, and as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

The alkyl group in Formulae (A′) and (E′) is more preferably unsubstituted.

Specific examples of the basic compound (N′) preferably include a guanidine, aminopyridine, pyrazole, pyrazoline, piperazine, aminomorpholine, aminoalkyl morpholine, piperidine, and the like, and more preferably include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl group and/or an ether bond, and the like.

Examples of the compound having an imidazole structure include imidazole, 2,4,5-triphenylimidazole, benzimidazole, and the like. Examples of the compound having a diazabicyclo structure include 1,4-diazabicyclo[2,2,2]octane, 1,5-diazabicyclo[4,3,0]non-5-ene, 1,8-diazabicyclo[5,4,0]undec-7-ene, and the like. Examples of the compound having an onium hydroxide structure include triaryl sulfonium hydroxide, phenacyl sulfonium hydroxide, and sulfonium hydroxide having a 2-oxoalkyl group, and specific examples thereof include triphenyl sulfonium hydroxide, tris(t-butylphenyl)sulfonium hydroxide, bis(t-butylphenyl)iodonium hydroxide, phenacyl thiophenium hydroxide, 2-oxopropyl thiophenium hydroxide, and the like. Examples of the compound having an onium carboxylate structure include a compound in which an anion portion of a compound having an onium hydroxide structure becomes carboxylate, and examples thereof include acetate, adamantane-1-carboxylate, perfluoroalkyl carboxylate, and the like. Examples of the compound having a trialkylamine structure include tri(n-butyl)amine, tri(n-octyl)amine, and the like. Examples of the compound having an aniline structure include 2,6-diisopropylaniline, N,N-dimethylaniline, N,N-dibutylaniline, N,N-dihexylaniline, and the like. Examples of the alkylamine derivative having a hydroxyl group and/or an ether bond include ethanolamine, diethanolamine, triethanolamine, tris(methoxyethoxyethyl)amine, and the like. Examples of the aniline derivative having a hydroxyl group and/or an ether bond include N,N-bis(hydroxyethyl)aniline and the like.

Examples of the preferred basic compound further include an amine compound having a phenoxy group, an ammonium salt compound having a phenoxy group, an amine compound having a sulfonic acid ester group, and an ammonium salt compound having a sulfonic acid ester group, and the like.

It is preferable that, in the amine compound having a phenoxy group, the ammonium salt compound having a phenoxy group, the amine compound having a sulfonic acid ester group, and the ammonium salt compound having a sulfonic acid ester group, at least 1 alkyl group is bonded to a nitrogen atom. Furthermore, it is preferable that the above compounds have an oxygen atom in the alkyl chain such that an oxyalkylene group is formed. The number of oxyalkylene groups in a molecule of the above compounds is one or more, preferably 3 to 9, and more preferably 4 to 6. Among the oxyalkylene groups, a structure of —CH₂CH₂O—, —CH(CH₃)CH₂O—, or —CH₂CH₂CH₂O— is preferable.

Specific examples of the amine compound having a phenoxy group, the ammonium salt compound having a phenoxy group, the amine compound having a sulfonic acid ester group, and the ammonium salt compound having a sulfonic acid ester group include the compounds (C1-1) to (C3-3) exemplified in paragraph “0066” of US2007/0224539A, but the compounds are not limited to thereto.

As a kind of basic compound, it is possible to use a nitrogen-containing organic compound having a group which is eliminated by the action of an acid. Examples of such a compound include a compound represented by the following Formula (F). The compound represented by the following Formula (F) exhibits effective basicity in a system by the elimination of the group which is eliminated by the action of an acid.

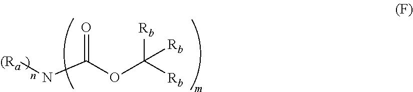

In Formula (F), Rₐ independently represents a hydrogen atom, an alkyl group, a cycloalkyl group, an aryl group, or an aralkyl group. When n=2, two Rₐ's may be the same as or different from each other, or two Rₐ's may form a divalent heterocyclic hydrocarbon group (preferably having 20 or less carbon atoms) or a derivative thereof by being bonded to each other.

R_{b} independently represents a hydrogen atom, an alkyl group, a cycloalkyl group, an aryl group, or an aralkyl group. Here, when one or more R_{b}'s in —C(R_{b})(R_{b})(R_{b})— represent a hydrogen atom, at least one of other R_{b}'s is a cyclopropyl group or a 1-alkoxyalkyl group.

At least two R_{b}'s may form an alicyclic hydrocarbon group, an aromatic hydrocarbon group, a heterocyclic hydrocarbon group, or a derivative thereof by being bonded to each other.

n represents an integer of 0 to 2, and m represents an integer of 1 to 3. n+m equals 3.

In Formula (F), the alkyl group, the cycloalkyl group, the aryl group, and the aralkyl group represented by Rₐ and R_{b} may be substituted with a functional group, such as a hydroxyl group, a cyano group, an amino group, a pyrrolidino group, a piperidino group, a morpholino group, or an oxo group, an alkoxy group, or a halogen atom.

Examples of the alkyl group, the cycloalkyl group, the aryl group, or the aralkyl group (These alkyl group, cycloalkyl group, aryl group, and aralkyl group may be substituted with the aforementioned functional group, an alkoxy group, or a halogen atom) as R include groups obtained by substituting groups derived from linear or branched alkanes such as methane, ethane, propane, butane, pentane, hexane, heptane, octane, nonane, decane, undeane, and dodecane and groups derived from these alkanes with one or more kinds of cycloalkyl group such as a cyclobutyl group, a cyclopentyl group, or a cyclohexyl group or with one or more cycloalkyl groups; groups obtained by substituting groups derived from cycloalkanes such as cyclobutane, cyclopentane, cyclohexane, cycloheptane, cyclooctane, norbornane, adamantane, and noradamantane or groups derived from these cycloalkanes with one or more kinds of linear or branched alkyl group such as a methyl group, an ethyl group, a n-propyl group, an i-propyl group, a n-butyl group, a 2-methylpropyl group, a 1-methylpropyl group, or a t-butyl group or with one or more linear or branched alkyl groups; groups obtained by substituting groups derived from aromatic compounds such as benzene, naphthalene, and anthracene or groups derived from these aromatic compounds with one or more kinds of linear or branched alkyl group such as a methyl group, an ethyl group, a n-propyl group, an i-propyl group, a n-butyl group, a 2-methylpropyl group, a 1-methylpropyl group, or a t-butyl group or with one or more linear or branched alkyl groups; groups obtained by substituting groups derived from heterocyclic compounds such as pyrrolidine, piperidine, morpholine, tetrahydrofuran, tetrahydropyran, indole, indoline, quinoline, perhydroquinoline, indazole, and benzimidazole or groups derived from these heterocyclic compounds with one or more kinds of linear or branched alkyl group or with one or more kinds of group derived from an aromatic compound; groups obtained by substituting a group derived from linear or branched alkane or a group derived from cycloalkane with one or more kinds of group derived from an aromatic compound such as a phenyl group, a naphthyl group, or an anthracenyl group or with one or more aromatic compounds; groups obtained by substituting the above substituents with a functional group such as a hydroxyl group, a cyano group, an amino group, a pyrrolidino group, a piperidino group, a morpholino group, or an oxo group; and the like.

Examples of the divalent heterocyclic hydrocarbon group (preferably having 1 to 20 carbon atoms) or a derivative thereof formed by Rₐ's bonded to each other include those obtained by substituting groups derived from heterocyclic compounds such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, and 1,5,9-triazacyclododecane or groups derived from these heterocyclic compounds with a group derived from linear or branched alkane, a group derived from cycloalkane, a group derived from an aromatic compound, a group derived from a heterocyclic compound, one or more kinds of functional group such as a hydroxyl group, a cyano group, an amino group, a pyrrolidino group, a piperidino group, a morpholino group, or an oxo group, or one or more functional groups, and the like.

Specific examples of the compound represented by Formula (F) will be shown below.

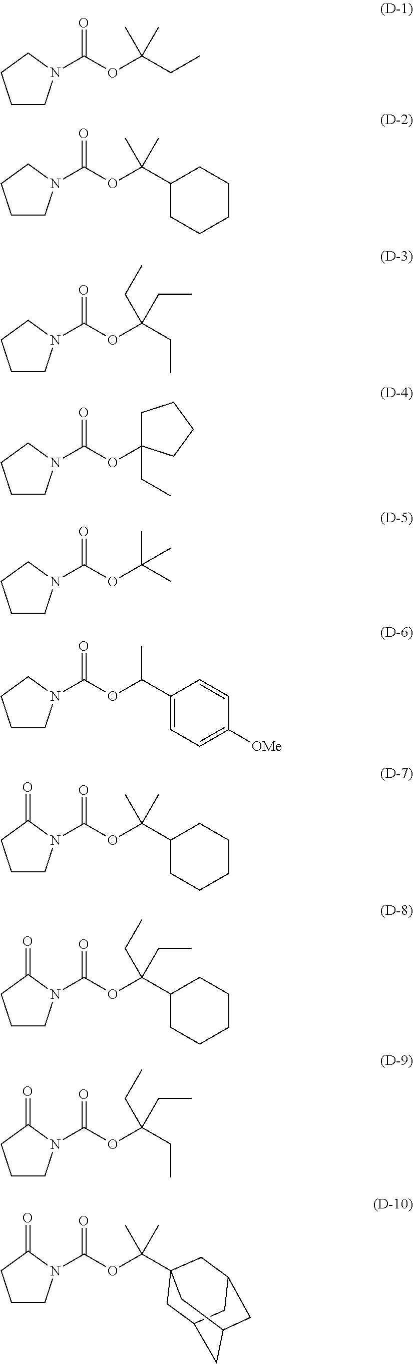

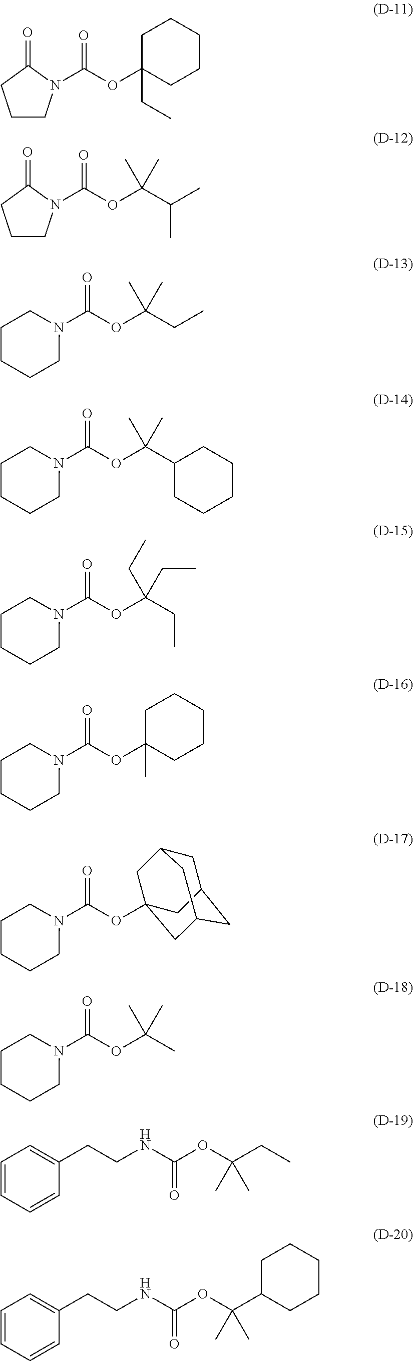

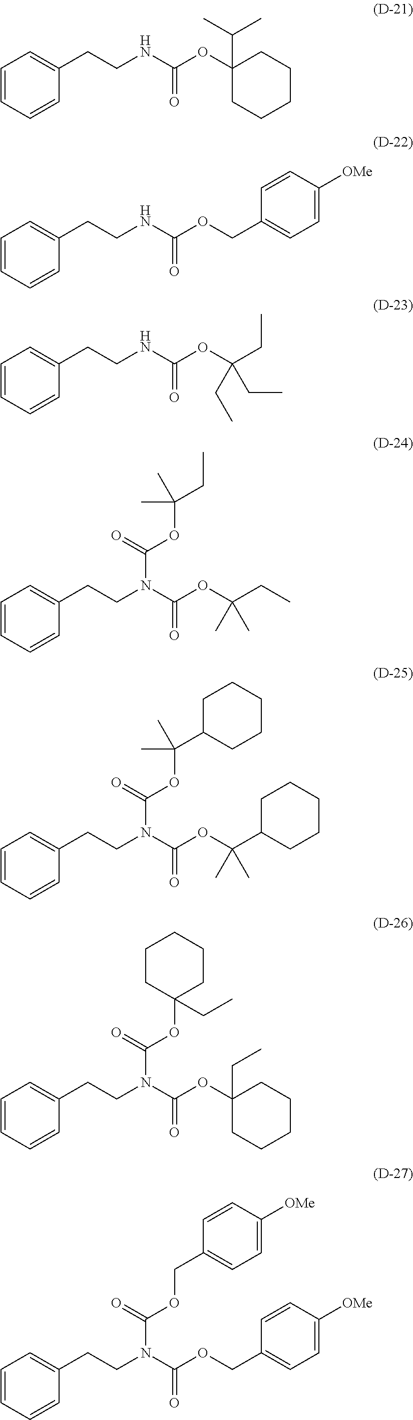

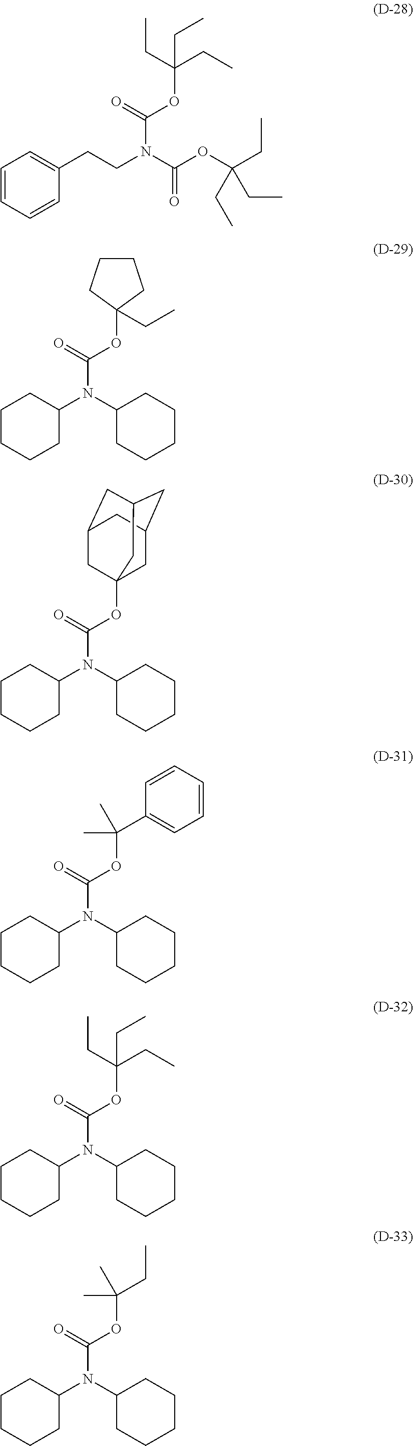

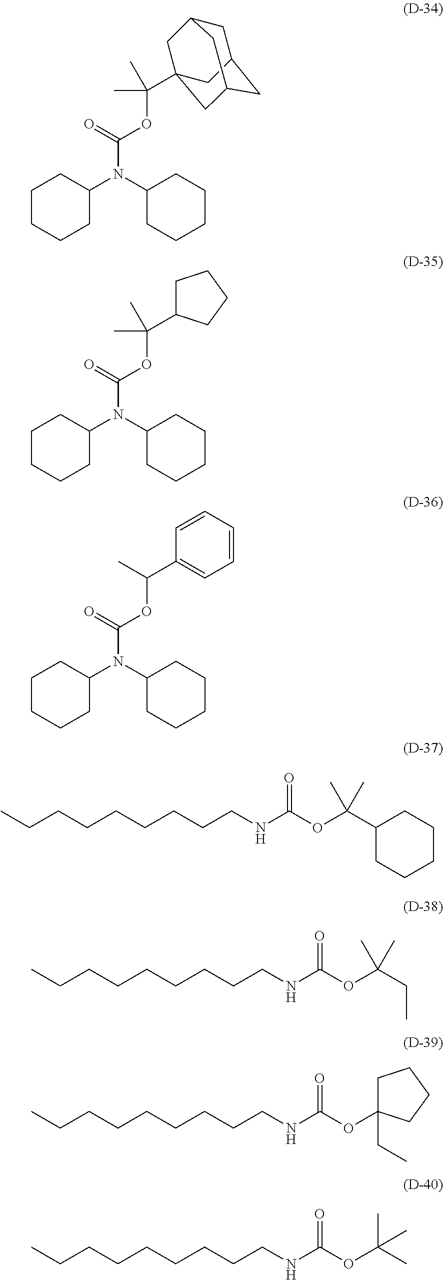

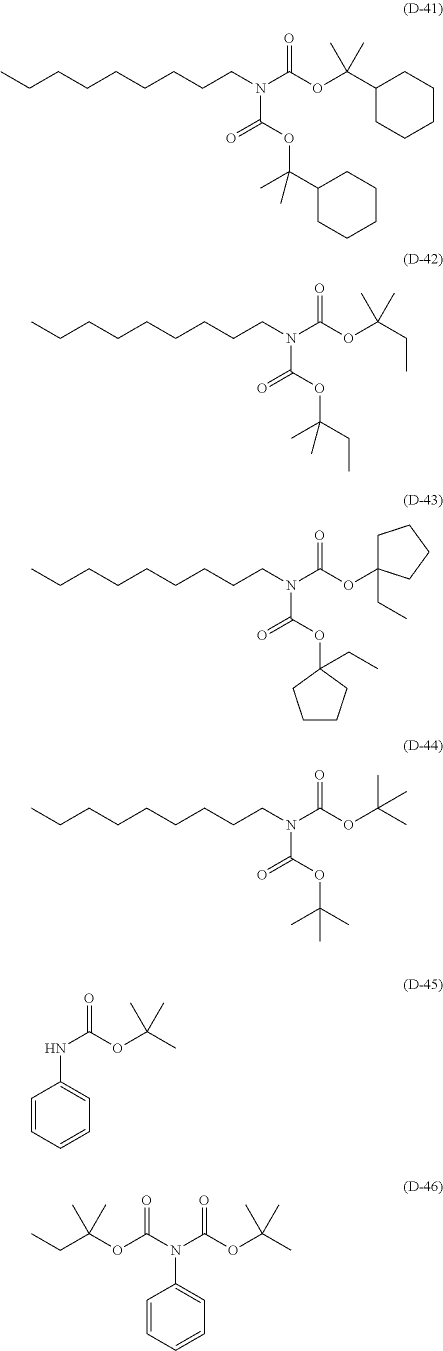

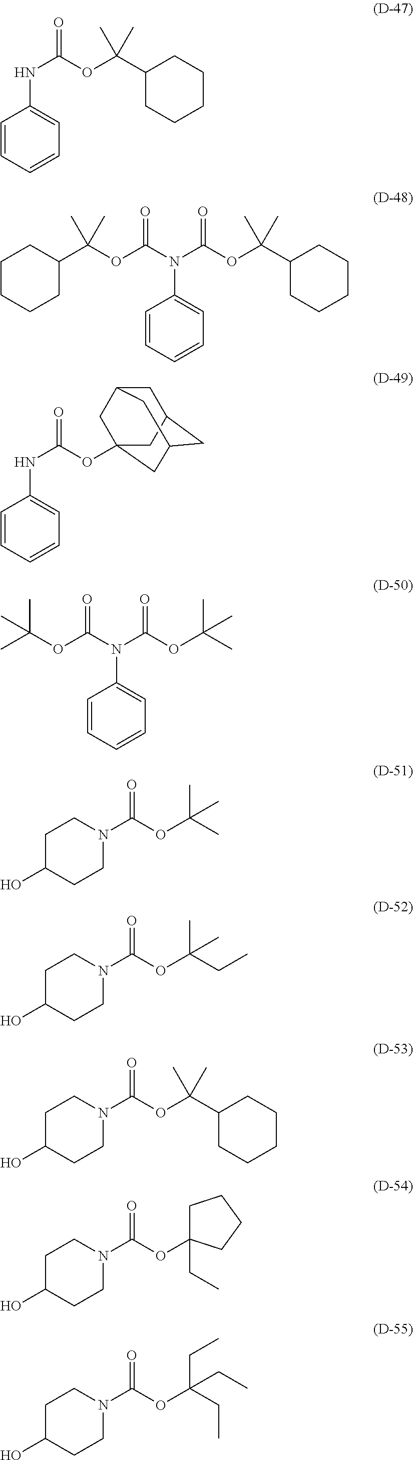

As the compound represented by Formula (F), commercially available compounds may be used. Furthermore, the compound represented by Formula (F) may be synthesized from a commercially available amine by the method described in Protective Groups in Organic Synthesis, 4^{th} edition. The compound represented by Formula (F) can also be synthesized based on the most common method such as the method described in JP2009-199021A.

As the basic compound (N′), a compound having an amine oxide structure can also be used. Specific examples of compounds which can be used as the compound include triethylaminepyridine N-oxide, tributylamine N-oxide, triethanolamine N-oxide, tris(methoxyethyl)amine N-oxide, tris(2-(methoxymethoxy)ethyl)amine oxide, 2,2′,2″-nitrilotriethylpropionate N-oxide, N-2-(2-methoxyethoxy)methoxyethyl morpholine N-oxide, and amine oxide compounds exemplified in JP2008-102383A.

A molecular weight of the basic compound (N′) is preferably 250 to 2,000, and more preferably 400 to 1,000. From the viewpoint of further reduction of LWR and dimensional uniformity of a local pattern, the molecular weight of the basic compound is preferably equal to or greater than 400, more preferably equal to or greater than 500, and even more preferably equal to or greater than 600.

These basic compounds (N′) may be used in combination with the compound (N). One kind of the basic compound (N′) is used singly, or two or more kinds thereof are used together.

The first resist composition in the present invention may or may not contain the basic compound (N′). In a case where the composition contains the basic compound (N′), an amount of the basic compound (N′) used is, based on the solid content of the first resist composition, generally 0.001% to 10% by mass, and preferably 0.01% to 5% by mass.

[6] Surfactant (F)

The first resist composition in the present invention may or may not further contain a surfactant. In a case where the composition contains the surfactant, it is preferable that the composition contains any of surfactants based on fluorine and/or silicon (a fluorine-based surfactant, a silicon-based surfactant, and a surfactant having both of a fluorine atom and a silicon atom) or contains two or more kinds of these surfactants.

In a case where the first resist composition in the present invention contains a surfactant, it is possible to form a resist pattern having small adhesiveness and development defect with excellent sensitivity and resolution at the time of using an exposure light source at equal to or less than 250 nm, particularly, equal to or less than 220 nm.

Examples of the surfactants based on fluorine and/or silicon include the surfactants described in paragraph “0276” of US2008/0248425A, such as FTOP EF301 and EF303 (manufactured by New Japanese Akita Kasei Co., Ltd), FLUORAD FC430, 431, and 4430 (manufactured by Sumitomo 3M Limited), MEGAFACE F171, F173, F176, F189, F113, F110, F177, F120, and R08 (manufactured by DIC Corporation), SURFLON S-382, SC101, 102, 103, 104, 105, 106, and KH-20 (manufactured by ASAHI GLASS CO., LTD.), TROYZOL S-366 (manufactured by Troy Chemical Industries), GF-300 and GF-150 (manufactured by TOAGOSEI CO., LTD.), SURFLON S-393 (manufactured by AGC SEIMI CHEMICAL CO., LTD.), FTOP EF121, EF122A, EF122B, RF122C, EF125M, EF135M, EF351, EF352, EF801, EF802, and EF601 (manufactured by JEMCO), PF636, PF656, PF6320, and PF6520 (manufactured by OMNOVA Solutions Inc.), and FTX-204G, 208G, 218G, 230G, 204D, 208D, 212D, 218D, and 222D (manufactured by NEOS COMPANY LIMITED). Furthermore, a polysiloxane polymer KP-341 (manufactured by Shin-Etsu Chemical Co., Ltd.) can also be used as a silicon-based surfactant.

As a surfactant, in addition to known ones described above, it is possible to use a surfactant using a polymer having a fluoroaliphatic group derived from a fluoroaliphatic compound manufactured by a telomerization method (referred to as a telomer method as well) or an oligomerization method (referred to as an oligomer method as well). The fluoroaliphatic compound can be synthesized by the method described in JP2002-90991A.

Examples of surfactants corresponding to the above include MEGAFACE F178, F-470, F-473, F-475, F-476, and F-472 (manufactured by DIC Corporation), a copolymer of acrylate (or methacrylate) having a C₆F₁₃ group and (poly(oxyalkylene))acrylate (or methacrylate), a copolymer of acrylate (or methacrylate) having a C₃F₇ group, (poly(oxyethylene))acrylate (or methacrylate), and (poly(oxypropylene))acrylate (or methacrylate), and the like.

In the present invention, it is possible to use surfactants which are described in paragraph “0280” of US2008/0248425A and different from the surfactants based on fluorine and/or silicon.

One kind of these surfactants may be used singly, or plural kinds thereof may be used in combination.

In a case where the first resist composition contains a surfactant, an amount of the surfactant used is, with respect to a total amount of the first resist composition (excluding a solvent), preferably 0.0001% to 2% by mass, and more preferably 0.0005% to 1% by mass.

In a case where the amount of the surfactant added is set to be equal to or less than 10 ppm with respect to a total amount of the first resist composition (excluding a solvent), surface localization properties of the hydrophobic resin are improved. Accordingly, the resist film surface can be more hydrophobic, and conformity to water at the time of liquid immersion exposure can be improved.

[7] Other Additives (G)

The first resist composition in the present invention may or may not contain a carboxylic acid onium salt. Examples of the carboxylic acid onium salt include those described in paragraphs “0605” and “0606” of US2008/0187860A.

The carboxylic acid onium salt can be synthesized by reacting sulfonium hydroxide, iodonium hydroxide, or ammonium hydroxide with silver oxide in an appropriate solvent.

In a case where the first resist composition contains a carboxylic acid onium salt, a content of the carboxylic acid onium salt is, with respect to the total solid content of the composition, generally 0.1% to 20% by mass, preferably 0.5% to 10% by mass, and even more preferably 1% to 7% by mass.

If necessary, the first resist composition of the present invention can contain a cross-linking agent, a dye, a plasticizer, a photosensitizer, a light absorber, an alkali-soluble resin, a dissolution inhibitor, a compound (for example, a phenol compound having a molecular weight of equal to or less than 1,000, or an alicyclic or aliphatic compound having a carboxyl group) promoting solubility in a developer, and the like.

The phenol compound having a molecular weight of equal to or less than 1,000 can by easily synthesized by those in the related art with reference to the methods described in, for example, JP1992-122938A (JP-H04-122938A), JP1990-28531A (JP-H02-28531A), U.S. Pat. No. 4,916,210A, and EP219294B.

Specific examples of the alicyclic or aliphatic compound having a carboxyl group include, but is not limited to, a carboxylic acid derivative having a steroid structure, such as cholic acid, deoxycholic acid, or lithocholic acid, an adamantane carboxylic acid derivative, adamantane dicarboxylic acid, cyclohexane carboxylic acid, cyclohexane dicarboxylic acid, and the like.

From the viewpoint of improving resolving power, the first resist composition in the present invention is preferably used at a film thickness of 30 to 250 nm and more preferably used at a film thickness of 30 to 200 nm. By setting the concentration of solid contents in the composition within an appropriate range such that appropriate viscosity is obtained and coating properties and film formability are improved, the above film thickness can be obtained.

The concentration of solid contents of the first resist composition in the present invention is generally 1.0% to 10% by mass, preferably 2.0% to 5.7% by mass, and even more preferably 2.0% to 5.3% by mass. In a case where the concentration of solid contents is within the above range, a substrate can be uniformly coated with a resist solution, and a resist pattern excellent in line width roughness can be formed. The reason is unclear but is assumed to be as below. In a case where the concentration of solid contents is set to be equal to or less than 10% by mass and preferably set to be equal to or less than 5.7% by mass, a material in the resist solution, particularly, a photoacid generator is inhibited from being aggregated, and as a result, a uniform resist film can be formed.

The concentration of solid contents is a weight percentage of a weight of resist components excluding a solvent in a total weight of the first resist composition.

The first resist composition in the present invention is used in a manner in which the aforementioned components are dissolve in a predetermined organic solvent, preferably, in a mixed solvent described above, subjected to filtration using a filter, and used for coating a predetermined support (substrate). The filter used for filtration is preferably a filter which is made of polytetrafluoroethylene, polyethylene, or nylon having a pore size of equal to or less than 0.1 μm, more preferably equal to or less than 0.05 μm, and even more preferably equal to or less than 0.03 μm. At the time of performing filtration using a filter, for example, as described in JP2002-62667A, circulative filtration may be performed, or a plurality of kinds of filter may be connected to each other in series or in parallel for performing filtration. Furthermore, the composition may be filtered plural times. In addition, before and after the filtration using a filter, the composition may be subjected to a deaeration treatment or the like.

<Second Resist Composition>

Next, the second resist composition used in the pattern forming method of the present invention will be described.

The second resist composition may be a negative resist composition or a positive resist composition, and a known composition can be used as each of the resist compositions. However, for the reason described above, the second resist composition is preferably a negative resist composition (more specifically, a negative resist composition for organic solvent development). Typically, the second resist composition is a chemical amplification-type resist composition.

As described above, it is preferable that the second resist composition contains a resin of which the solubility in a developer containing an organic solvent decreases due to an increase in polarity caused by the action of an acid. Examples of the resin include the same resin as the resin, of which the solubility in a developer containing an organic solvent decreases due to an increase in polarity caused by the action of an acid, described for the first resist composition. A preferred range of a content of the aforementioned resin with respect to a total amount of the second resist composition is also the same as described above for the first resist composition.

The second resist composition can also contain the same component as each of the components that the first resist composition can contain. A preferred range of a content of each component with respect to a total amount of the second resist composition is also the same as described above for the first resist composition.

<Composition for Forming Planarization Layer (a)>

Next, the composition for forming a planarization layer (a) used in the pattern forming method of the present invention will be described.

The composition for forming a planarization layer (a) is typically a composition containing a solvent, and is preferably a resin composition containing a resin and a solvent. By coating the first pattern with the resin composition, void portions of the pattern are filled with the resin composition, and a planarization layer is suitably formed.

The resin composition may contain, in addition to a resin and a solvent, any component that is generally used in a resist composition, an underlayer film of a resist film, or the like, such as a cross-linking agent or a surfactant.

The resin contained in the resin composition is preferably a resin having an Onishi parameter of equal to or greater than 4.0, more preferably a resin having an Onishi parameter of equal to or greater than 5.0, and even more preferably a resin having an Onishi parameter of equal to or greater than 5.5.

The planarization layer preferably contains a resin having an Onishi parameter of equal to or greater than 4.0, more preferably contains a resin having an Onishi parameter of equal to or greater than 5.0, and even more preferably contains a resin having an Onishi parameter of equal to or greater than 5.5.

The aforementioned resin is generally a resin having an Onishi parameter of equal to or less than 15.

Herein, an Onishi parameter of a resin is defined as below by an Onishi parameter of a monomer corresponding to a repeating unit constituting the resin.

(Onishi parameter of resin)=(total number of atoms)/{(number of carbon atoms)−number of oxygen atoms}

(Onishi parameter of resin)=Σ{(ratio of monomer introduced (weight ratio))×(Onishi parameter of monomer)}

As the composition for forming a planarization layer, it is possible to use known composition for forming a planarization film, composition for forming an underlayer film, and composition for forming an antireflection film. Examples of documents disclosing these known components include WO2004/074938A, WO2004/061526A, JP2003-057828A, JP2008-120876A, and JP2008-242492A.

The composition for forming a planarization layer may be any of a composition mainly composed of a resin, a composition mainly composed of a low-molecular weight compound, and a mixture of a resin and a low-molecular weight compound.

Examples of the resin contained in the composition for forming a planarization layer include a resin containing a (meth)acryl-based repeating unit, a resin containing a styrene-based repeating unit, a polyester-based resin, a polycarbonate-based resin, a polyvinyl alcohol-based resin, a polyether ketone-based resin, a polysiloxane-based resin, and the like. Examples of the resin-containing composition for forming an planarization layer include the compositions disclosed in WO2004/061526A, JP2010-528453A, JP2010-153655A, and the like.

Examples of the low-molecular weight compound contained in the composition for forming a planarization layer include a thermally cross-linkable compound, photo cross-linkable compound, a compound cross-linked by the action of an acid, and a compound cross-linked by the action of an alkali. Examples of the low-molecular weight compound-containing composition for forming a planarization layer include the compositions disclosed in JP2000-007982A and JP2000-195955A.

The composition for forming a planarization layer may contain a cross-linking agent, a surfactant, a granular compound, and the like (for example, JP2009-004438A). The cross-linking agent may be a low-molecular weight compound or may be supported on a resin.

Examples of the solvent which can be contained in the composition for forming a planarization layer include the aforementioned solvents for a resist composition.

The present invention also relates to a method for manufacturing an electronic device including the aforementioned pattern forming method of the present invention and an electronic device manufactured by the manufacturing method.

The electronic device of the present invention is suitably mounted on electric and electronic instruments (home appliances, OA•media-related instruments, optical instruments, communication instruments, and the like).

### EXPLANATION OF REFERENCES

51: substrate
52: first resist film
53: first resist film having undergone exposure
54: first pattern
55: microfabricated pattern
56: second resist film
57: second resist film having undergone exposure
58: second pattern
61: mask
71: actinic rays or radiation
75: etching gas
81: planarization layer

What is claimed is:

1. A pattern forming method comprising:
(A) a step of forming a first resist film on a substrate by using a first resist composition;
(B) a step of exposing the first resist film;
(C) a step of forming a first pattern by developing the exposed first resist film;
(D) a step of forming a planarization layer on the substrate provided with the first pattern by using a composition for forming a planarization layer (a);
(E) a step of forming a second resist film on the planarization layer by using a second resist composition;
(F) a step of exposing the second resist film; and
(G) a step of forming a second pattern by developing the exposed second resist film in this order;
wherein the first pattern is insoluble in the composition for forming the planarization layer (a).

2. The pattern forming method according to claim 1,
wherein the step (C) is a step of forming the first pattern by developing the exposed first resist film by using a developer containing an organic solvent.

3. The pattern forming method according to claim 1, further comprising:
(C′) a step of heating the first pattern between the step (C) and the step (D).

4. The pattern forming method according to claim 3,
wherein a heating temperature in the step (C′) is equal to or higher than 130° C.

5. The pattern forming method according to claim 1,
wherein the step (G) is a step of forming a negative pattern as the second pattern by using a developer containing an organic solvent.

6. The pattern forming method according to claim 1,
wherein the step (G) is a step of forming a positive pattern as the second pattern by using an alkali developer.

7. The pattern forming method according to claim 1, further comprising:
(H) a step of converting the first pattern into a microfabricated pattern by performing an etching treatment on the planarization layer and the first pattern by using the second pattern as a mask after the step (G).

8. The pattern forming method according to claim 1,
wherein at least one of the first pattern or the second pattern contains a silicon atom.

9. The pattern forming method according to claim 7,
wherein at least one of the first pattern or the second pattern contains a silicon atom.

10. The pattern forming method according to claim 7, further comprising:
(I) a step of removing the planarization layer and the second pattern after the step (H).

11. The pattern forming method according to claim 10,
wherein the step (I) includes a step of performing an etching treatment on the planarization layer under a condition in which an etching rate of the planarization layer becomes higher than an etching rate of the microfabricated pattern.

12. The pattern forming method according to claim 1,
wherein the planarization layer is a layer containing a resin having an Onishi parameter of equal to or greater than 4.0.

13. The pattern forming method according to claim 7,
wherein the planarization layer is a layer containing a resin having an Onishi parameter of equal to or greater than 4.0.

14. The pattern forming method according to claim 10,
wherein the planarization layer is a layer containing a resin having an Onishi parameter of equal to or greater than 4.0.

15. The pattern forming method according to claim 11,
wherein the planarization layer is a layer containing a resin having an Onishi parameter of equal to or greater than 4.0.

16. A method for manufacturing an electronic device, comprising the pattern forming method according to claim 1.
